(19) United States
(12) Patent Application Publication
(10) Pub. No.: US 2016/0093812 A1
(43) Pub. Date: Mar. 31, 2016

(54) ORGANIC ELECTROLUMINESCENT DEVICE

(71) Applicant: MERCK PATENT GMBH, Darmstadt (DE)

(72) Inventors: Philipp STOESSEL, Frankfurt Am Main (DE); Christof PFLUMM, Darmstadt (DE); Amir Hossain PARHAM, Frankfurt Am Main (DE); Anja JATSCH, Frankfurt Am Main (DE); Joachim KAISER, Darmstadt (DE)

(21) Appl. No.: 14/782,621

(22) PCT Filed: Mar. 18, 2014
(86) PCT No.: PCT/EP2014/000742

§ 371 Date: Oct. 6, 2015

(30) Foreign Application Priority Data
Apr. 8, 2013 (EP) 13001796.5

(51) Int. Cl. H01L 51/00; C09K 11/06

(52) U.S. Cl. CPC H01L 51/0072; C09K 11/06; H01L 51/0067; H01L 51/0056; H01L 51/0077; H01L 51/5072

(57) ABSTRACT

The present invention relates to organic electroluminescent devices which comprise a luminescent material having a small singlet-triplet separation in the emitting layer and a material having an LUMO≦−2.55 eV in the adjacent electron-conducting layer.

The present invention relates to organic electroluminescent devices which comprise a luminescent material having a small singlet-triplet separation in the emitting layer and a material having an LUMO≦−2.55 eV in the electron-transport layer.

The structure of organic electroluminescent devices (OLEDs) in which organic semiconductors are employed as functional materials is described, for example, in U.S. Pat. No. 4,539,507, U.S. Pat. No. 5,151,629, EP 0676461 and WO 98/27136. The emitting materials employed here are also, in particular, organometallic iridium and platinum complexes, which exhibit phosphorescence instead of fluorescence (M. A. Baldo et al., Appl. Phys. Lett. 1999, 75, 4-6). For quantum-mechanical reasons, an up to four-fold increase in the energy and power efficiency is possible using organometallic compounds as phosphorescence emitters.

In spite of the good results achieved with organometallic iridium and platinum complexes, these also have, however, a number of disadvantages: thus, iridium and platinum are rare and expensive metals. It would therefore be desirable, for resource conservation, to be able to avoid the use of these rare metals. Furthermore, metal complexes of this type in some cases have lower thermal stability than purely organic compounds, in particular during sublimation, so that the use of purely organic compounds would also be advantageous for this reason so long as they result in comparably good efficiencies. Furthermore, blue-, in particular deep-blue-phosphorescent iridium and platinum emitters having high efficiency and a long lifetime can only be achieved with technical difficulty, so that there is also a need for improvement here. Furthermore, there is, in particular, a need for improvement in the lifetime of phosphorescent OLEDs comprising Ir or Pt emitters if the OLED is operated at elevated temperature, as is necessary for some applications.

An alternative development is the use of emitters which exhibit thermally activated delayed fluorescence (TADF) (for example H. Uoyama et al., Nature 2012, Vol. 492, 234). These are organic materials in which the energetic separation between the lowest triplet state T₁ and the first excited singlet state S₁ is so small that this energy separation is smaller or in the region of thermal energy. For quantum-statistical reasons, the excited states arise to the extent of 75% in the triplet state and to the extent of 25% in the singlet state on electronic excitation in the OLED. Since purely organic molecules usually cannot emit from the triplet state, 75% of the excited states cannot be utilised for emission, meaning that in principle only 25% of the excitation energy can be converted into light. However, if the energetic separation between the lowest triplet state and the lowest excited singlet state is not or is not significantly greater than the thermal energy, which is described by kT, the first excited singlet state of the molecule is accessible from the triplet state through thermal excitation and can be occupied thermally. Since this singlet state is an emissive state from which fluorescence is possible, this state can be used for the generation of light. Thus, the conversion of up to 100% of electrical energy into light is in principle possible on use of purely organic materials as emitters. Thus, an external quantum efficiency of greater than 19% is described in the prior art, which is of the same order of magnitude as for phosphorescent OLEDs. It is thus possible, using purely organic materials of this type, to achieve very good efficiencies and at the same time to avoid the use of rare metals, such as iridium or platinum. Furthermore, it is also possible using such materials to achieve highly efficient blue-emitting OLEDs.

The prior art describes the use of various electron-conducting compounds, for example benzimidazole derivatives, such as TPBi (H. Uoyama et al., Nature 2012, 492, 234), pyridine derivatives (Mehes et al., Angew. Chem. Int. Ed. 2012, 51, 11311; Endo et al., Appl. Phys. Lett. 2011, 98, 083302/1 or WO 2013/011954) or phenanthroline derivatives (Nakagawa et al., Chem. Commun. 2012, 48, 9580 or WO 2011/070963), adjacent to the emitting layer which exhibits thermally activated delayed fluorescence. It is common to these electron-conducting materials that they all have an LUMO of −2.51 eV or higher.

In general, there is still a further need for improvement, in particular with respect to efficiency, voltage and lifetime, in organic electroluminescent devices which exhibit emission by the TADF mechanism. The technical object on which the present invention is based is thus the provision of OLEDs whose emission is based on TADF and which have improved properties, in particular with respect to one or more of the above-mentioned properties.

Surprisingly, it has been found that organic electroluminescent devices which have an organic TADF molecule in the emitting layer and have one or more layers which comprise an electron-conducting material having an LUMO of ≦−2.55 eV adjacent to this layer on the cathode side achieve this object and result in improvements in the organic electroluminescent device. The present invention therefore relates to organic electroluminescent devices of this type.

The present invention relates to an organic electroluminescent device comprising cathode, anode and emitting layer which comprises at least one luminescent organic compound which has a separation between the lowest triplet state T₁ and the first excited singlet state S₁ of ≦0.15 eV, characterised in that the electroluminescent device comprises one or more electron-transport layers, each of which comprises at least one compound having an LUMO≦−2.55 eV, on the cathode side of the emitting layer.

An organic electroluminescent device in the sense of the present invention comprises anode, cathode, emitting layer, which is arranged between anode and cathode, and at least one electron-transport layer. An electron-transport layer in the sense of the present invention is a layer which is arranged between the cathode or the electron-injection layer and the emitting layer. An electron-injection layer in the sense of the present invention is a layer which is directly adjacent to the cathode and which has a layer thickness of not greater than 5 nm, preferably 0.5 to 5 nm.

In accordance with the invention, all electron-transport layers, i.e. all layers which are present between the cathode or, if present, the electron-injection layer and the emitting layer, comprise at least one compound having an LUMO≦−2.55 eV.

The luminescent organic compound which has a separation between the lowest triplet state T₁ and the first excited singlet state S₁ of ≦0.15 eV is described in greater detail below. This is a compound which exhibits TADF (thermally activated delayed fluorescence). This compound is abbreviated to “TADF compound” in the following description.

An organic compound in the sense of the present invention is a carbon-containing compound which contains no metals. In particular, the organic compound is built up from the elements C, H, D, B, Si, N, P, O, S, F, Cl, Br and I.

A luminescent compound in the sense of the present invention is taken to mean a compound which is capable of emitting light at room temperature on optical excitation in an environment as is present in the organic electroluminescent device. The compound preferably has a luminescence quantum efficiency of at least 40%, particularly preferably at least 50%, very particularly preferably at least 60% and especially preferably at least 70%. The luminescence quantum efficiency is determined here in a layer in a mixture with the matrix material, as is to be employed in the organic electroluminescent device. The way in which the determination of the luminescence quantum yield is carried out for the purposes of the present invention is described in detail in general terms in the example part.

It is furthermore preferred for the TADF compound to have a short decay time. The decay time is preferably ≦50 μs. The way in which the decay time is determined for the purposes of the present invention is described in detail in general terms in the example part.

The energy of the lowest excited singlet state (S₁) and of the lowest triplet state (T₁) is determined by quantum-chemical calculation. The way in which this determination is carried out in the sense of the present invention is generally described in detail in the example part.

As described above, the separation between S₁ and T₁ can be a maximum of 0.15 eV in order that the compound is a TADF compound in the sense of the present invention. The separation between S₁ and T₁ is preferably ≦0.10 eV, particularly preferably ≦0.08 eV, very particularly preferably ≦0.05 eV.

The TADF compound is preferably an aromatic compound which has both donor and also acceptor substituents, where the LUMO and the HOMO of the compound only spatially overlap weakly. What is meant by donor or acceptor substituents is known in principle to the person skilled in the art. Suitable donor substituents are, in particular, diaryl- and diheteroarylamino groups and carbazole groups or carbazole derivatives, each of which are preferably bonded to the aromatic compound via N. These groups may also be substituted further. Suitable acceptor substituents are, in particular, cyano groups, but also, for example, electron-deficient heteroaryl groups, which may also be substituted further.

Examples of suitable molecules which exhibit TADF are the structures shown in the following table.

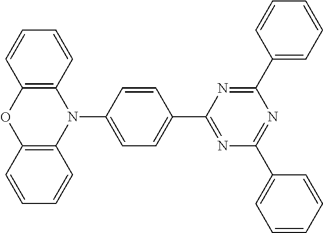 [SMILES: c1ccc(-c2nc(-c3ccccc3)nc(-c3ccc(N4c5ccccc5Oc5ccccc54)cc3)n2)cc1]

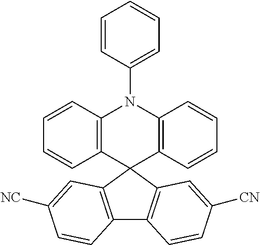 [SMILES: N#Cc1ccc2c(c1)C1(c3cc(C#N)ccc3-2)c2ccccc2N(c2ccccc2)c2ccccc21]

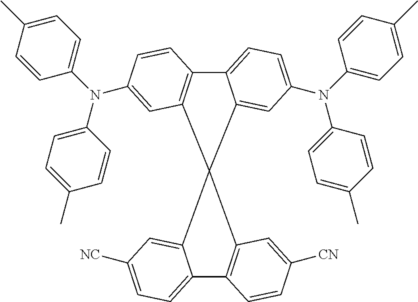

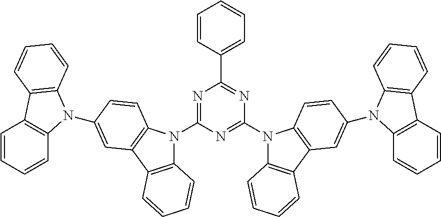 [SMILES: c1ccc(-c2nc(-n3c4ccccc4c4cc(-n5c6ccccc6c6ccccc65)ccc43)nc(-n3c4ccccc4c4cc(-n5c6ccccc6c6ccccc65)ccc43)n2)cc1]

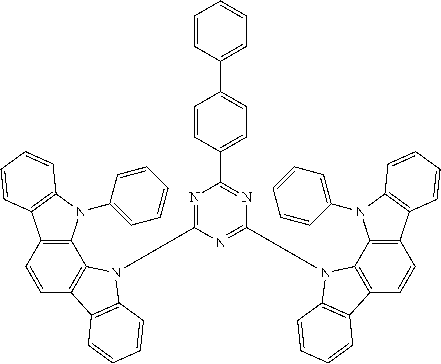 [SMILES: c1ccc(-c2ccc(-c3nc(-n4c5ccccc5c5ccc6c7ccccc7n(-c7ccccc7)c6c54)nc(-n4c5ccccc5c5ccc6c7ccccc7n(-c7ccccc7)c6c54)n3)cc2)cc1]

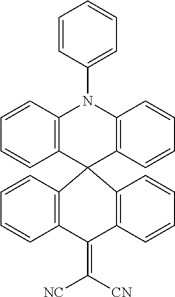 [SMILES: N#CC(C#N)=C1c2ccccc2C2(c3ccccc31)c1ccccc1N(c1ccccc1)c1ccccc12]

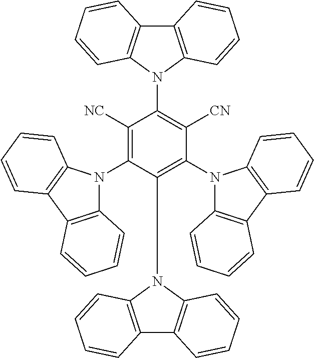 [SMILES: N#Cc1c(-n2c3ccccc3c3ccccc32)c(C#N)c(-n2c3ccccc3c3ccccc32)c(-n2c3ccccc3c3ccccc32)c1-n1c2ccccc2c2ccccc21]

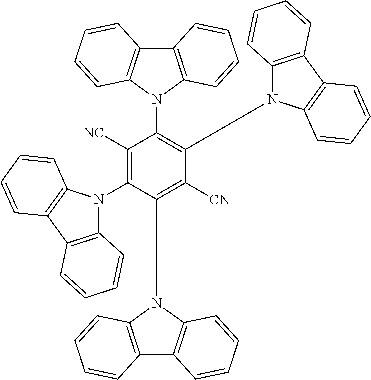 [SMILES: N#Cc1c(-n2c3ccccc3c3ccccc32)c(-n2c3ccccc3c3ccccc32)c(C#N)c(-n2c3ccccc3c3ccccc32)c1-n1c2ccccc2c2ccccc21]

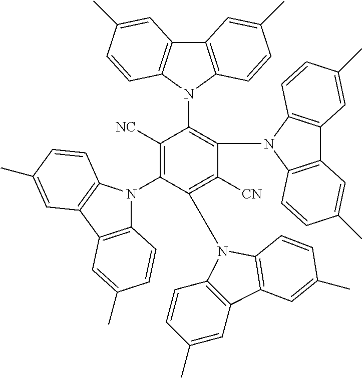

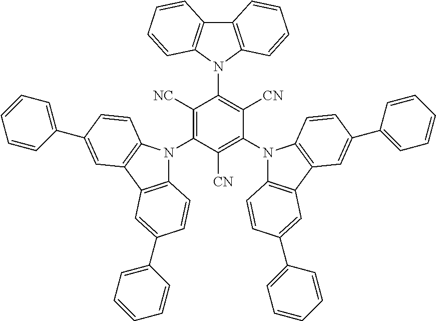 [SMILES: N#Cc1c(-n2c3ccccc3c3ccccc32)c(C#N)c(-n2c3ccc(-c4ccccc4)cc3c3cc(-c4ccccc4)ccc32)c(C#N)c1-n1c2ccc(-c3ccccc3)cc2c2cc(-c3ccccc3)ccc21]

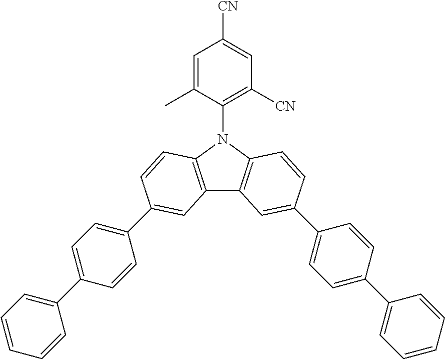 [SMILES: Cc1cc(C#N)cc(C#N)c1-n1c2ccc(-c3ccc(-c4ccccc4)cc3)cc2c2cc(-c3ccc(-c4ccccc4)cc3)ccc21]

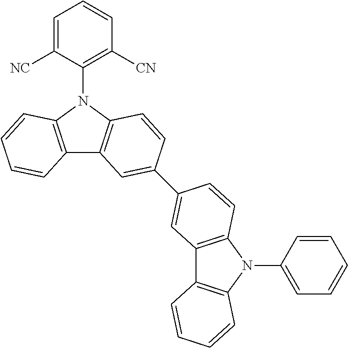 [SMILES: N#Cc1cccc(C#N)c1-n1c2ccccc2c2cc(-c3ccc4c(c3)c3ccccc3n4-c3ccccc3)ccc21]

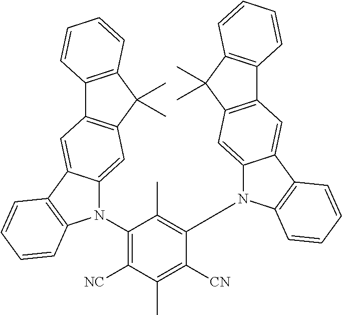 [SMILES: Cc1c(C#N)c(-n2c3ccccc3c3cc4c(cc32)C(C)(C)c2ccccc2-4)c(C)c(-n2c3ccccc3c3cc4c(cc32)C(C)(C)c2ccccc2-4)c1C#N]

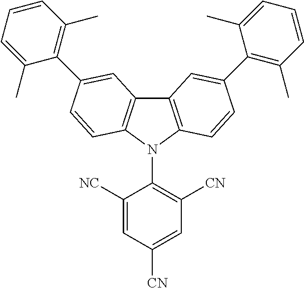 [SMILES: Cc1cccc(C)c1-c1ccc2c(c1)c1cc(-c3c(C)cccc3C)ccc1n2-c1c(C#N)cc(C#N)cc1C#N]

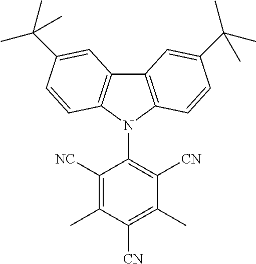 [SMILES: Cc1c(C#N)c(C)c(C#N)c(-n2c3ccc(C(C)(C)C)cc3c3cc(C(C)(C)C)ccc32)c1C#N]

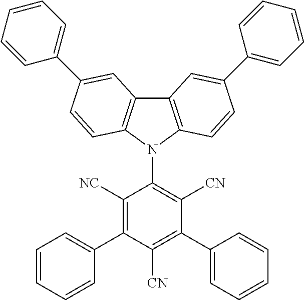 [SMILES: N#Cc1c(-c2ccccc2)c(C#N)c(-n2c3ccc(-c4ccccc4)cc3c3cc(-c4ccccc4)ccc32)c(C#N)c1-c1ccccc1]

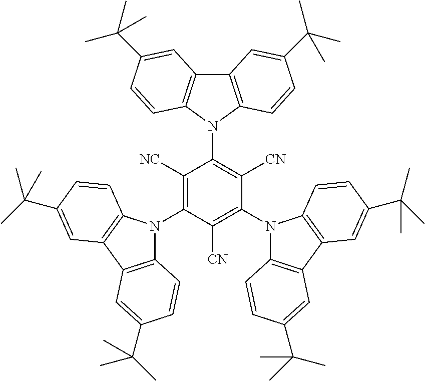 [SMILES: CC(C)(C)c1ccc2c(c1)c1cc(C(C)(C)C)ccc1n2-c1c(C#N)c(-n2c3ccc(C(C)(C)C)cc3c3cc(C(C)(C)C)ccc32)c(C#N)c(-n2c3ccc(C(C)(C)C)cc3c3cc(C(C)(C)C)ccc32)c1C#N]

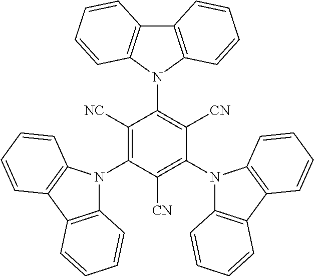 [SMILES: N#Cc1c(-n2c3ccccc3c3ccccc32)c(C#N)c(-n2c3ccccc3c3ccccc32)c(C#N)c1-n1c2ccccc2c2ccccc21]

The TADF compound in the emitting layer is preferably present in a matrix. The matrix material does not contribute or does not contribute essentially to the emission of the mixture.

In order to prevent exciplex formation in the emitting layer, it is preferred for the following to apply to LUMO(TADF), i.e. the LUMO of the TADF compound, and HOMO(matrix):

LUMO(TADF)−HOMO(matrix)>S₁(TADF)−0.4 eV;

particularly preferably:

LUMO(TADF)−HOMO(matrix)>S₁(TADF)−0.3 eV;

and very particularly preferably:

LUMO(TADF)−HOMO(matrix)>S₁(TADF)−0.2 eV.

S₁(TADF) here is the first excited singlet state S₁ of the TADF compound.

In order that the TADF compound is the emitting compound in the mixture of the emitting layer, it is preferred for the lowest triplet energy of the matrix to be a maximum of 0.1 eV lower than the triplet energy of the molecule which exhibits TADF. Particularly preferably, T₁(matrix)≦T₁(TADF). The following particularly preferably applies: T₁(matrix)−T₁(TADF)≦0.1 eV, very particularly preferably T₁(matrix)−T₁(TADF)≦0.2 eV. T₁(matrix) here stands for the lowest triplet energy of the matrix compound and T₁(TADF) stands for the lowest triplet energy of the compound which exhibits TADF. The triplet energy of the matrix is determined here by quantum-chemical calculation, as generally described below in the example part for the compounds which exhibit TADF.

Examples of suitable matrix materials are ketones, phosphine oxides, sulfoxides and sulfones, for example in accordance with WO 2004/013080, WO 2004/093207, WO 2006/005627 or WO 2010/006680, triarylamines, carbazole derivatives, for example CBP (N,N-biscarbazolylbiphenyl), m-CBP or the carbazole derivatives disclosed in WO 2005/039246, US 2005/0069729, JP 2004/288381, EP 1205527, WO 2008/086851 or US 2009/0134784, indolocarbazole derivatives, for example in accordance with WO 2007/063754 or WO 2008/056746, indenocarbazole derivatives, for example in accordance with WO 2010/136109 or WO 2011/000455, azacarbazoles, for example in accordance with EP 1617710, EP 1617711, EP 1731584, JP 2005/347160, bipolar matrix materials, for example in accordance with WO 2007/137725, silanes, for example in accordance with WO 2005/111172, azaboroles or boronic esters, for example in accordance with WO 2006/117052, diazasilole derivatives, for example in accordance with WO 2010/054729, diazaphosphole derivatives, for example in accordance with WO 2010/054730, triazine derivatives, for example in accordance with WO 2010/015306, WO 2007/063754 or WO 2008/056746, zinc complexes, for example in accordance with EP 652273 or WO 2009/062578, or bridged carbazole derivatives, for example in accordance with US 2009/0136779, WO 2010/050778, WO 2011/042107 or WO 2011/088877.

The electron-transport layer according to the invention is described in greater detail below.

As already described above, one or more electron-transport layers are present, where each of these layers comprises at least one material having an LUMO≦−2.55 eV.

In a preferred embodiment of the invention, one, two or three electron-transport layers of this type are present, particularly preferably one or two electron-transport layers.

The layer thickness of the electron-transport layers here is preferably in total between 10 and 100 nm, particularly preferably between 15 and 90 nm, very particularly preferably between 20 and 70 nm.

As described above, the electron-transport layer comprises at least one electron-transporting compound which has an LUMO≦−2.55 eV. The LUMO is preferably ≦−2.60 eV, particularly preferably ≦−2.65 eV, very particularly preferably ≦−2.70 eV, The LUMO here is the lowest unoccupied molecular orbital. The value of the LUMO of the compound is determined by quantum-chemical calculation, as generally described below in the example part.

In order that the emission of the TADF compound is not quenched at the directly adjacent electron-transport layer, it is preferred for the lowest triplet energy of this electron-transport layer to be a maximum of 0.1 eV lower than the triplet energy of the molecule which exhibits TADF. Particularly preferably, T₁(ETL)≧T₁(TADF). The following particularly preferably applies: T₁(ETL)−T₁(TADF)≧0.1 eV, very particularly preferably T₁(ETL)−T₁(TADF)≧0.2 eV. T₁(ETL) here stands for the lowest triplet energy of the electron-transport layer which is directly adjacent to the emitting layer, and T₁(TADF) stands for the lowest triplet energy of the TADF compound. The triplet energy of the materials of the electron-transport layer is determined here by quantum-chemical calculation, as is generally described below in the example part. If the electron-transport layer comprises more than one compound, the condition for the triplet energy preferably applies to each of the compounds.

The above-mentioned conditions for the triplet energy are only preferred for the electron-transport layer directly adjacent to the emitting layer. In the case of the presence of further electron-transport layers which are arranged on the cathode side of the electron-transport layer directly adjacent to the emitting layer, the triplet energy for these further electron-transport layers is unimportant, so that electron-transport materials having a lower triplet energy, for example anthracene derivatives, can also be selected here.

The electron-transport layer according to the invention directly adjacent to the emitting layer on the cathode side can also act as hole-blocking layer, i.e. can also simultaneously have hole-blocking properties in addition to electron-transporting properties. This is dependent on the position of the HOMO level of the layer. In particular, the layer acts as hole-blocking layer if the following applies to the HOMO of the layer: HOMO(EML)−HOMO(ETL)>0.2 eV, preferably HOMO(EML)−HOMO(ETL)>0.3 eV. HOMO(ETL) is the HOMO of the material of the electron-transport layer. If this layer consists of a plurality of materials, HOMO(ETL) is the highest HOMO of these materials. HOMO(EML) is the HOMO of the material of the emitting layer. If this layer consists of a plurality of materials, HOMO(EML) is the highest HOMO of these materials. The HOMO (highest occupied molecular orbital) here is in each case determined by quantum-chemical calculations, as generally explained below in the example part.

For clarification, it is again emphasised here that the values for HOMO and LUMO are by definition negative numerical values. The highest HOMO is therefore the HOMO with the smallest modulus, and the lowest LUMO is the LUMO with the greatest modulus.

The electron-transport layer according to the invention may be in the form of a pure layer, i.e. it may consist only of one compound, which then has an LUMO≦−2.55 eV. The layer may also be in the form of a mixture, where at least one of the compounds then has an LUMO≦−2.55 eV. This compound is preferably present in the layer in a proportion of at least 30% by vol., particularly preferably at least 50% by vol., very particularly preferably at least 70% by vol. The layer is especially preferably in the form of a pure layer, i.e. it consists only of one compound which has an LUMO≦−2.55 eV. If the electron-transport layer comprises a mixture of two or more materials, it is preferred for each of these materials to have an LUMO≦−2.55 eV.

Suitable electron-transport materials for use in the electron-transport layer according to the invention are selected from the substance classes of the triazines, the pyrimidines, the lactams, the metal complexes, in particular the Be, Zn and Al complexes, the aromatic ketones, the aromatic phosphine oxides, the azaphospholes, the azaboroles, which are substituted by at least one electron-conducting substituent, the benzimidazoles and the quinoxalines. It is essential to the invention that these materials have an LUMO of ≦−2.55 eV. Many derivatives of the above-mentioned substance classes have such an LUMO, so that these substance classes can generally be regarded as suitable, even if individual compounds from these substance classes possibly have an LUMO>-2.55 eV. However, only those electron-conducting materials which have an LUMO≦−2.55 eV are employed in accordance with the invention. It is possible for the person skilled in the art, without inventive step, to select suitable materials for the electron-transport layer according to the invention.

If the electron-transport material in the electron-transport layer according to the invention is a triazine or pyrimidine compound, this compound is then preferably selected from the compounds of the following formulae (1) and (2),

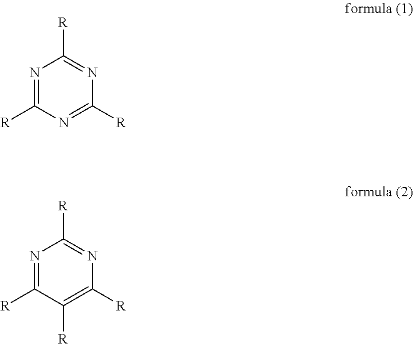

where the following applies to the symbols used:
R is selected on each occurrence, identically or differently, from the group consisting of H, D, F, Cl, Br, I, CN, NO₂, N(Ar)₂, N(R¹)₂, C(═O)Ar, C(═O)R¹, P(═O)(Ar)₂, a straight-chain alkyl, alkoxy or thioalkyl group having 1 to 40 C atoms or a branched or cyclic alkyl, alkoxy or thioalkyl group having 3 to 40 C atoms or an alkenyl or alkynyl group having 2 to 40 C atoms, each of which may be substituted by one or more radicals R¹, where one or more non-adjacent CH₂ groups may be replaced by R¹C═CR¹, C≡C, Si(R¹)₂, C═O, C═S, C═NR¹, P(═O)(R¹), SO, SO₂, NR¹, O, S or CONR¹ and where one or more H atoms may be replaced by D, F, Cl, Br, I, CN or NO₂, an aromatic or heteroaromatic ring system having 5 to 80, preferably 5 to 60, aromatic ring atoms, which may in each case be substituted by one or more radicals R¹, an aryloxy or heteroaryloxy group having 5 to 60 aromatic ring atoms, which may be substituted by one or more radicals R¹, or an aralkyl or heteroaralkyl group having 5 to 60 aromatic ring atoms, which may be substituted by one or more radicals R¹, where two or more adjacent substituents R may optionally form a monocyclic or polycyclic, aliphatic, aromatic or heteroaromatic ring system, which may be substituted by one or more radicals R¹;
R¹ is selected on each occurrence, identically or differently, from the group consisting of H, D, F, Cl, Br, I, CN, NO₂, N(Ar)₂, N(R²)₂, C(═O)Ar, C(═O)R², P(═O)(Ar)₂, a straight-chain alkyl, alkoxy or thioalkyl group having 1 to 40 C atoms or a branched or cyclic alkyl, alkoxy or thioalkyl group having 3 to 40 C atoms or an alkenyl or alkynyl group having 2 to 40 C atoms, each of which may be substituted by one or more radicals R², where one or more non-adjacent CH₂ groups may be replaced by R²≡CR², C≡C, Si(R²)₂, C═O, C═S, C═NR², P(═O)(R²), SO, SO₂, NR², O, S or CONR² and where one or more H atoms may be replaced by D, F, Cl, Br, I, CN or NO₂, an aromatic or heteroaromatic ring system having 5 to 60 aromatic ring atoms, which may in each case be substituted by one or more radicals R², an aryloxy or heteroaryloxy group having 5 to 60 aromatic ring atoms, which may be substituted by one or more radicals R², or an aralkyl or heteroaralkyl group having 5 to 60 aromatic ring atoms, where two or more adjacent substituents R¹ may optionally form a monocyclic or polycyclic, aliphatic, aromatic or heteroaromatic ring system, which may be substituted by one or more radicals R²;
Ar is on each occurrence, identically or differently, an aromatic or heteroaromatic ring system having 5-30 aromatic ring atoms, which may be substituted by one or more non-aromatic radicals R²; two radicals Ar which are bonded to the same N atom or P atom here may also be bridged to one another by a single bond or a bridge selected from N(R²), C(R²)₂, O or S;
R² is selected from the group consisting of H, D, F, CN, an aliphatic hydrocarbon radical having 1 to 20 C atoms, an aromatic or heteroaromatic ring system having 5 to 30 aromatic ring atoms, in which one or more H atoms may be replaced by D, F, Cl, Br, I or CN, where two or more adjacent substituents R² may form a mono- or polycyclic, aliphatic, aromatic or heteroaromatic ring system with one another.

Adjacent substituents in the sense of the present application are substituents which are either bonded to the same carbon atom or which are bonded to carbon atoms which are in turn bonded directly to one another.

An aryl group in the sense of this invention contains 6 to 60 C atoms; a heteroaryl group in the sense of this invention contains 2 to 60 C atoms and at least one heteroatom, with the proviso that the sum of C atoms and heteroatoms is at least 5. The heteroatoms are preferably selected from N, O and/or S. An aryl group or heteroaryl group here is taken to mean either a simple aromatic ring, i.e. benzene, or a simple heteroaromatic ring, for example pyridine, pyrimidine, thiophene, etc., or a condensed (fused) aryl or heteroaryl group, for example naphthalene, anthracene, phenanthrene, quinoline, isoquinoline, etc. Aromatic rings linked to one another by a single bond, such as, for example, biphenyl, are, by contrast, not referred to as an aryl or heteroaryl group, but instead as an aromatic ring system.

An aromatic ring system in the sense of this invention contains 6 to 80 C atoms in the ring system. A heteroaromatic ring system in the sense of this invention contains 2 to 60 C atoms and at least one heteroatom in the ring system, with the proviso that the sum of C atoms and heteroatoms is at least 5. The heteroatoms are preferably selected from N, O and/or S. An aromatic or heteroaromatic ring system in the sense of this invention is intended to be taken to mean a system which does not necessarily contain only aryl or heteroaryl groups, but instead in which, in addition, a plurality of aryl or heteroaryl groups may be connected by a non-aromatic unit, such as, for example, a C, N or O atom. Thus, for example, systems such as fluorene, 9,9′-spirobifluorene, 9,9-diarylfluorene, triarylamine, diaryl ether, stilbene, etc., are also intended to be taken to be aromatic ring systems in the sense of this invention, as are systems in which two or more aryl groups are connected, for example, by a short alkyl group.

For the purposes of the present invention, an aliphatic hydrocarbon radical or an alkyl group or an alkenyl or alkynyl group, which may contain 1 to 40 C atoms and in which, in addition, individual H atoms or CH₂ groups may be substituted by the above-mentioned groups, is preferably taken to mean the radicals methyl, ethyl, n-propyl, i-propyl, n-butyl, i-butyl, s-butyl, t-butyl, 2-methylbutyl, n-pentyl, s-pentyl, neopentyl, cyclopentyl, n-hexyl, neohexyl, cyclohexyl, n-heptyl, cycloheptyl, n-octyl, cyclooctyl, 2-ethylhexyl, trifluoromethyl, pentafluoroethyl, 2,2,2-trifluoroethyl, ethenyl, propenyl, butenyl, pentenyl, cyclopentenyl, hexenyl, cyclohexenyl, heptenyl, cycloheptenyl, octenyl, cyclooctenyl, ethynyl, propynyl, butynyl, pentynyl, hexynyl, heptynyl or octynyl, An alkoxy group having 1 to 40 C atoms is preferably taken to mean methoxy, trifluoromethoxy, ethoxy, n-propoxy, i-propoxy, n-butoxy, i-butoxy, s-butoxy, t-butoxy, n-pentoxy, s-pentoxy, 2-methylbutoxy, n-hexoxy, cyclohexyloxy, n-heptoxy, cycloheptyloxy, n-octyloxy, cyclooctyloxy, 2-ethylhexyloxy, pentafluoroethoxy or 2,2,2-trifluoroethoxy. A thioalkyl group having 1 to 40 C atoms is taken to mean, in particular, methylthio, ethylthio, n-propylthio, i-propylthio, n-butylthio, i-butylthio, s-butylthio, t-butylthio, n-pentylthio, s-pentylthio, n-hexylthio, cyclohexylthio, n-heptylthio, cycloheptylthio, n-octylthio, cyclooctylthio, 2-ethylhexylthio, trifluoromethylthio, pentafluoroethylthio, 2,2,2-trifluoroethylthio, ethenylthio, propenylthio, butenylthio, pentenylthio, cyclopentenylthio, hexenylthio, cyclohexenylthio, heptenylthio, cycloheptenylthio, octenylthio, cyclooctenylthio, ethynylthio, propynylthio, butynylthio, pentynylthio, hexynylthio, heptynylthio or octynylthio. In general, alkyl, alkoxy or thioalkyl groups in accordance with the present invention may be straight-chain, branched or cyclic, where one or more non-adjacent CH₂ groups may be replaced by the above-mentioned groups; furthermore, one or more H atoms may also be replaced by D, F, Cl, Br, I, CN or NO₂, preferably F, Cl or CN, furthermore preferably F or CN, particularly preferably CN.

An aromatic or heteroaromatic ring system having 5-30 or 5-60 aromatic ring atoms respectively, which may also in each case be substituted by the above-mentioned radicals R, R¹ or R², is taken to mean, in particular, groups derived from benzene, naphthalene, anthracene, benzanthracene, phenanthrene, pyrene, chrysene, perylene, fluoranthene, naphthacene, pentacene, benzopyrene, biphenyl, biphenylene, terphenyl, triphenylene, fluorene, spirobifluorene, dihydrophenanthrene, dihydropyrene, tetrahydropyrene, cisor trans-indenofluorene, cis- or trans-indenocarbazole, cis- or transindolocarbazole, truxene, isotruxene, spirotruxene, spiroisotruxene, furan, benzofuran, isobenzofuran, dibenzofuran, thiophene, benzothiophene, isobenzothiophene, dibenzothiophene, pyrrole, indole, isoindole, carbazole, pyridine, quinoline, isoquinoline, acridine, phenanthridine, benzo-5,6-quinoline, benzo-6,7-quinoline, benzo-7,8-quinoline, phenothiazine, phenoxazine, pyrazole, indazole, imidazole, benzimidazole, naphthimidazole, phenanthrimidazole, pyridimidazole, pyrazinimidazole, quinoxalinimidazole, oxazole, benzoxazole, naphthoxazole, anthroxazole, phenanthroxazole, isoxazole, 1,2-thiazole, 1,3-thiazole, benzothiazole, pyridazine, hexaazatriphenylene, benzopyridazine, pyrimidine, benzopyrimidine, quinoxaline, 1,5-diazaanthracene, 2,7-diazapyrene, 2,3-diazapyrene, 1,6-diazapyrene, 1,8-diazapyrene, 4,5-diazapyrene, 4,5,9,10-tetraazaperylene, pyrazine, phenazine, phenoxazine, phenothiazine, fluorubin, naphthyridine, azacarbazole, benzocarboline, phenanthroline, 1,2,3-triazole, 1,2,4-triazole, benzotriazole, 1,2,3-oxadiazole, 1,2,4-oxadiazole, 1,2,5-oxadiazole, 1,3,4-oxadiazole, 1,2,3-thiadiazole, 1,2,4-thiadiazole, 1,2,5-thiadiazole, 1,3,4-thiadiazole, 1,3,5-triazine, 1,2,4-triazine, 1,2,3-triazine, tetrazole, 1,2,4,5-tetrazine, 1,2,3,4-tetrazine, 1,2,3,5-tetrazine, purine, pteridine, indolizine and benzothiadiazole or groups derived from combinations of these systems.

In a preferred embodiment of the compounds of the formula (1) or formula (2), at least one of the substituents R stands for an aromatic or heteroaromatic ring system. In formula (1), it is particularly preferred for all three substituents R to stand for an aromatic or heteroaromatic ring system, which may in each case be substituted by one or more radicals R¹. In formula (2), it is particularly preferred for one, two or three substituents R to stand for an aromatic or heteroaromatic ring system, which may in each case be substituted by one or more radicals R¹, and for the other substituents R to stand for H. Particularly preferred embodiments are thus the compounds of the following formulae (1a) and (2a) to (2d),

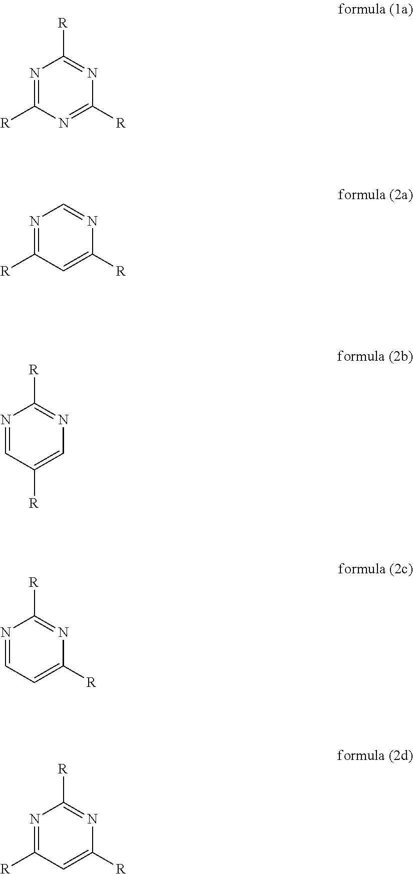

where R formula (1a) identically or differently, for an aromatic or heteroaromatic ring system having 5 to 60 aromatic ring atoms, which may in each case be substituted by one or more radicals R¹, and R¹ has the above-mentioned meaning.

In the case of pyrimidine compounds, preference is given here to the compounds of the formulae (2a) and (2d), in particular compounds of the formula (2d).

Preferred aromatic or heteroaromatic ring systems contain 5 to 30 aromatic ring atoms, in particular 6 to 24 aromatic ring atoms, and may be substituted by one or more radicals R¹. The aromatic or heteroaromatic ring systems here preferably contain no condensed aryl or heteroaryl groups in which more than two aromatic six-membered rings are condensed directly onto one another. They particularly preferably contain absolutely no aryl or heteroaryl groups in which aromatic six-membered rings are condensed directly onto one another. This preference is due to the higher triplet energy of substituents of this type. Thus, it is preferred for R to have, for example, no naphthyl groups or higher condensed aryl groups and likewise no quinoline groups, acridine groups, etc. By contrast, it is possible for R to have, for example, carbazole groups, dibenzofuran groups, etc., since no 6-membered aromatic or heteroaromatic rings are condensed directly onto one another in these structures.

Preferred substituents R are selected from the group consisting of benzene, ortho-, meta- or para-biphenyl, ortho-, meta-, para- or branched terphenyl, ortho-, meta-, para- or branched quaterphenyl, 1-, 2-, 3- or 4-fluorenyl, 1-, 2-, 3- or 4-spirobifluorenyl, 1- or 2-naphthyl, pyrrole, furan, thiophene, indole, benzofuran, benzothiophene, 1-, 2- or 3-carbazole, 1-, 2- or 3-dibenzofuran, 1-, 2- or 3-dibenzothiophene, indenocarbazole, indolocarbazole, 2-, 3- or 4-pyridine, 2-, 4- or 5-pyrimidine, pyrazine, pyridazine, triazine, anthracene, phenanthrene, triphenylene, pyrene, benzanthracene or combinations of two or three of these groups, each of which may be substituted by one or more radicals R¹.

It is particularly preferred for at least one group R to be selected from the structures of the following formulae (3) to (44),

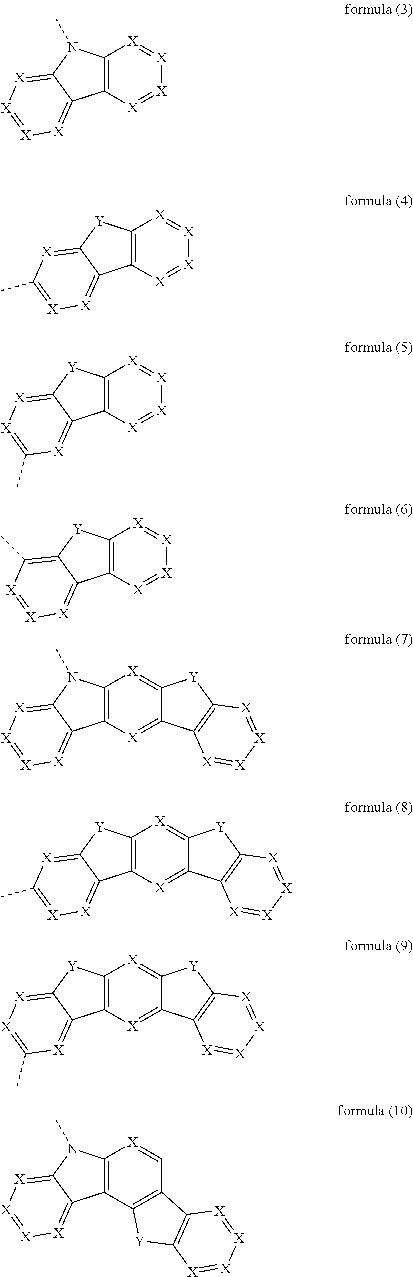

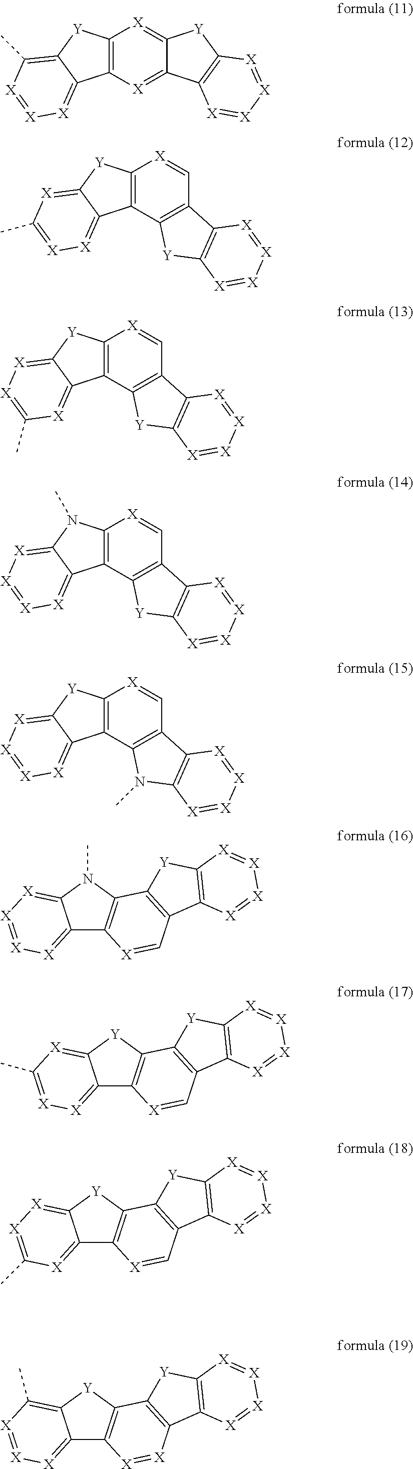

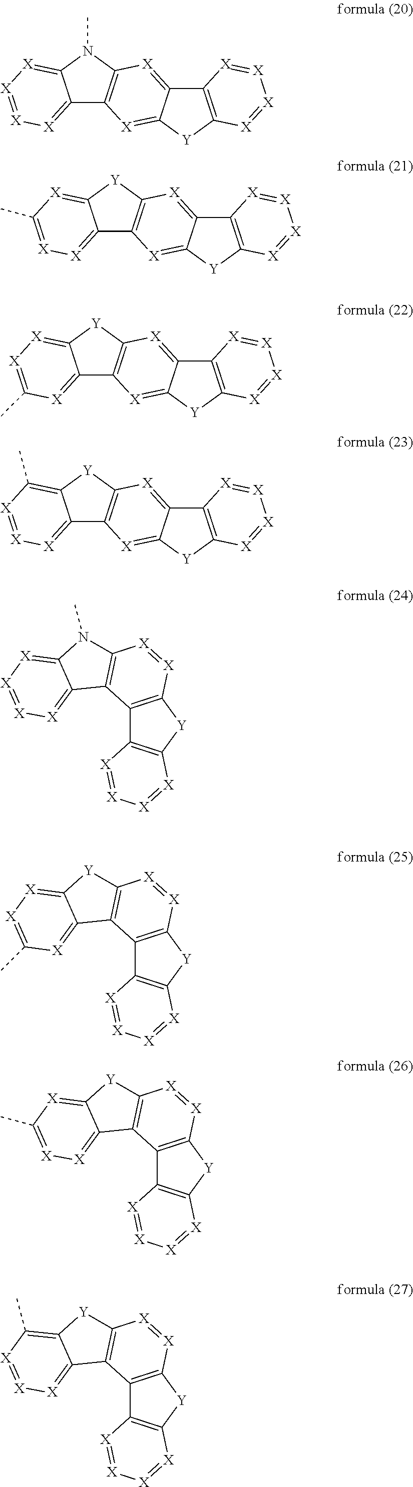

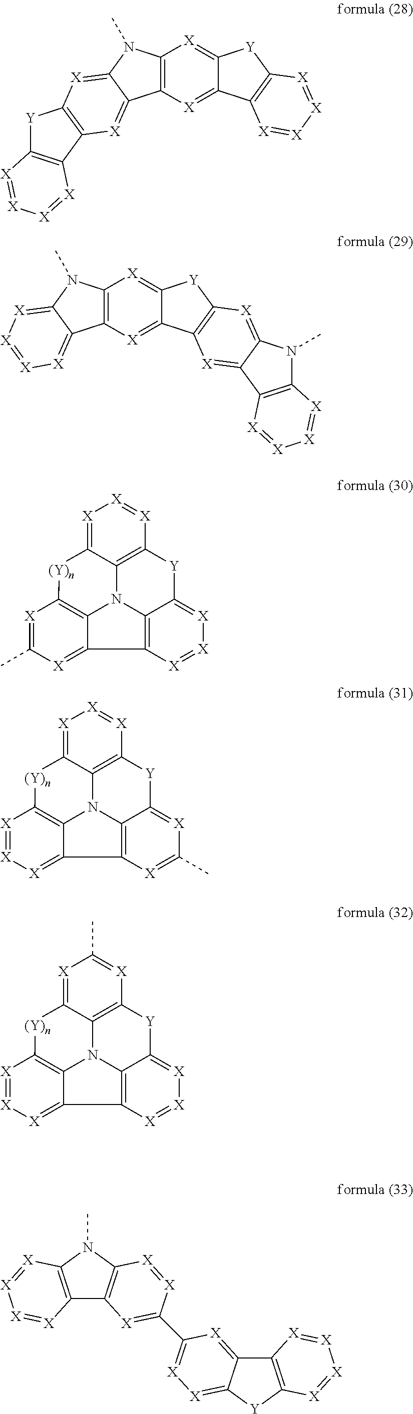

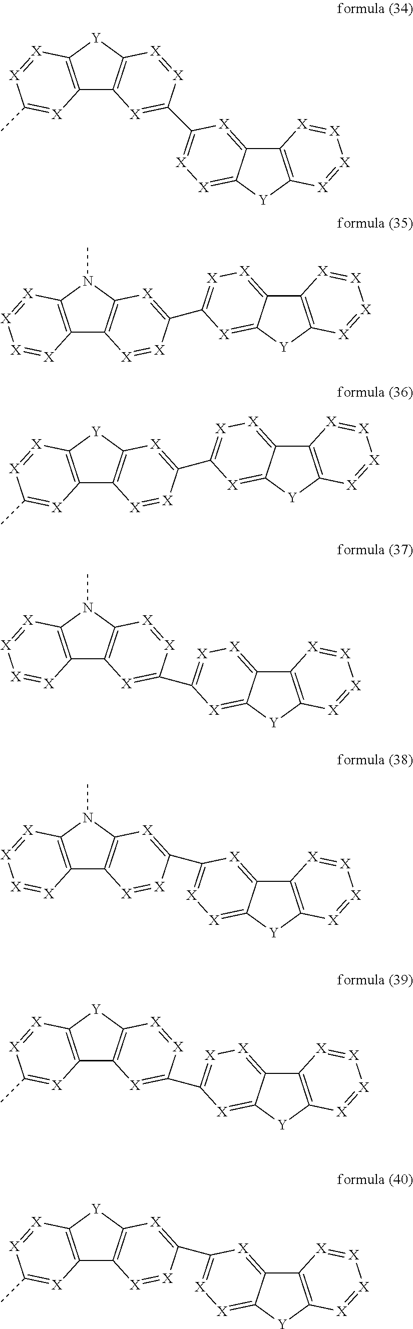

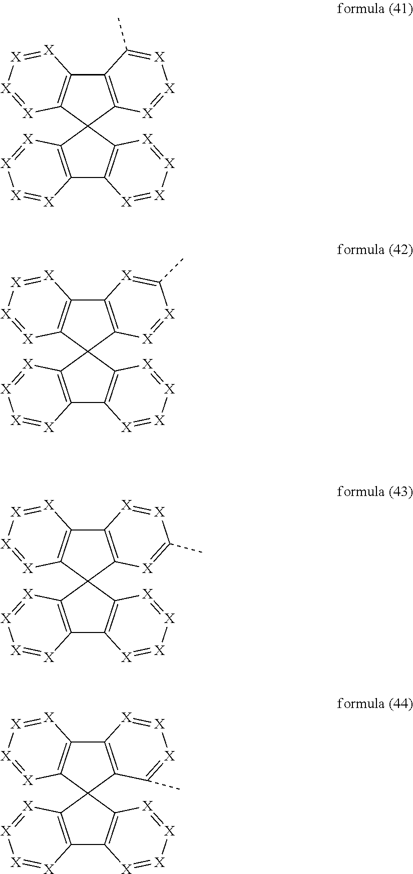

where R¹ and R² have the above-mentioned meanings, the dashed bond represents the bond to the group of the formula (1) or (2), and furthermore:
X is on each occurrence, identically or differently, CR¹ or N, where preferably a maximum of 2 symbols X per ring stand for N;
Y is on each occurrence, identically or differently, C(R¹)₂, NR¹, O or S;
n is 0 or 1, where n equals 0 means that no group Y is bonded at this position and instead radicals R¹ are bonded to the corresponding carbon atoms.

The term “per ring” mentioned above and also used below relates, for the purposes of the present application, to each individual ring present in the compound, i.e. to each individual 5- or 6-membered ring.

In preferred groups of the above-mentioned formulae (3) to (44), a maximum of one symbol X per ring stands for N. The symbol X particularly preferably stands, identically or differently on each occurrence, for CR¹, in particular for CH.

If the groups of the formulae (3) to (44) have a plurality of groups Y, all combinations from the definition of Y are possible for this purpose. Preference is given to groups of the formulae (3) to (44) in which one group Y stands for NR¹ and the other group Y stands for C(R¹)₂ or in which both groups Y stand for NR¹ or in which both groups Y stand for O.

In a further preferred embodiment of the invention, at least one group Y in the formulae (3) to (44) stands, identically or differently on each occurrence, for C(R¹)₂ or for NR¹.

Furthermore preferably, the substituent R¹ which is bonded directly to a nitrogen atom in these groups stands for an aromatic or heteroaromatic ring system having 5 to 24 aromatic ring atoms, which may also be substituted by one or more radicals R². In a particularly preferred embodiment, this substituent R¹ stands, identically or differently on each occurrence, for an aromatic or heteroaromatic ring system having 6 to 24 aromatic ring atoms which has no condensed aryl groups and which has no condensed heteroaryl groups in which two or more aromatic or heteroaromatic 6-membered ring groups are condensed directly onto one another and which may in each case also be substituted by one or more radicals R².

If Y stands for C(R¹)₂, R¹ preferably stands, identically or differently on each occurrence, for a linear alkyl group having 1 to 10 C atoms or for a branched or cyclic alkyl group having 3 to 10 C atoms or for an aromatic or heteroaromatic ring system having 5 to 24 aromatic ring atoms, which may also be substituted by one or more radicals R². R¹ very particularly preferably stands for a methyl group or for a phenyl group.

Furthermore, it may be preferred for the group of the above-mentioned formulae (3) to (44) not to bond directly to the triazine in formula (1) or the pyrimidine in formula (2), but instead via a bridging group. This bridging group is then preferably selected from an aromatic or heteroaromatic ring system having 5 to 24 aromatic ring atoms, in particular having 6 to 12 aromatic ring atoms, which may in each case be substituted by one or more radicals R¹.

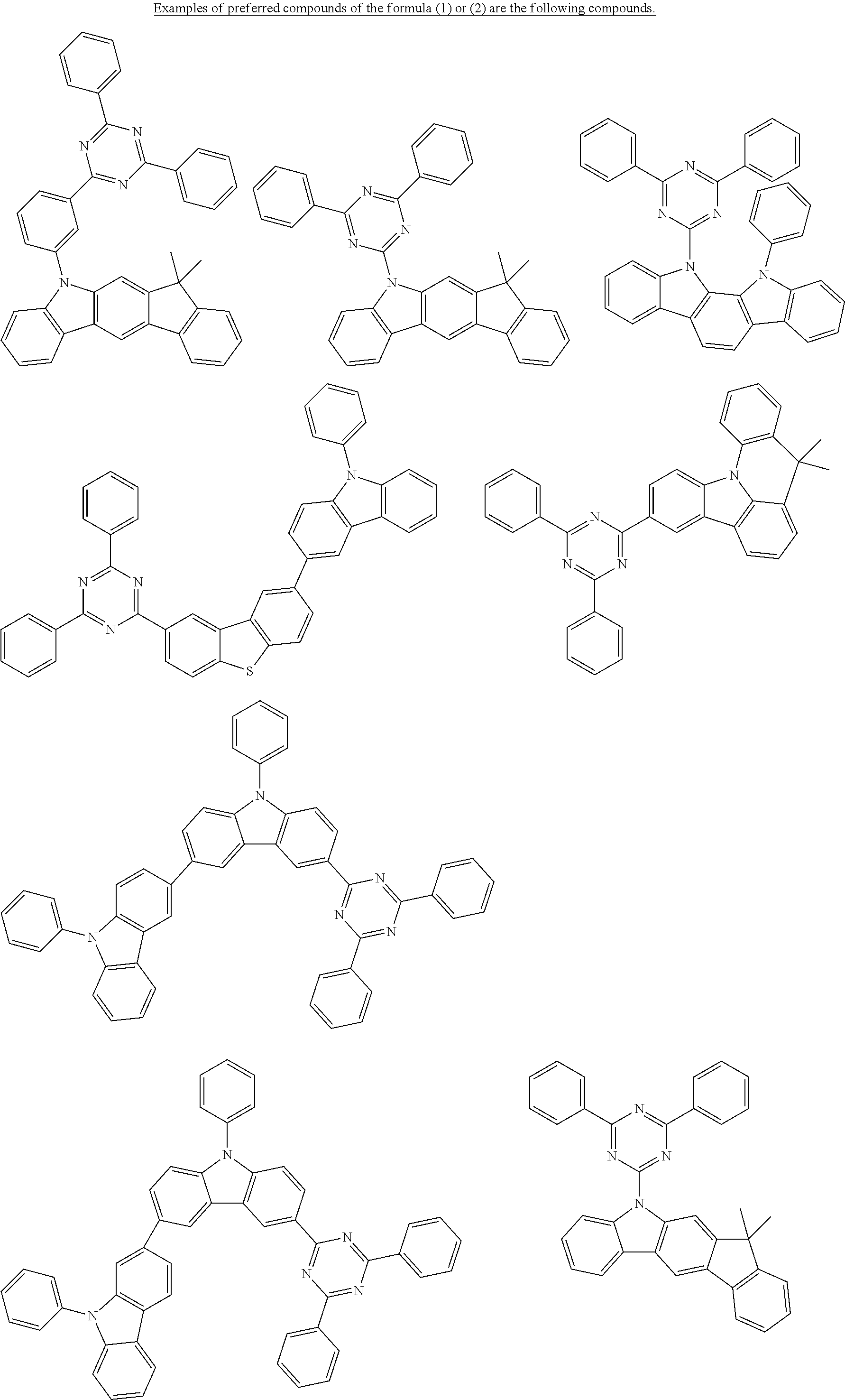

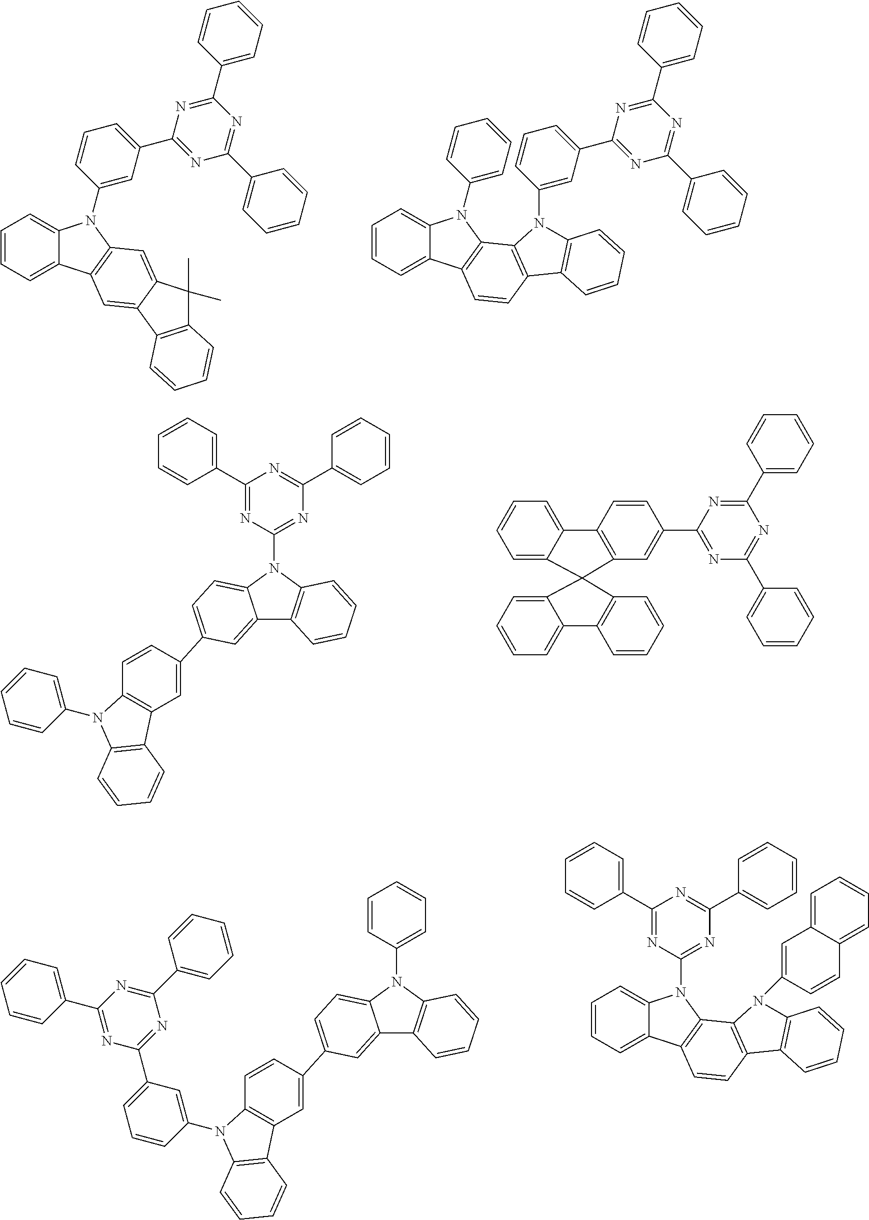

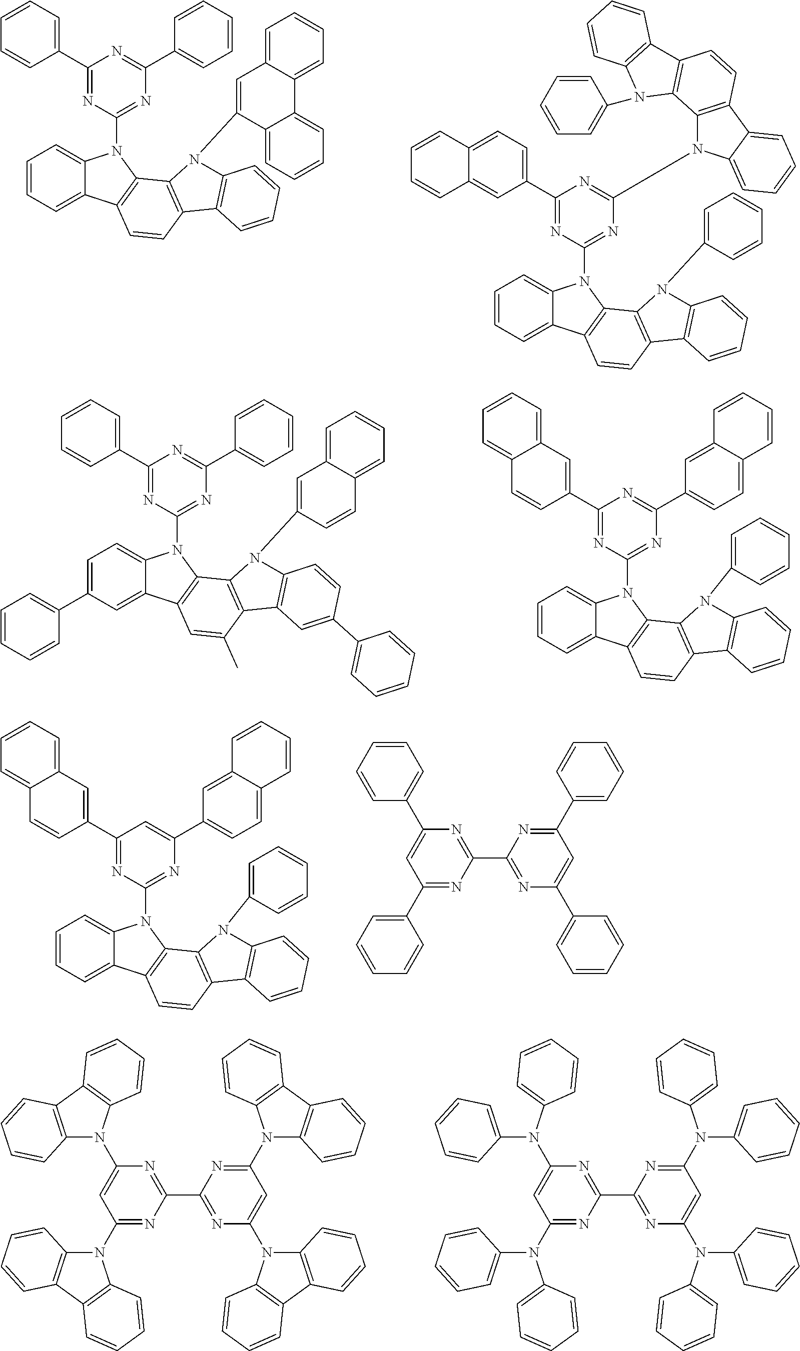

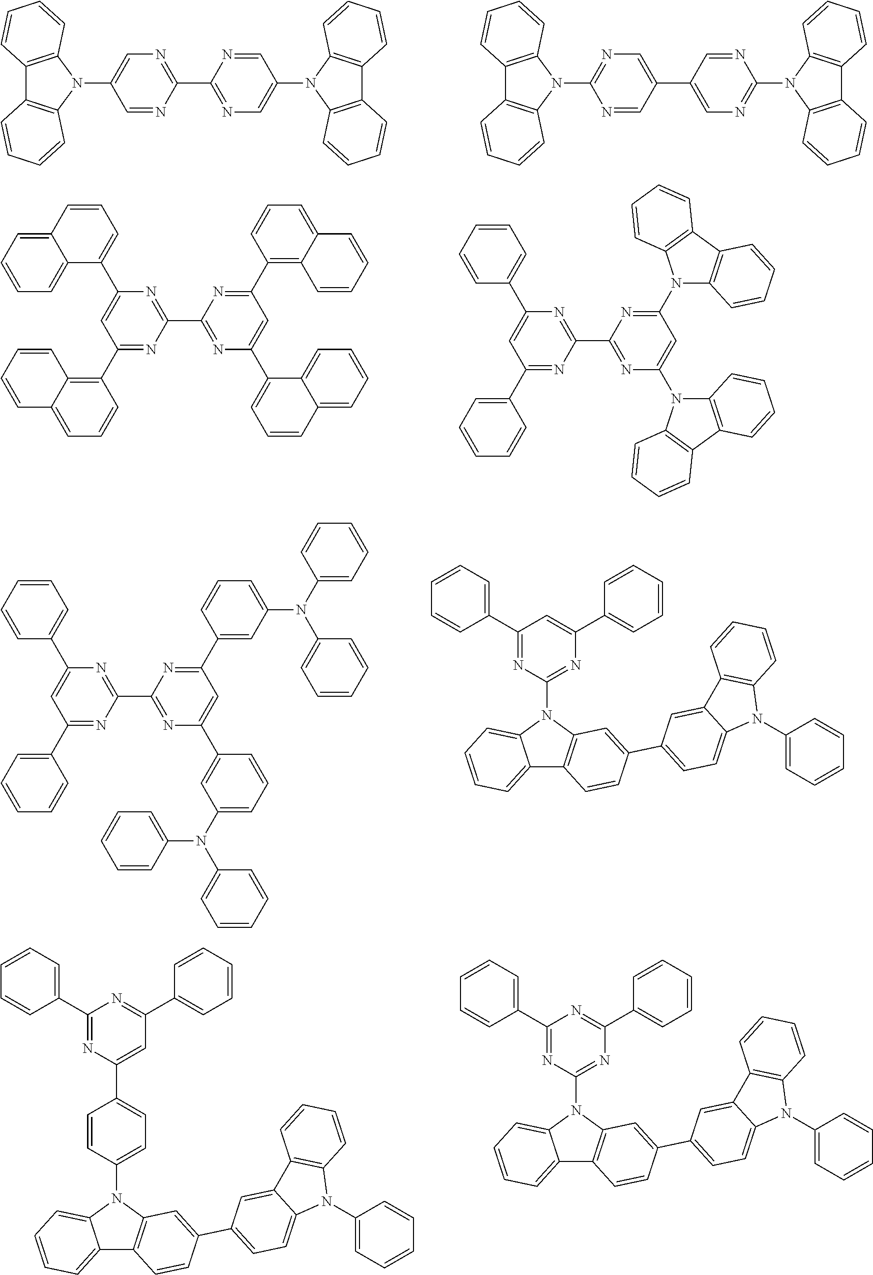

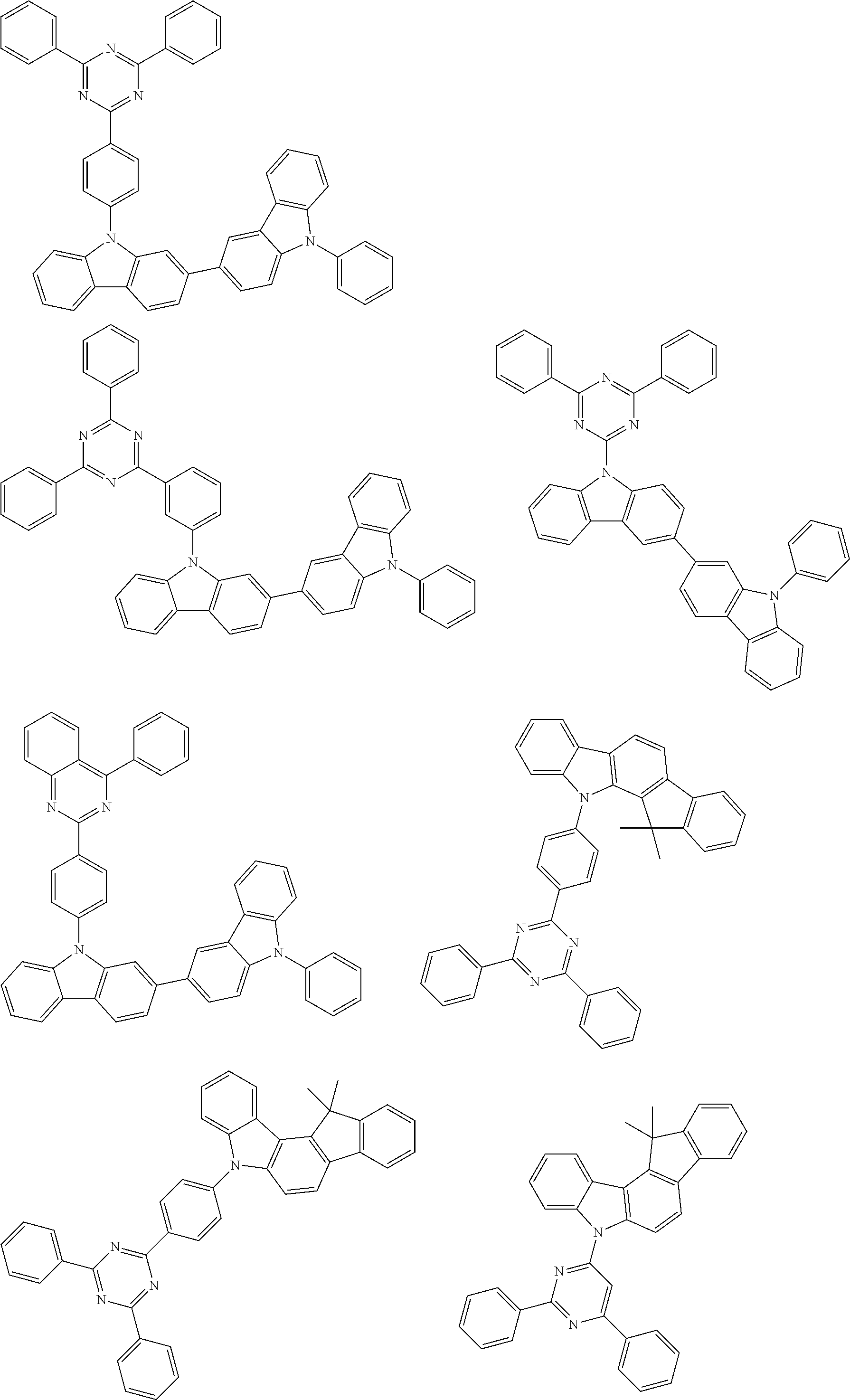

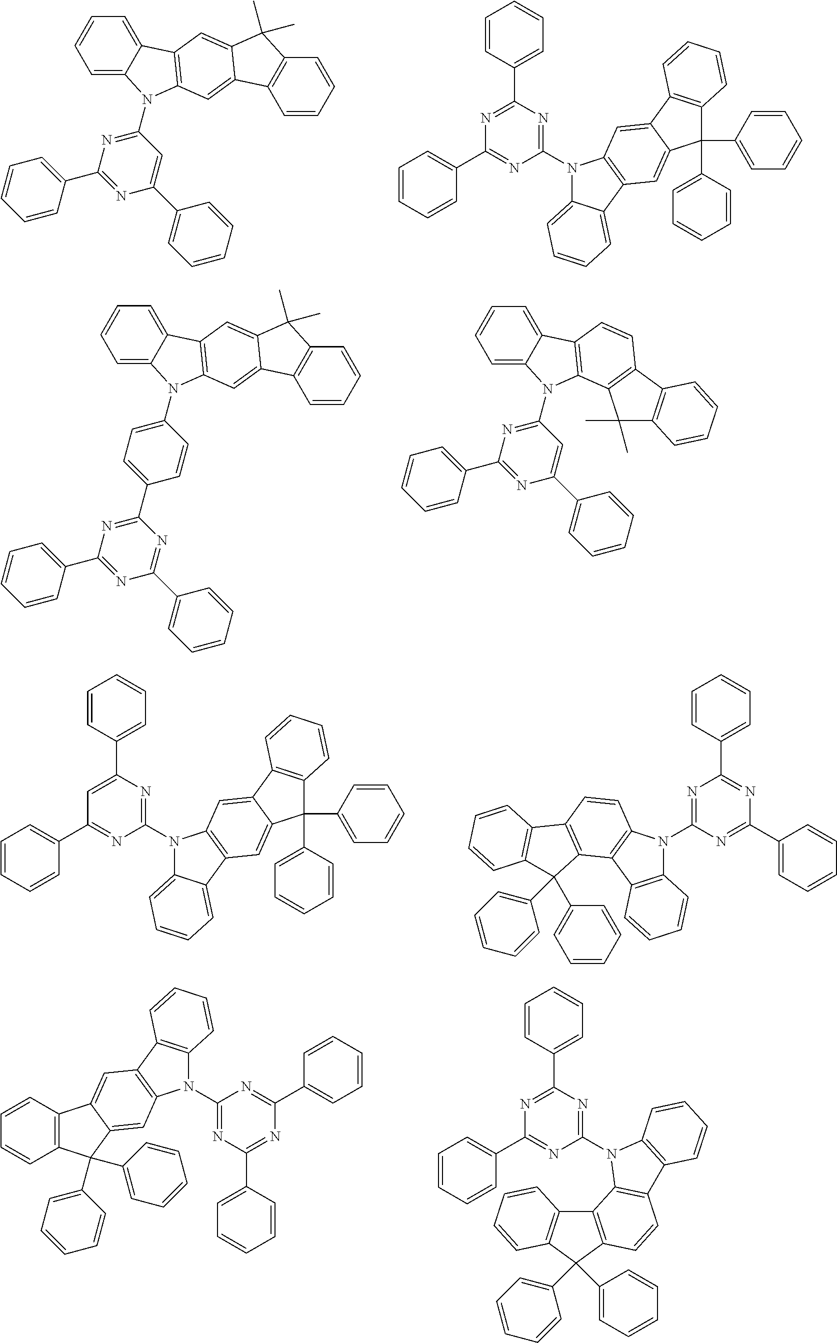

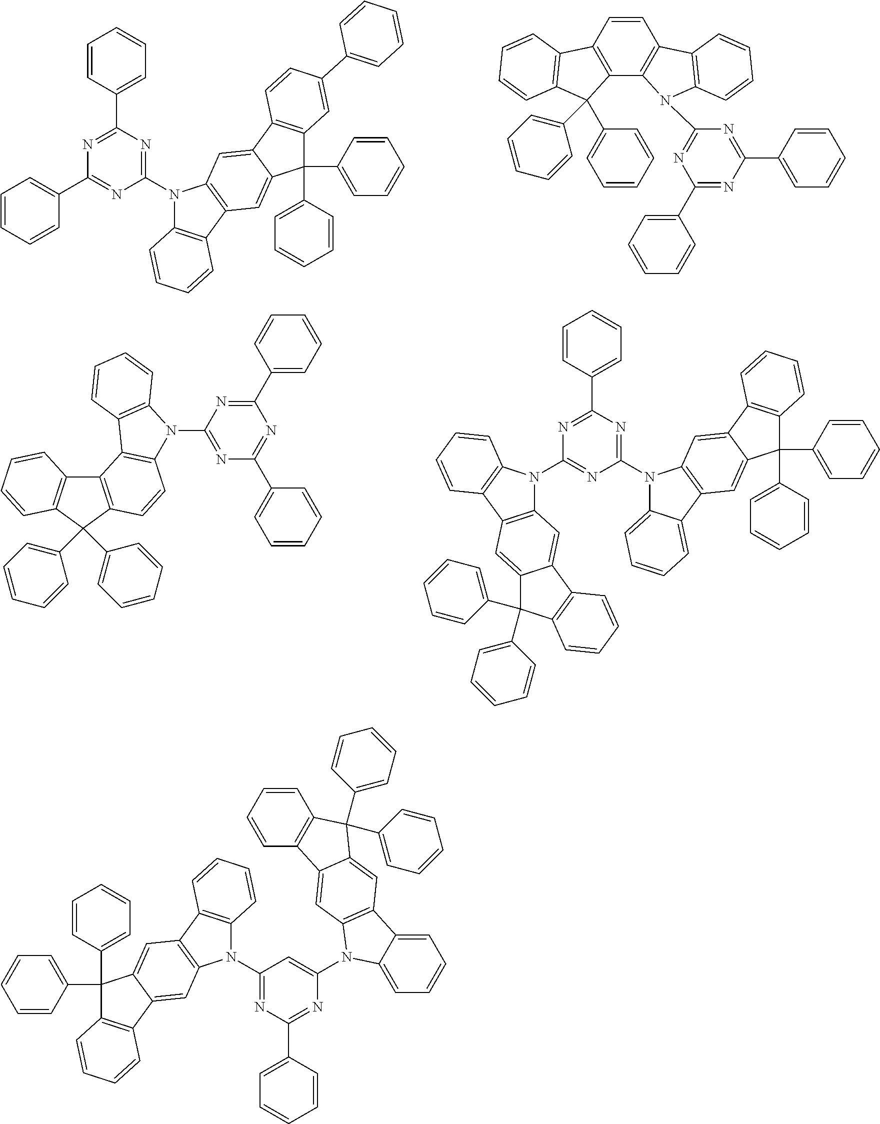

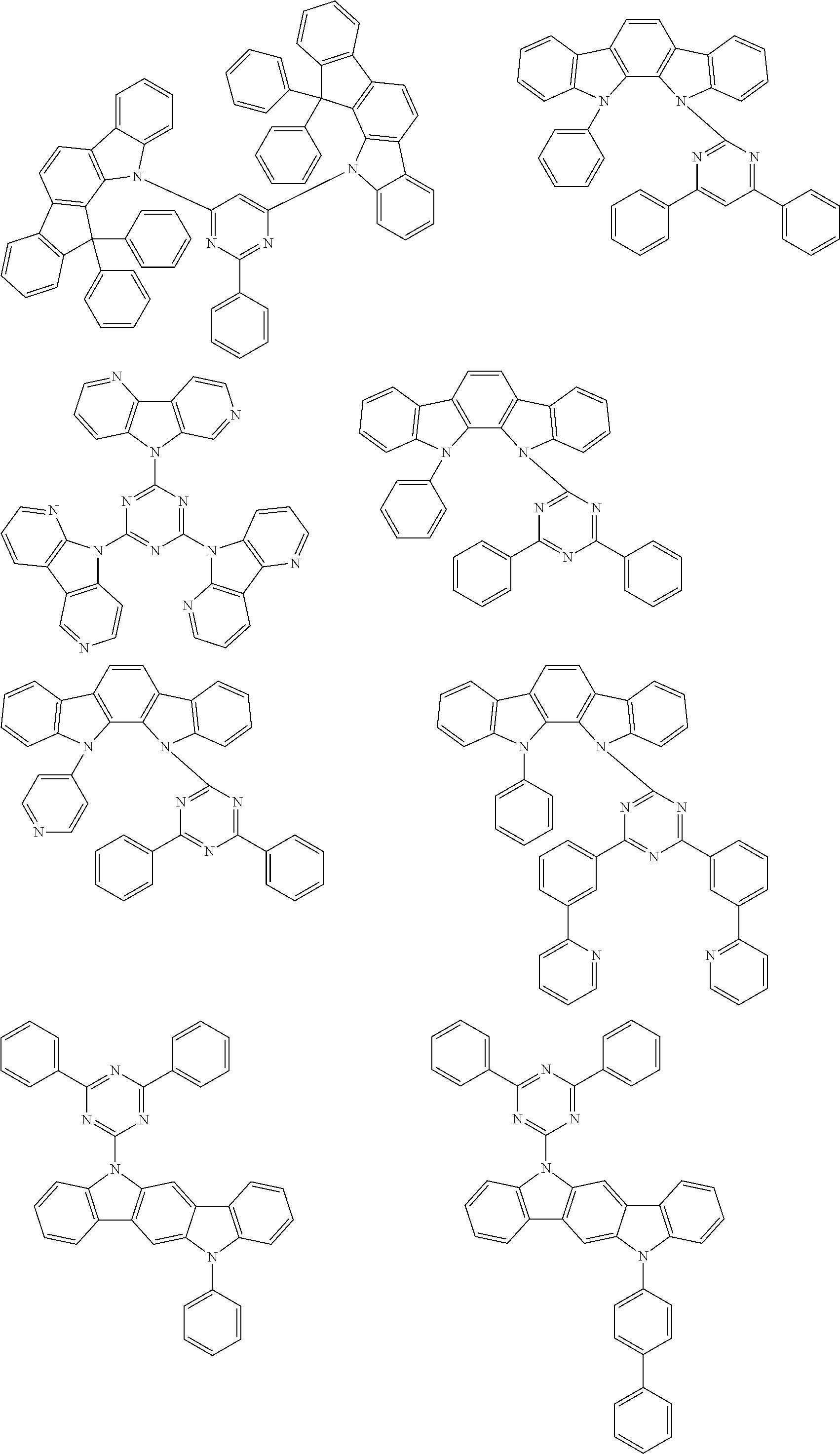

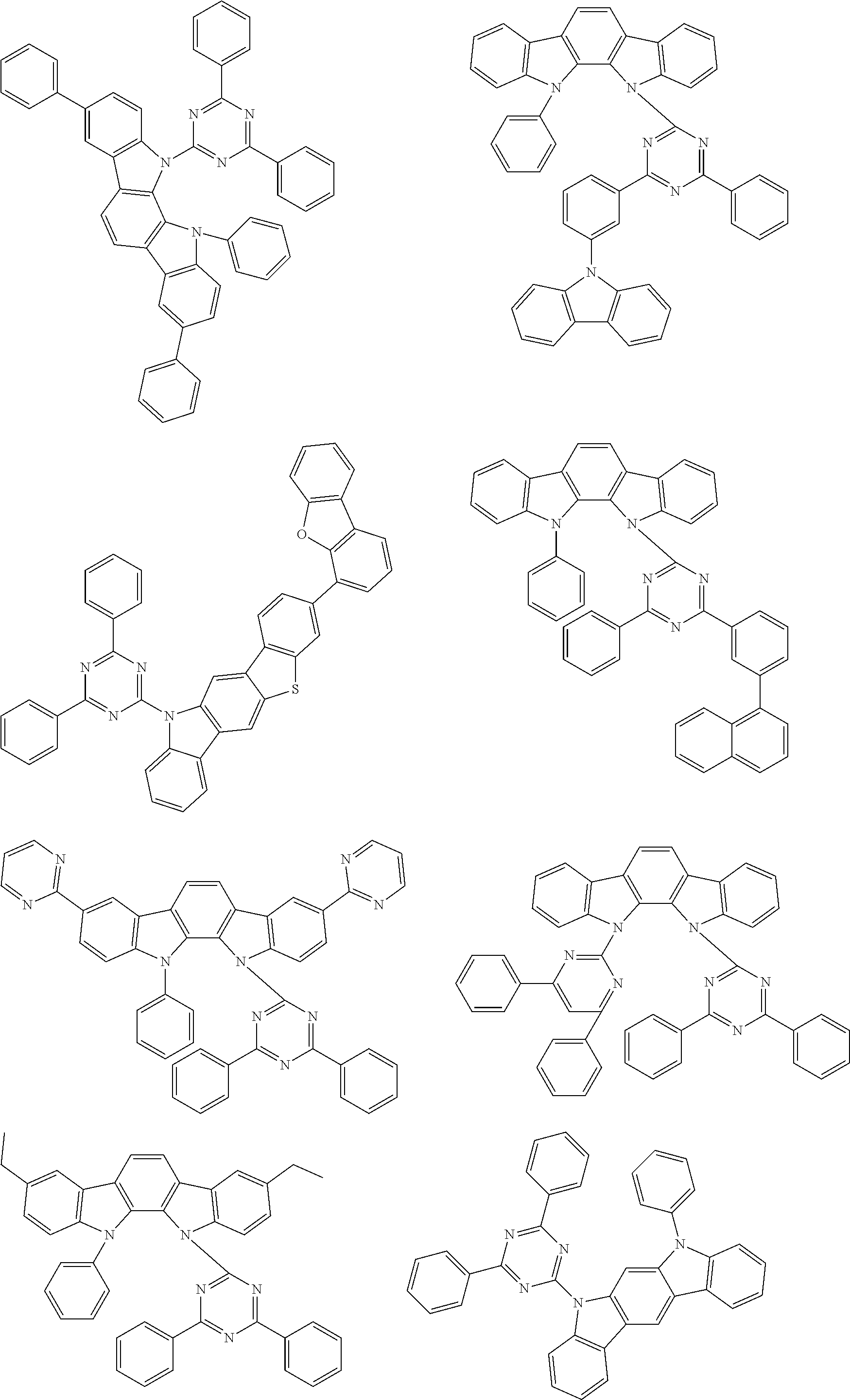

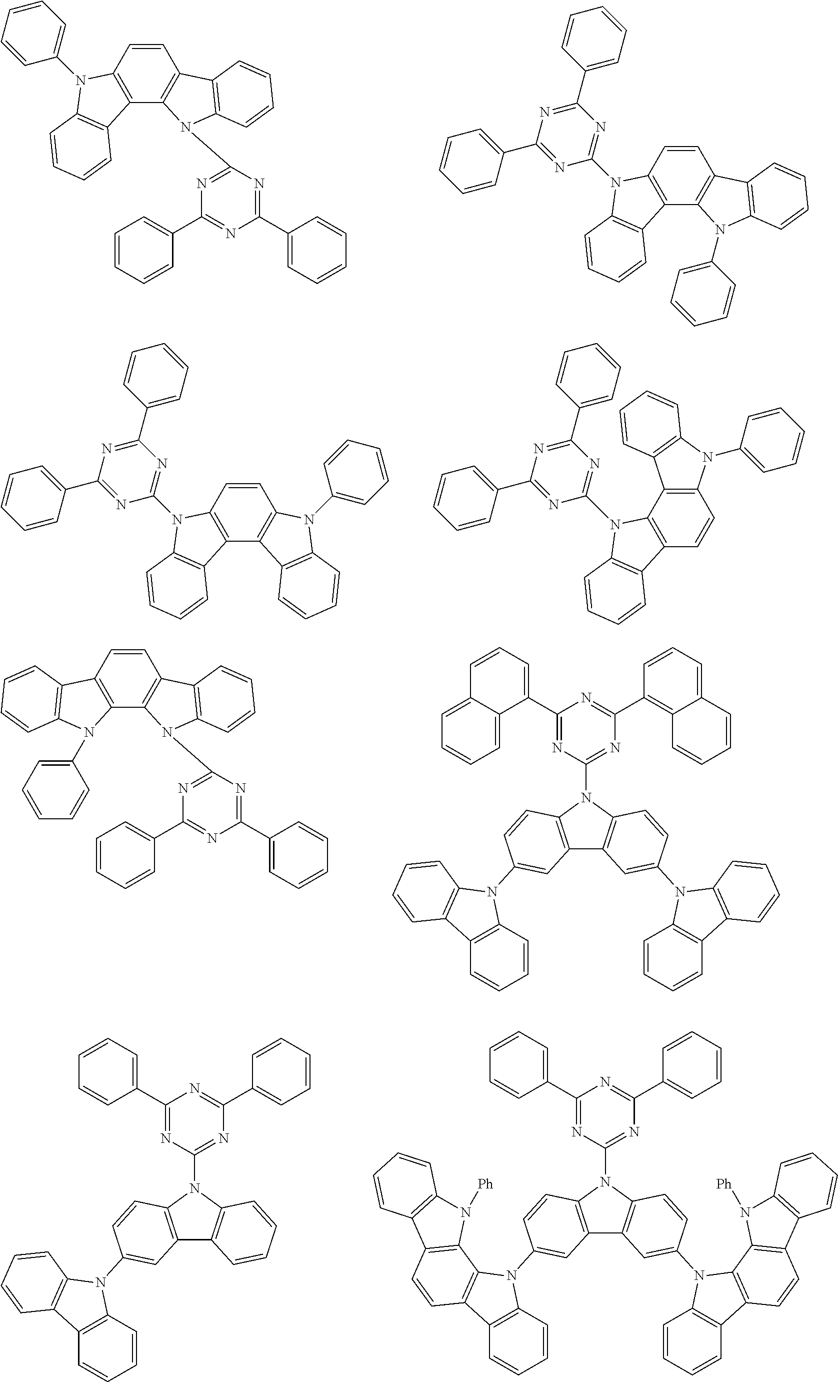

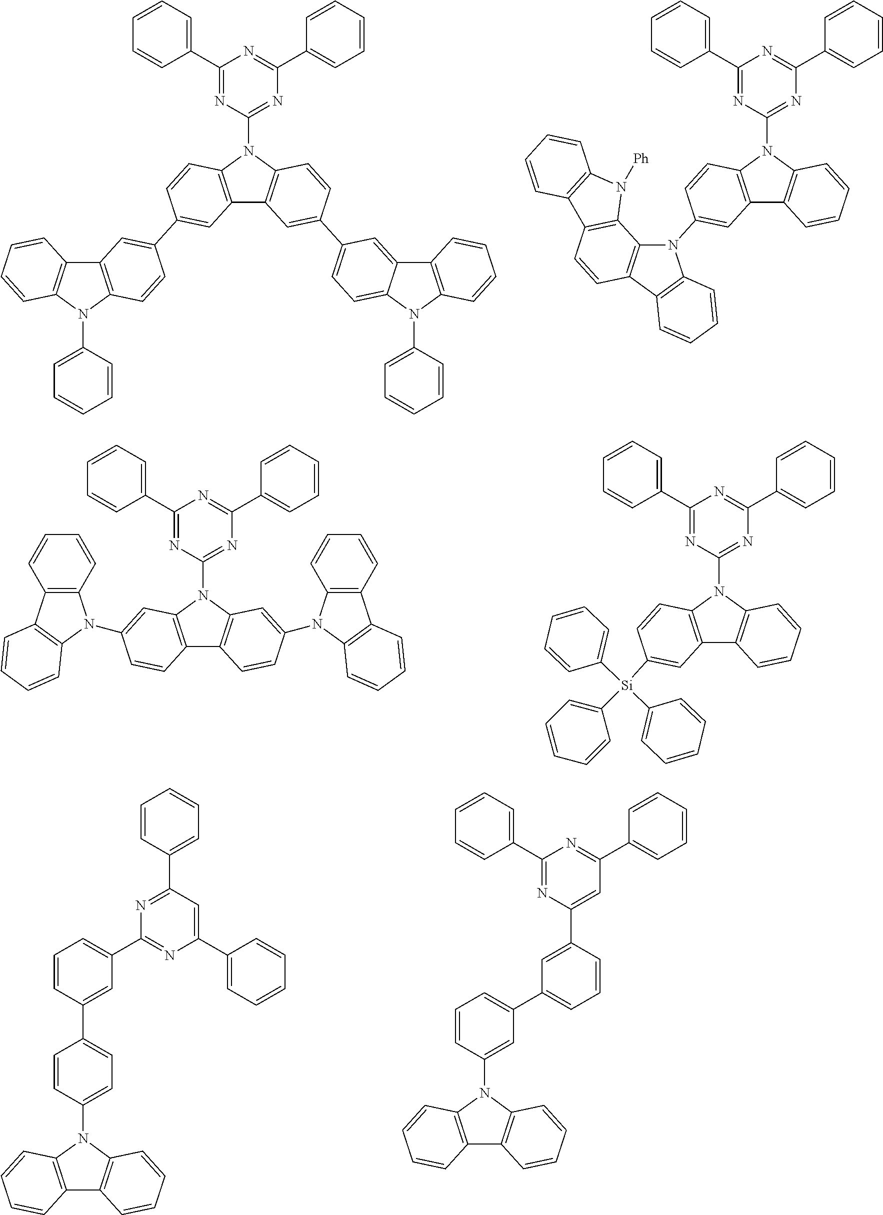

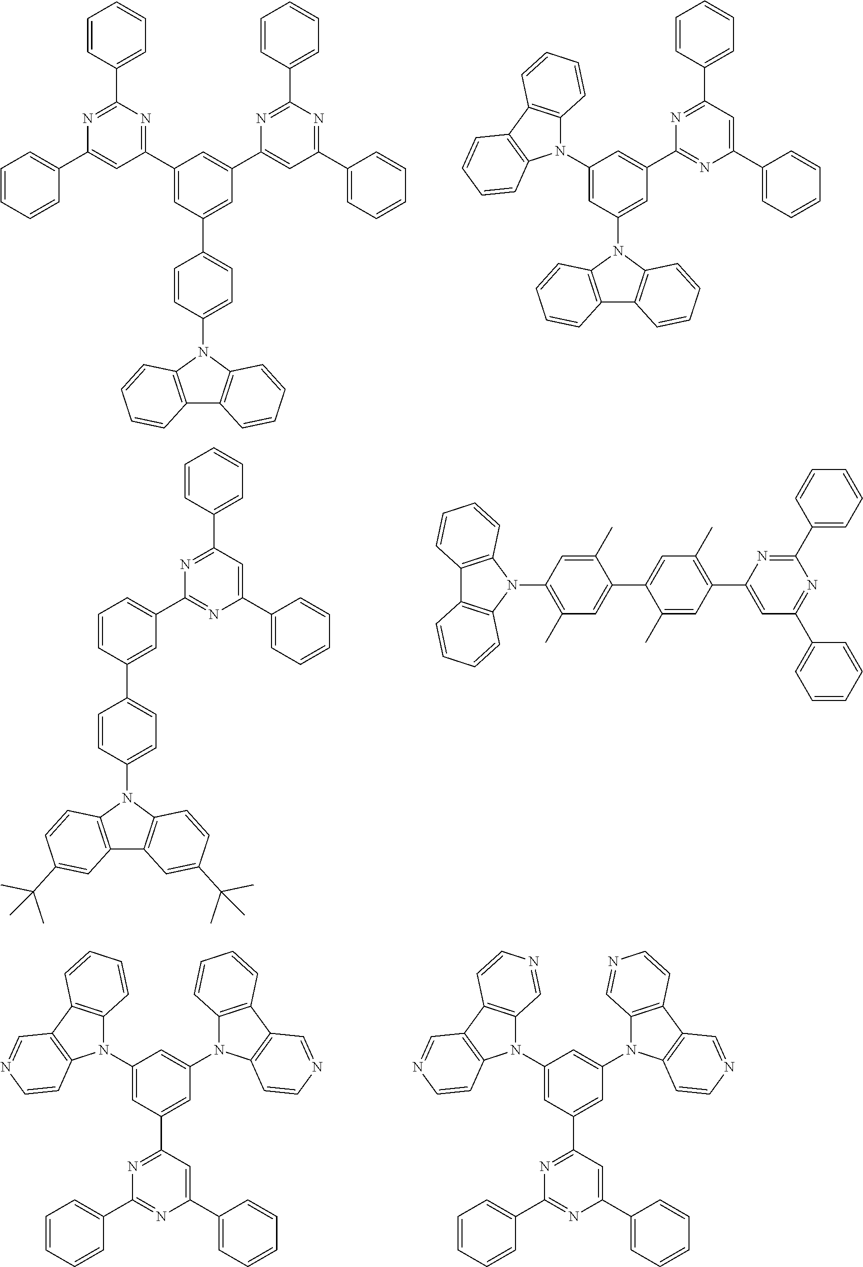

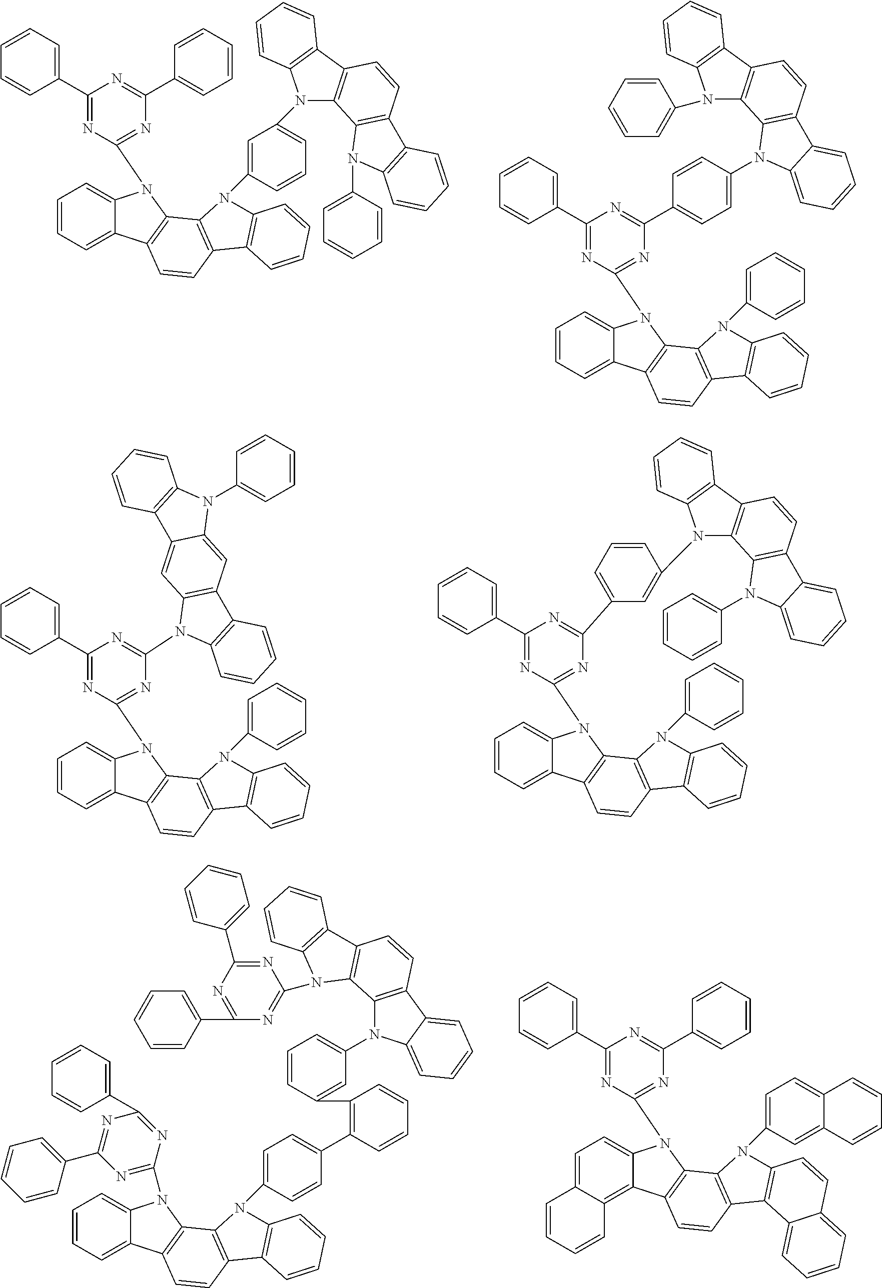

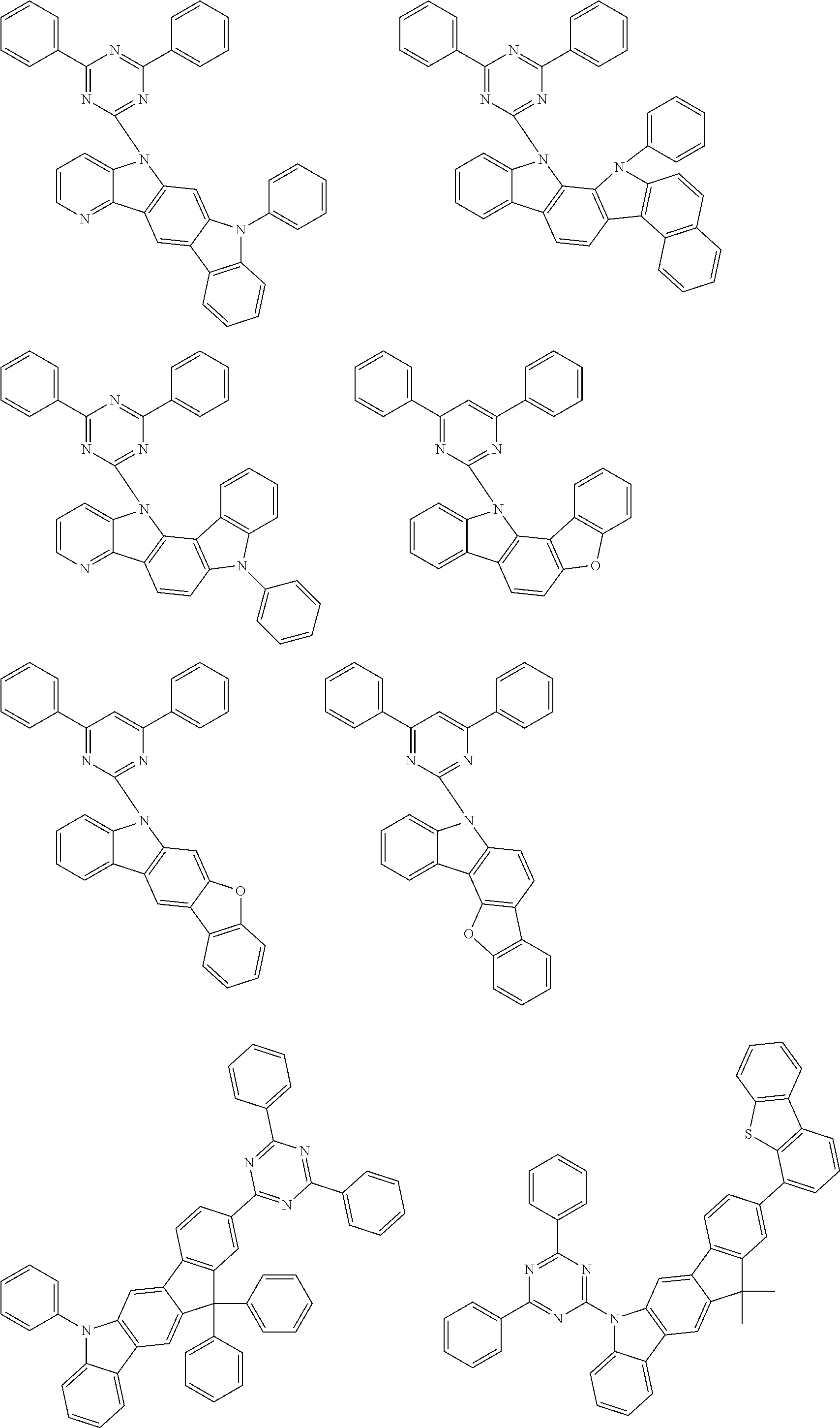

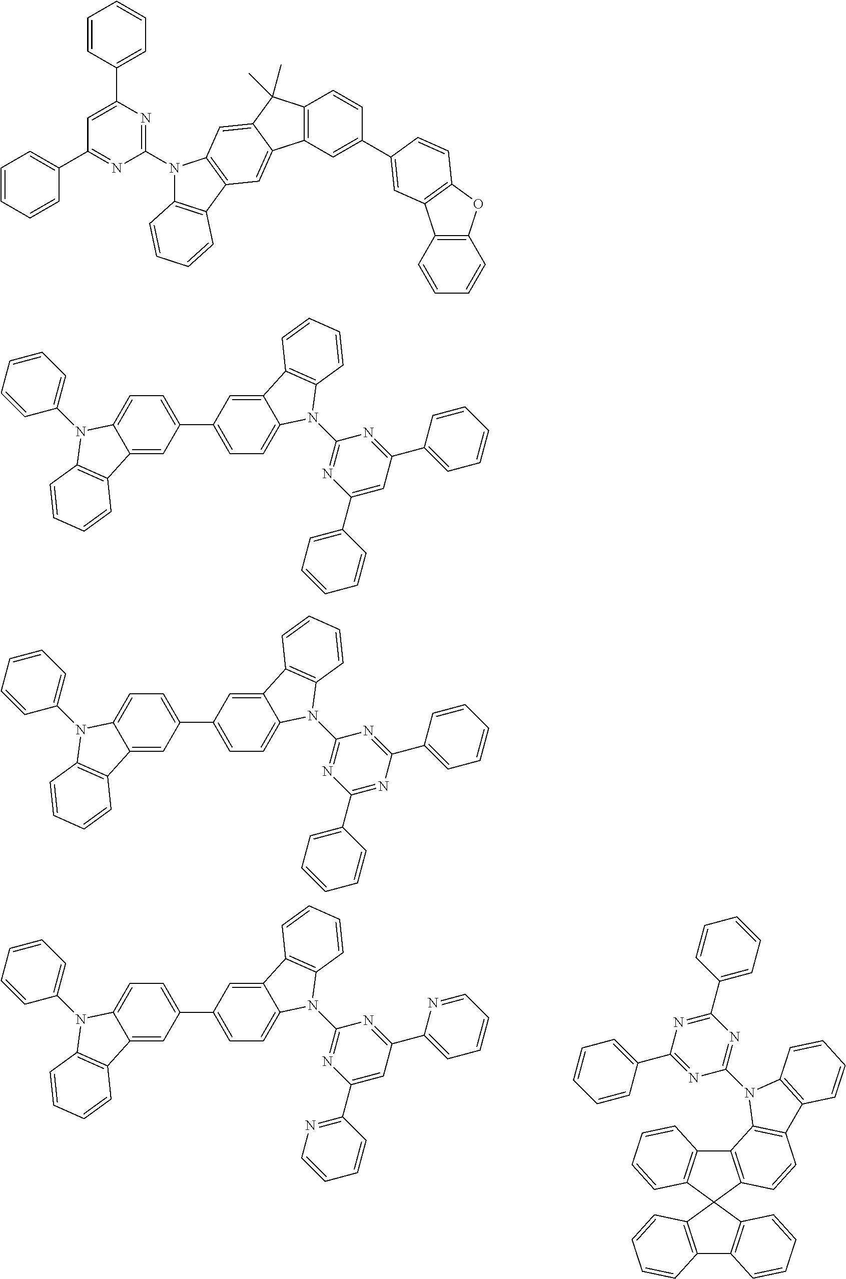

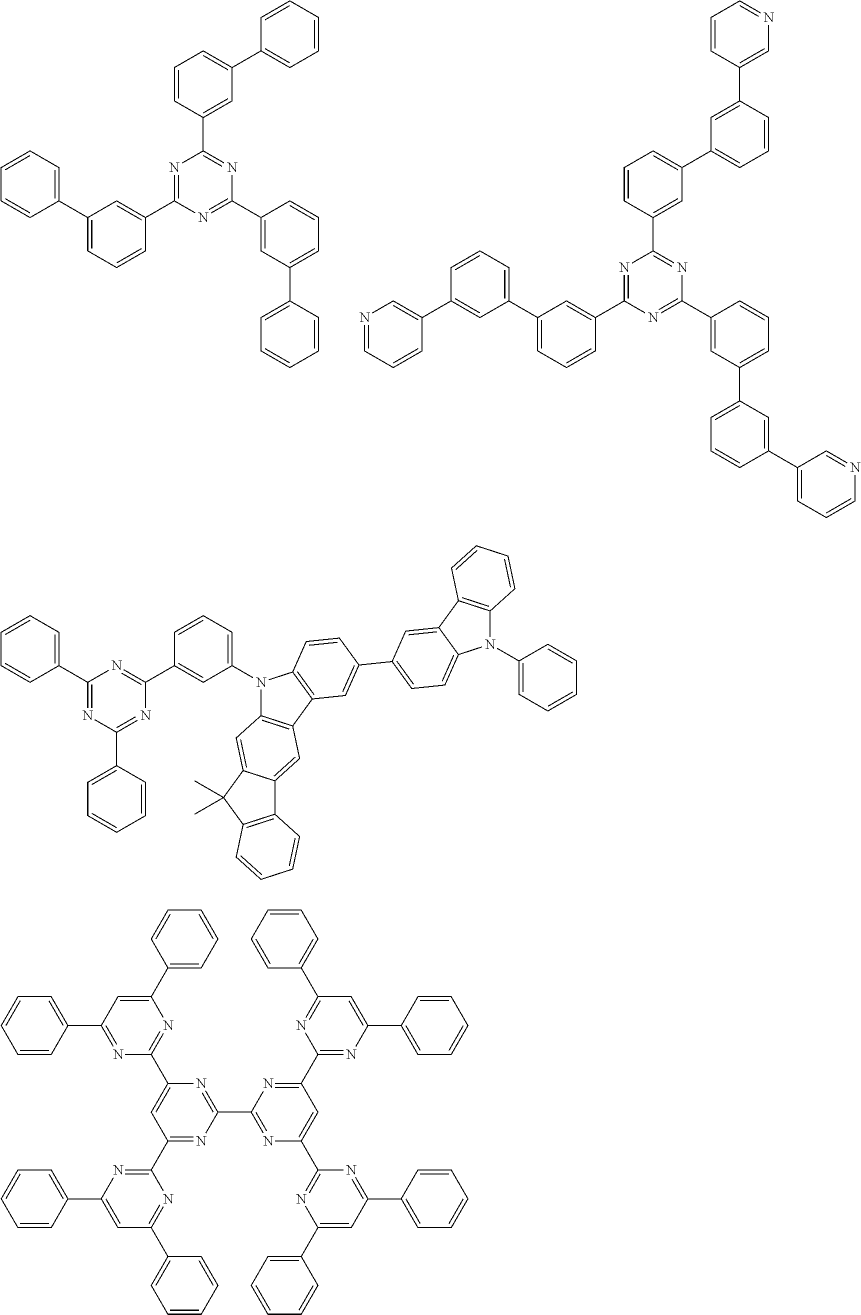

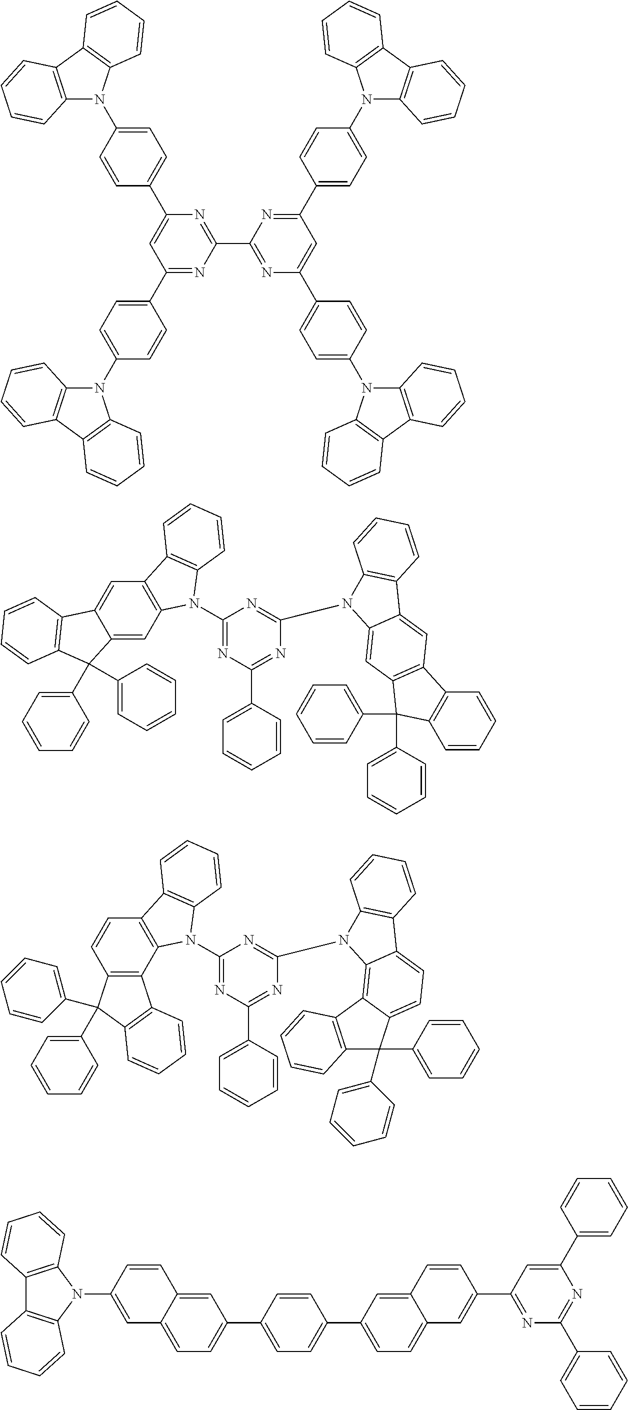

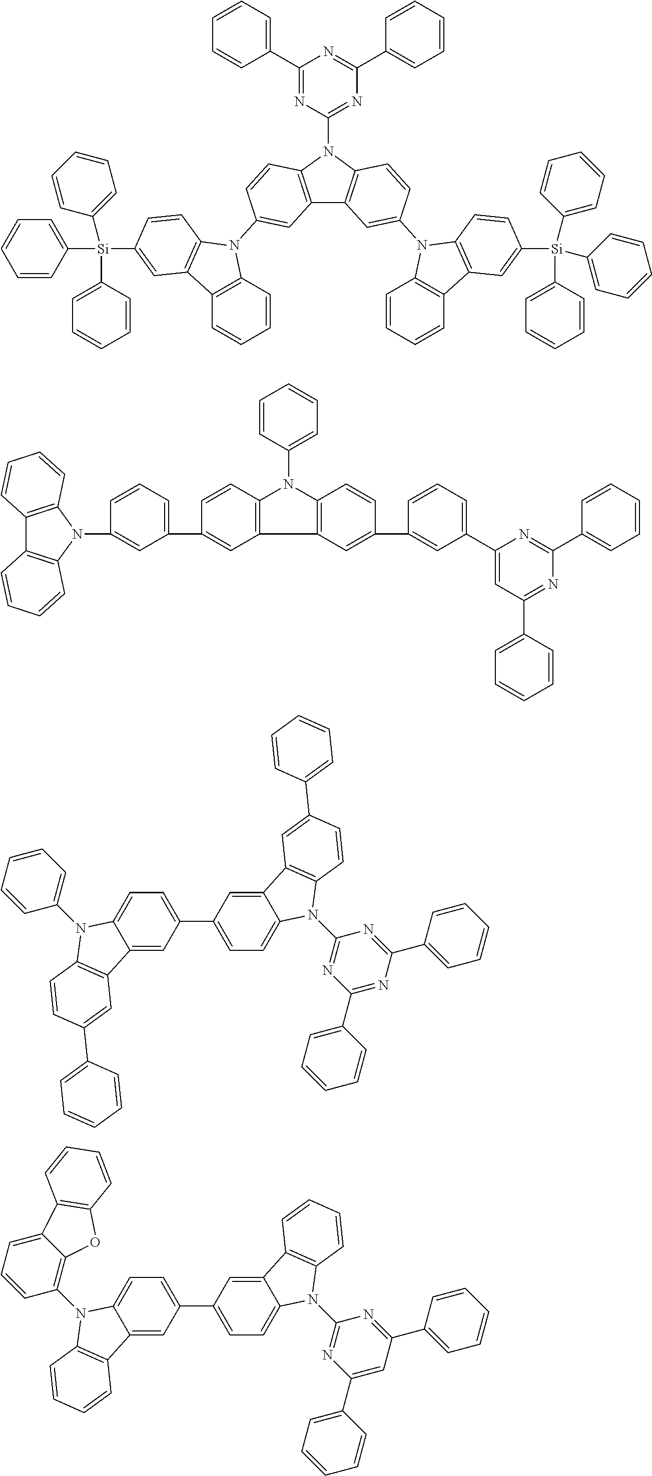

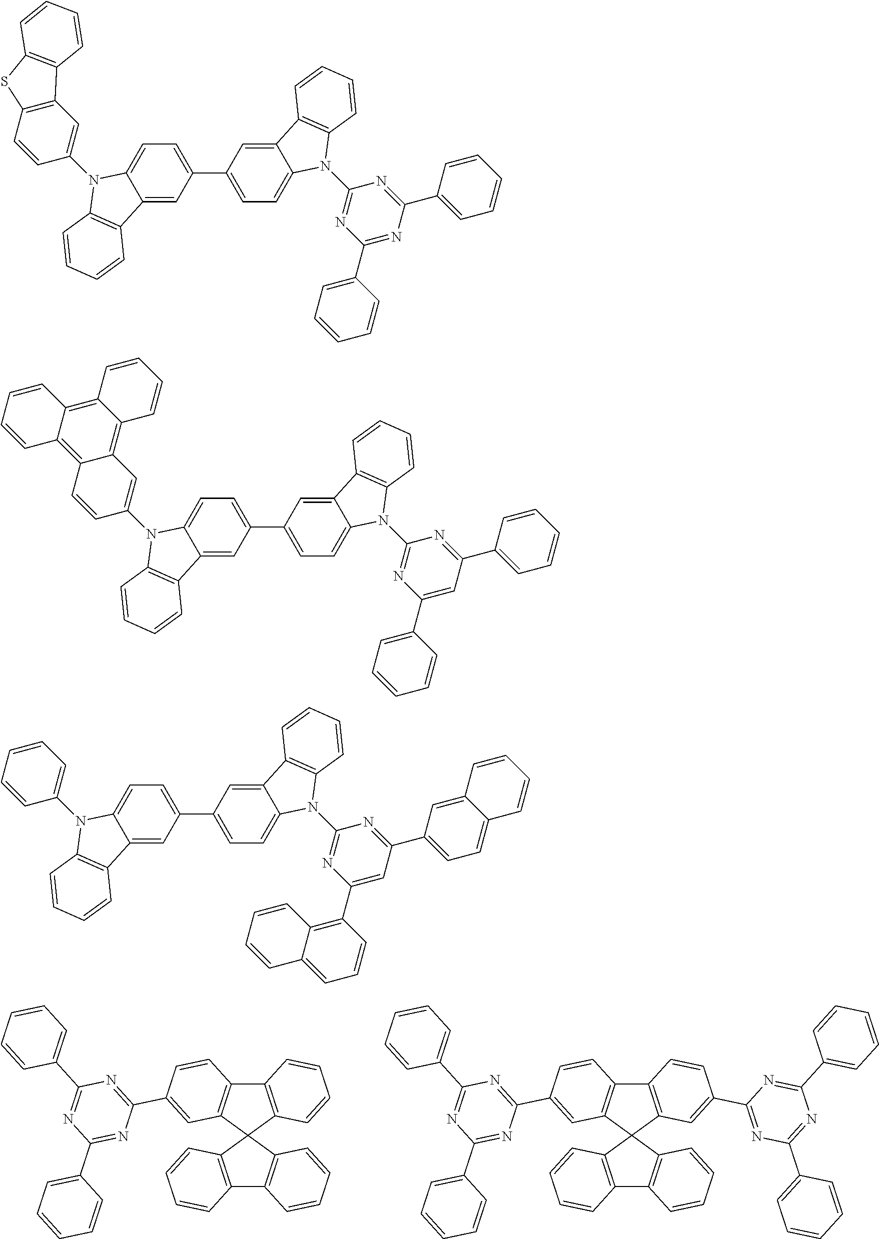 [SMILES: c1ccc(-c2nc(-c3ccccc3)nc(-n3c4ccccc4c4cc(-c5ccc6c(c5)c5ccccc5n6-c5ccc6sc7ccccc7c6c5)ccc43)n2)cc1 ; c1ccc(-c2cc(-c3ccccc3)nc(-n3c4ccccc4c4cc(-c5ccc6c(c5)c5ccccc5n6-c5ccc6c7ccccc7c7ccccc7c6c5)ccc43)n2)cc1 ; c1ccc(-n2c3ccccc3c3cc(-c4ccc5c(c4)c4ccccc4n5-c4nc(-c5ccc6ccccc6c5)cc(-c5cccc6ccccc56)n4)ccc32)cc1 ; c1ccc(-c2nc(-c3ccccc3)nc(-c3ccc4c(c3)C3(c5ccccc5-c5ccccc53)c3ccccc3-4)n2)cc1 ; c1ccc(-c2nc(-c3ccccc3)nc(-c3ccc4c(c3)C3(c5ccccc5-c5ccccc53)c3cc(-c5nc(-c6ccccc6)nc(-c6ccccc6)n5)ccc3-4)n2)cc1]

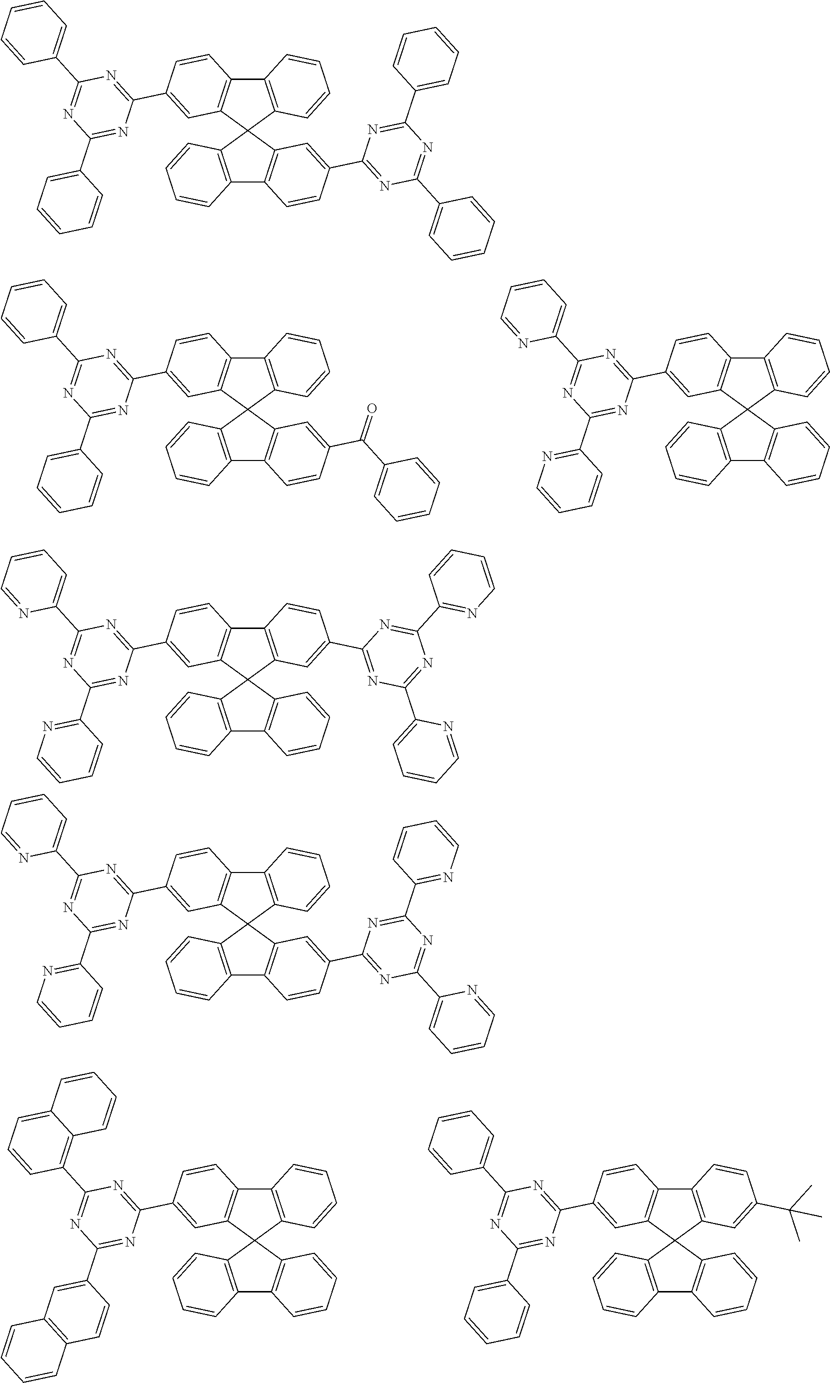

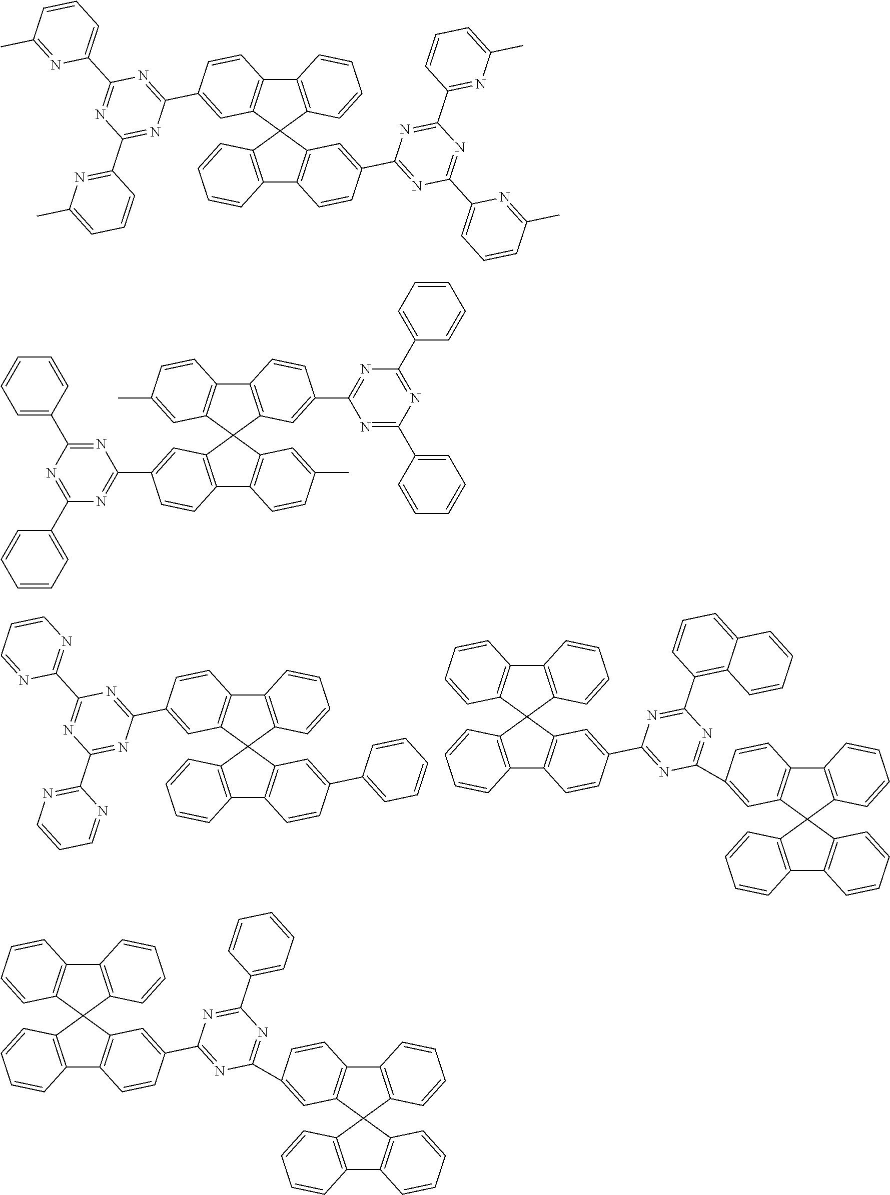

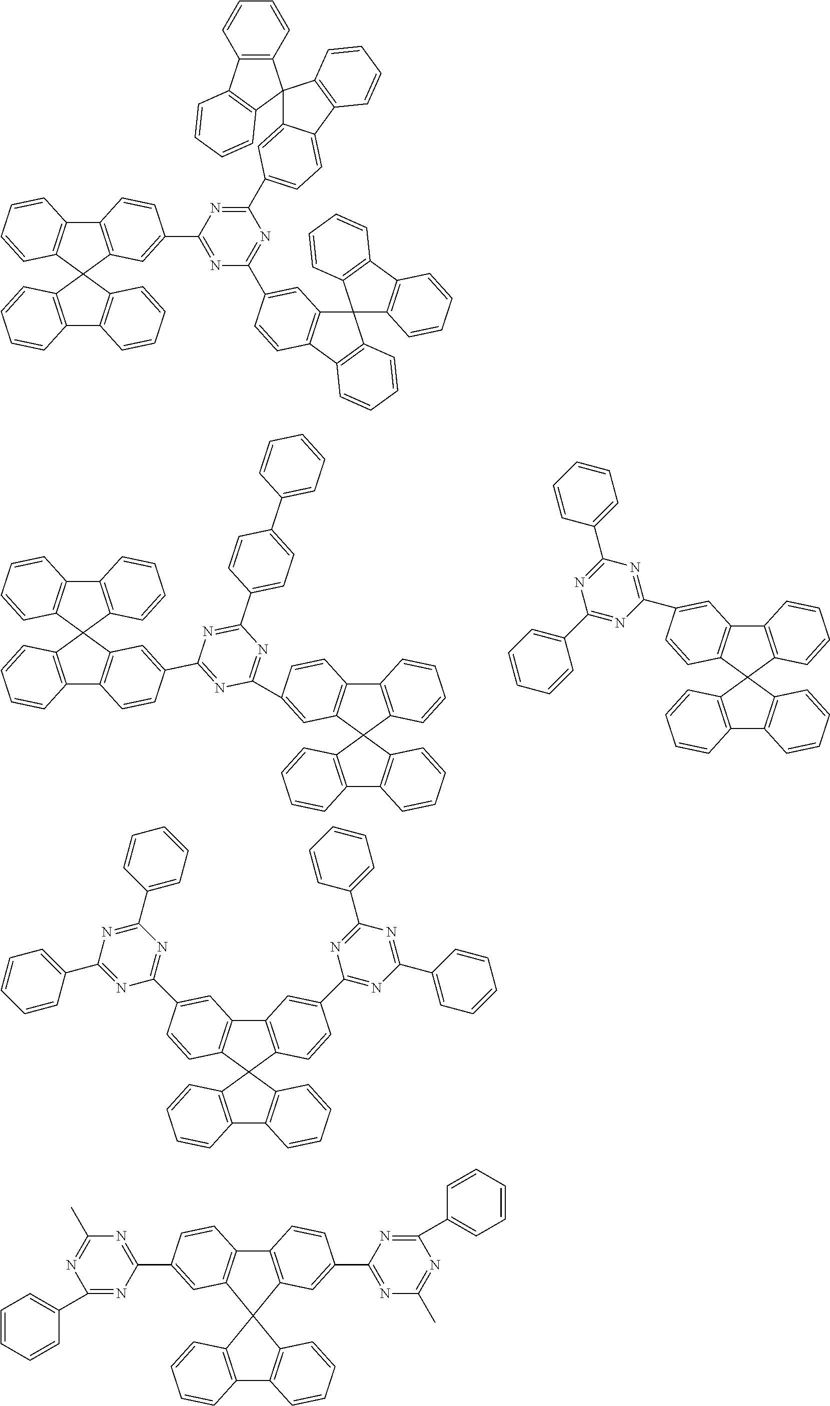

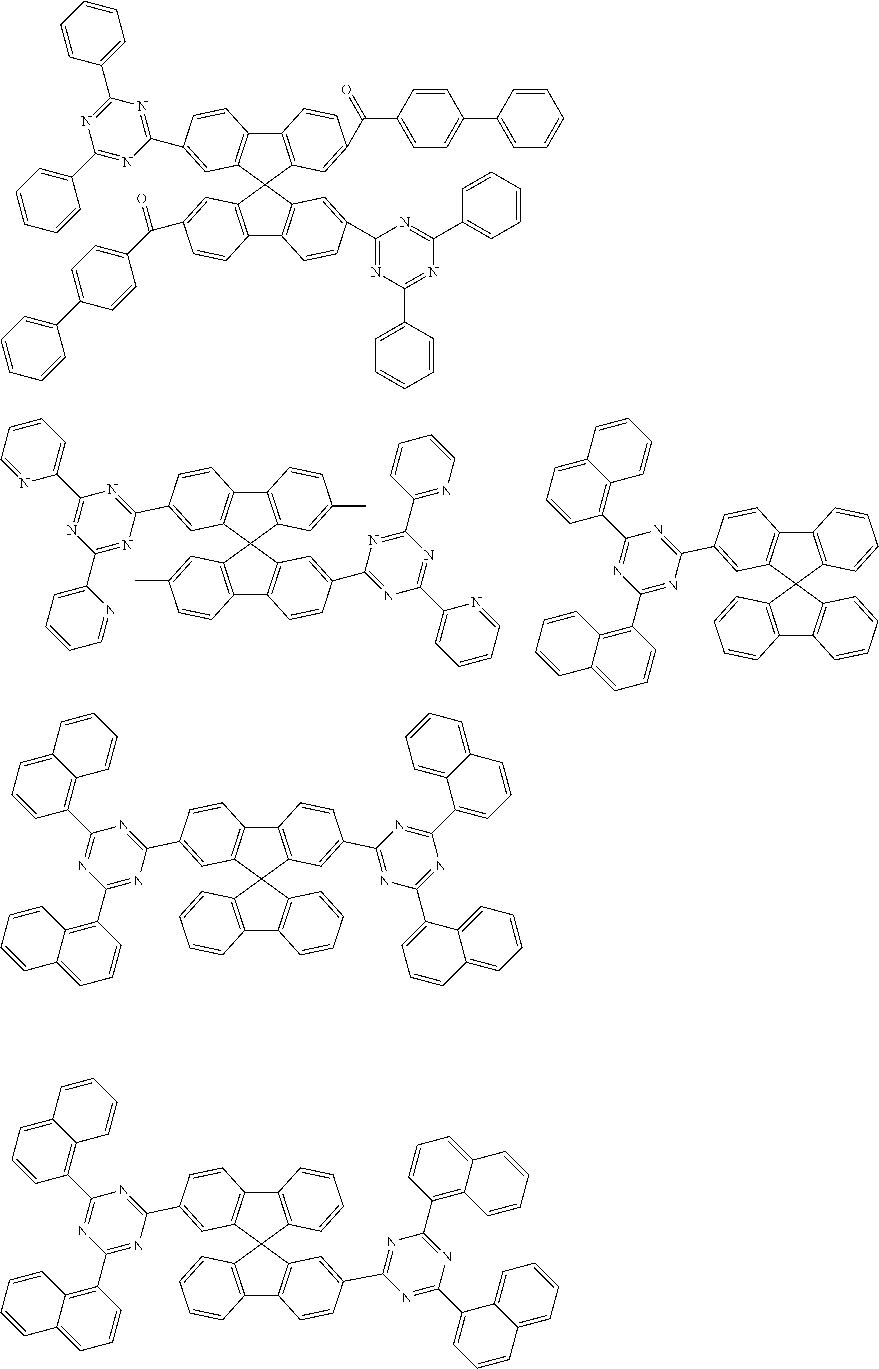

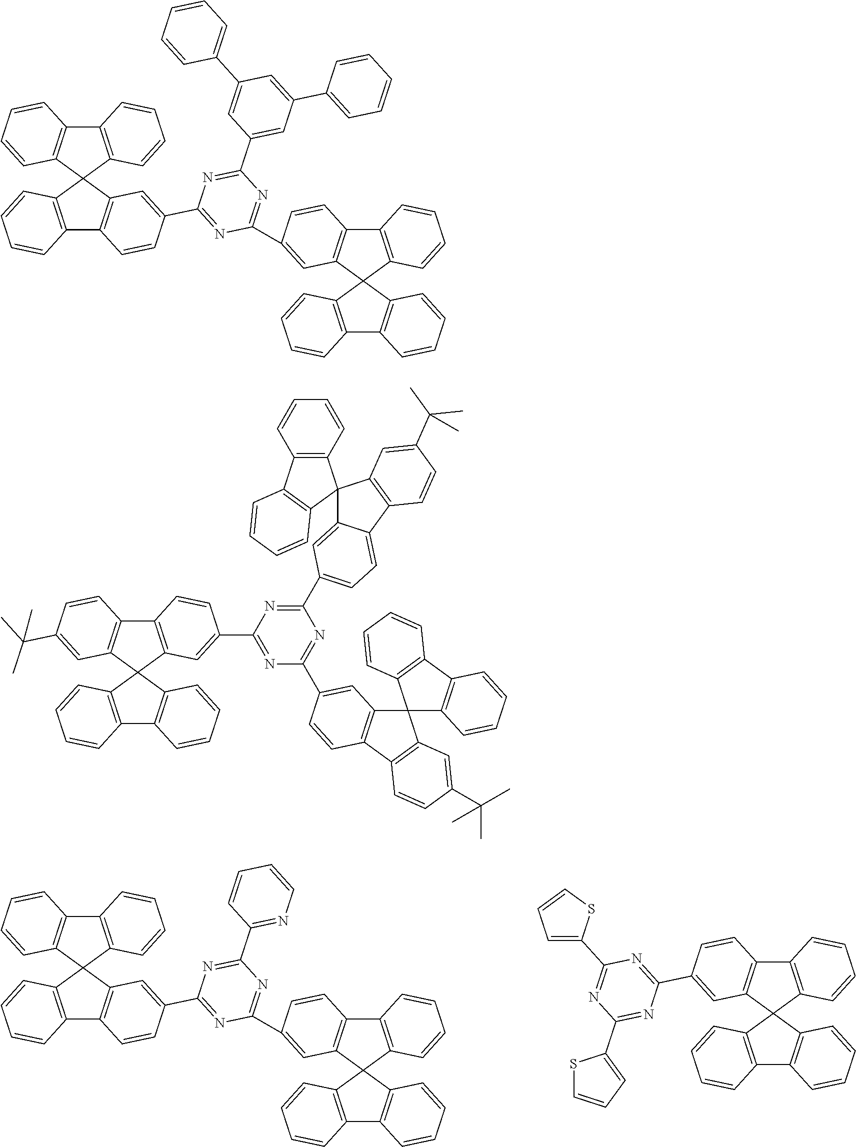

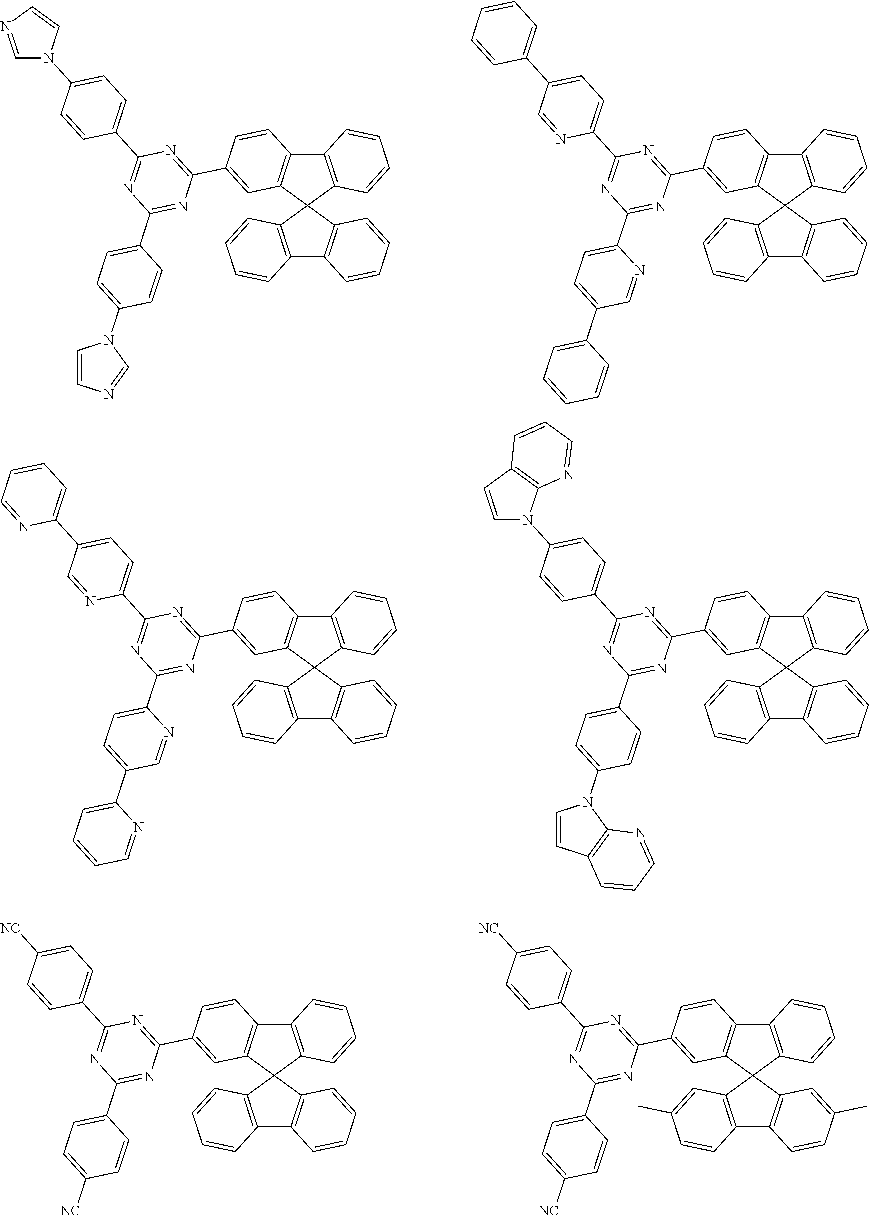

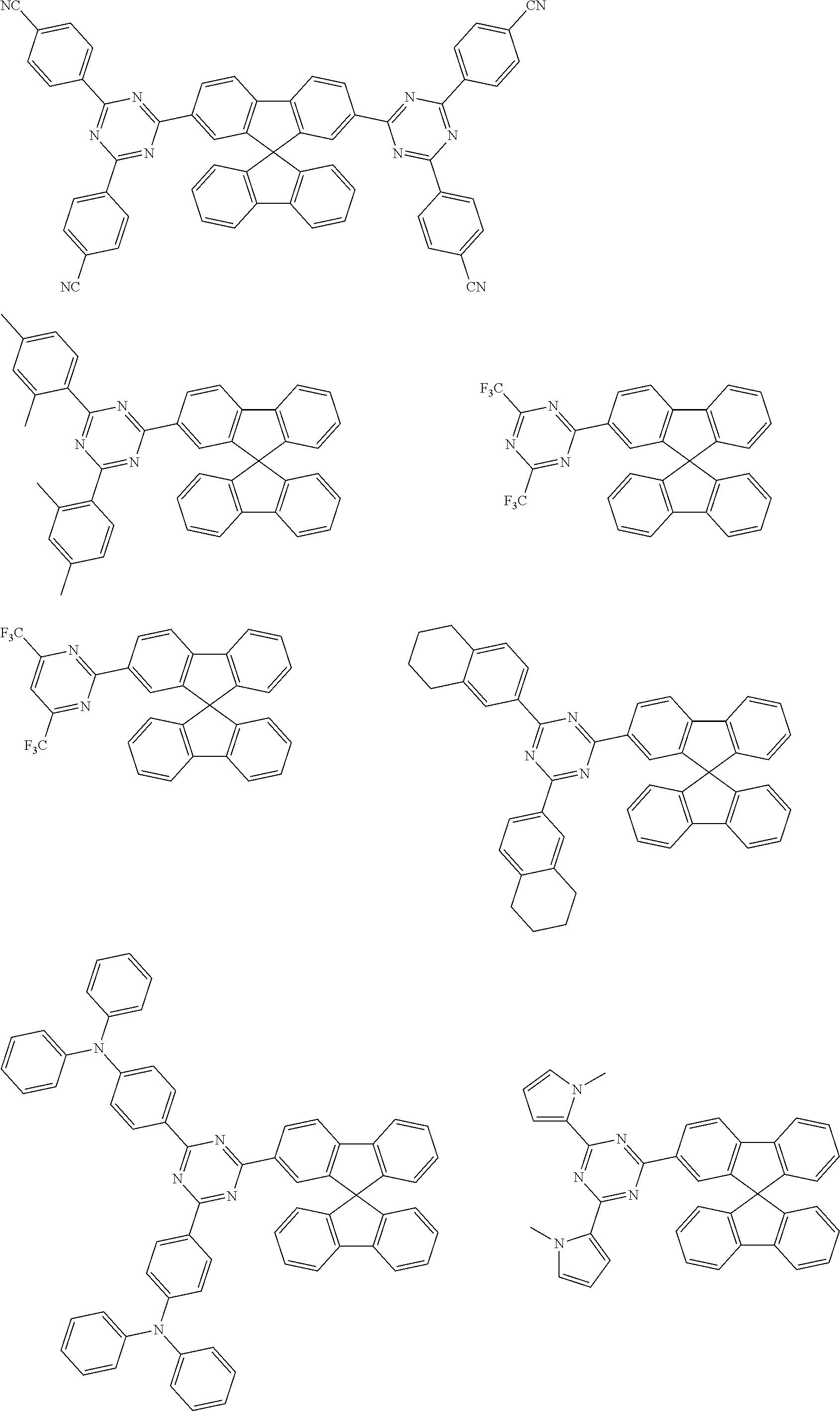

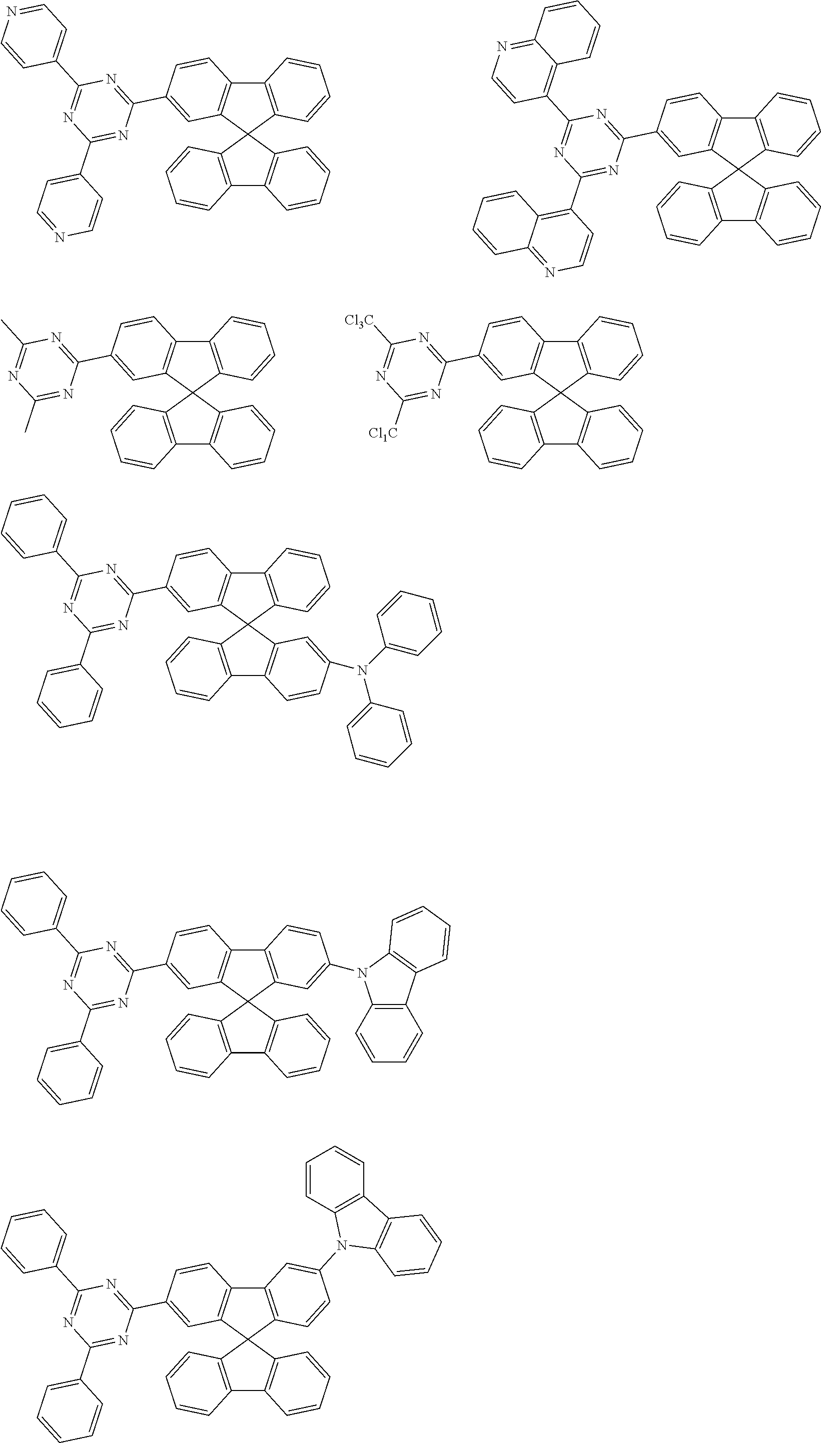

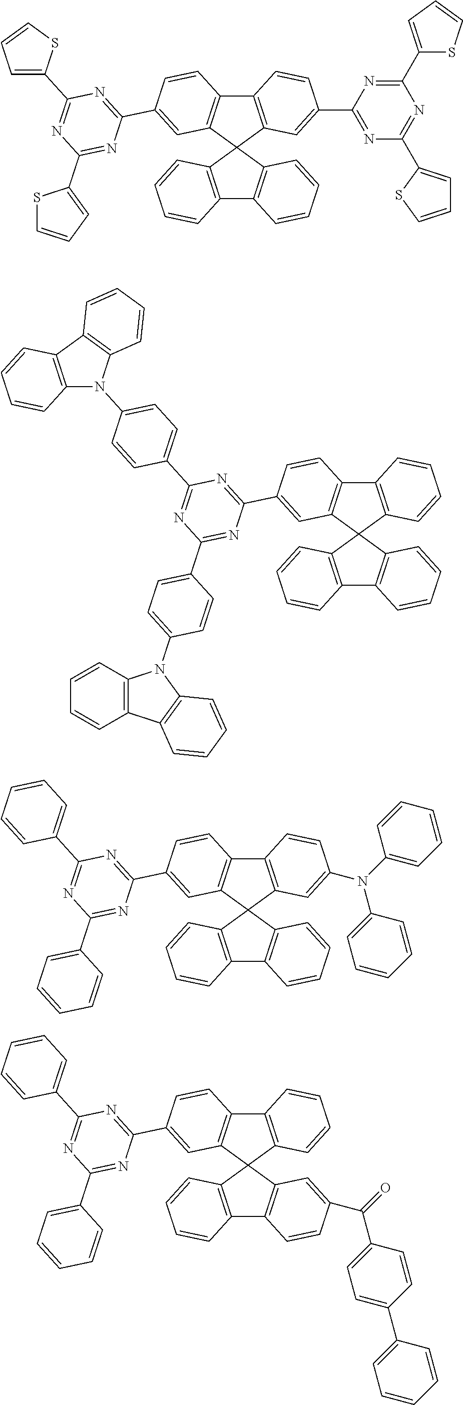

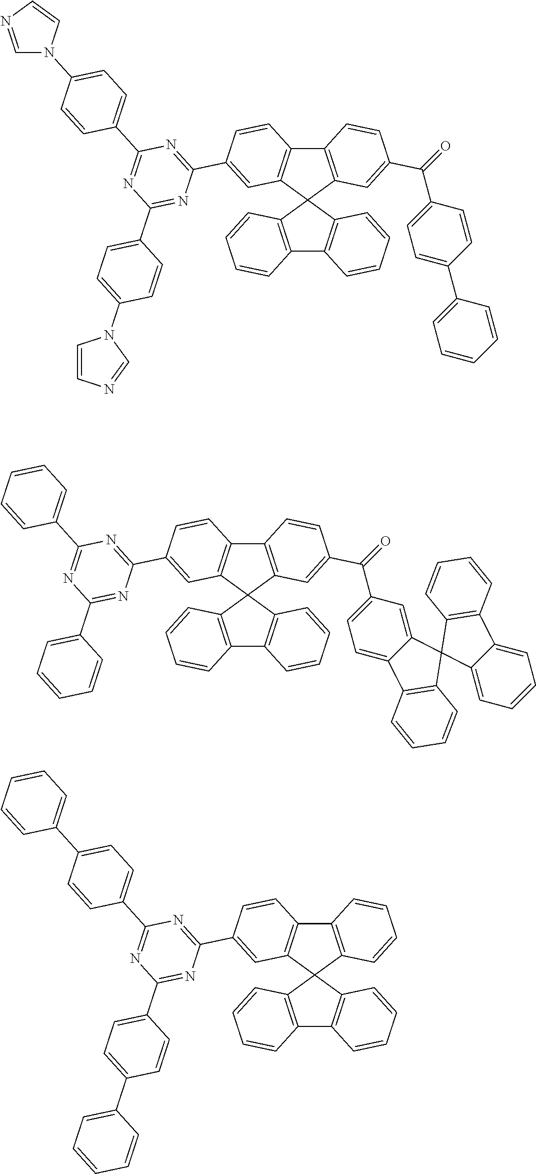 [SMILES: O=C(c1ccc(-c2ccccc2)cc1)c1ccc2c(c1)C1(c3ccccc3-c3ccccc31)c1cc(-c3nc(-c4ccc(-n5ccnc5)cc4)nc(-c4ccc(-n5ccnc5)cc4)n3)ccc1-2 ; O=C(c1ccc2c(c1)C1(c3ccccc3-c3ccccc31)c1ccccc1-2)c1ccc2c(c1)C1(c3ccccc3-c3ccccc31)c1cc(-c3nc(-c4ccccc4)nc(-c4ccccc4)n3)ccc1-2 ; c1ccc(-c2ccc(-c3nc(-c4ccc(-c5ccccc5)cc4)nc(-c4ccc5c(c4)C4(c6ccccc6-c6ccccc64)c4ccccc4-5)n3)cc2)cc1]

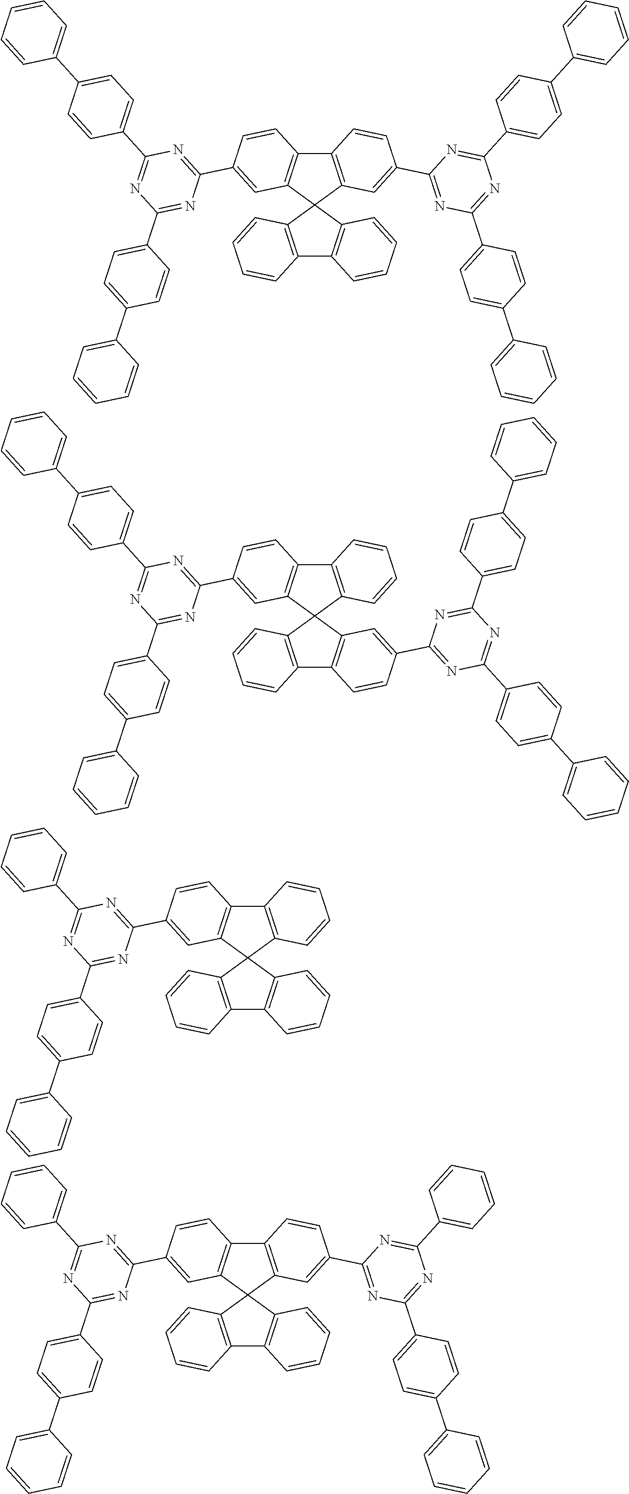

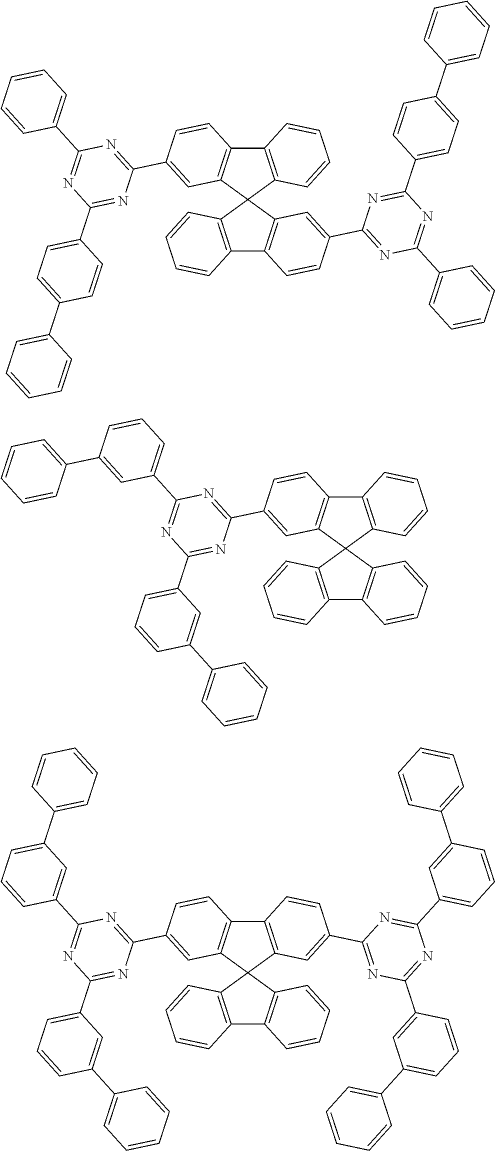

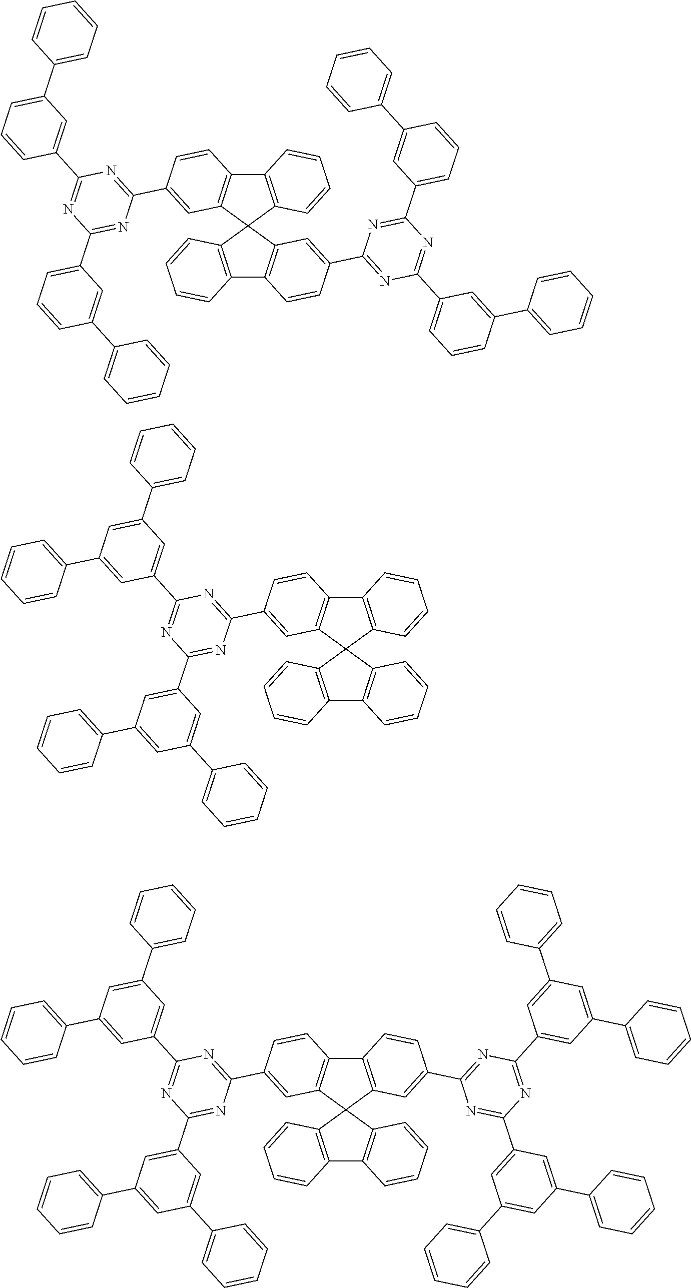

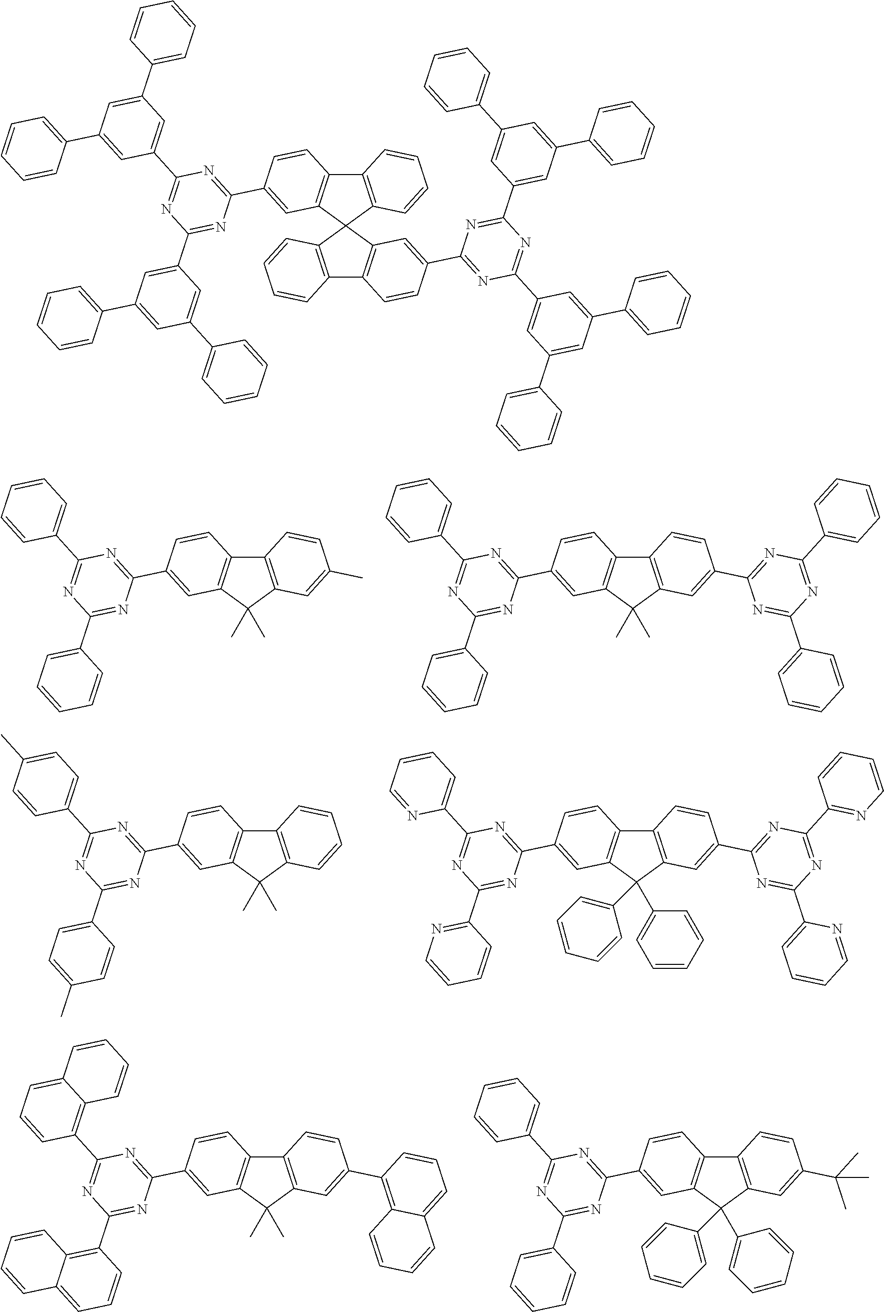

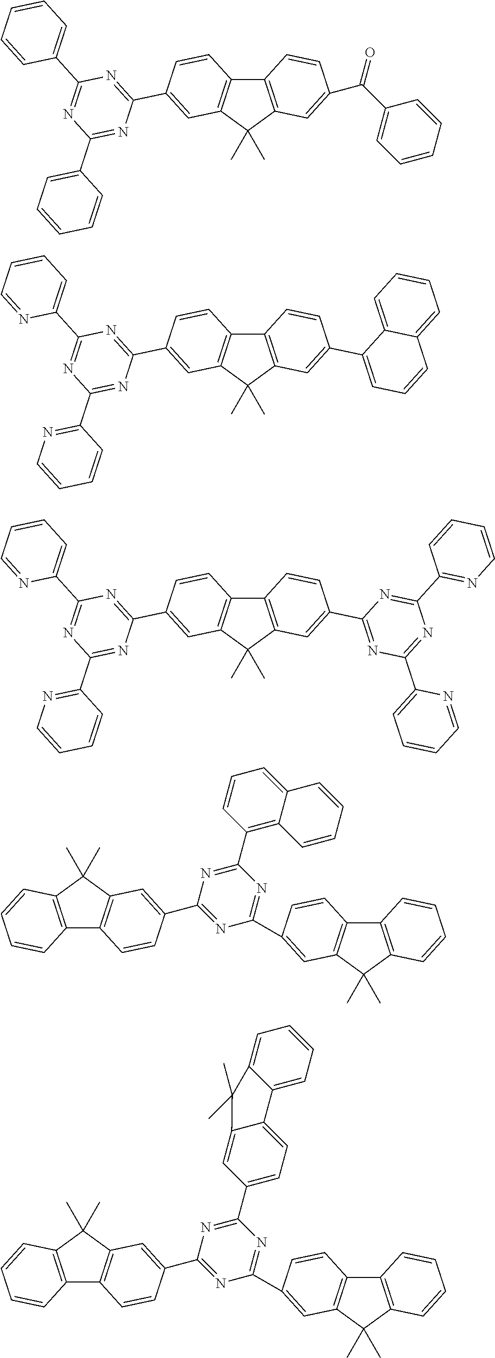

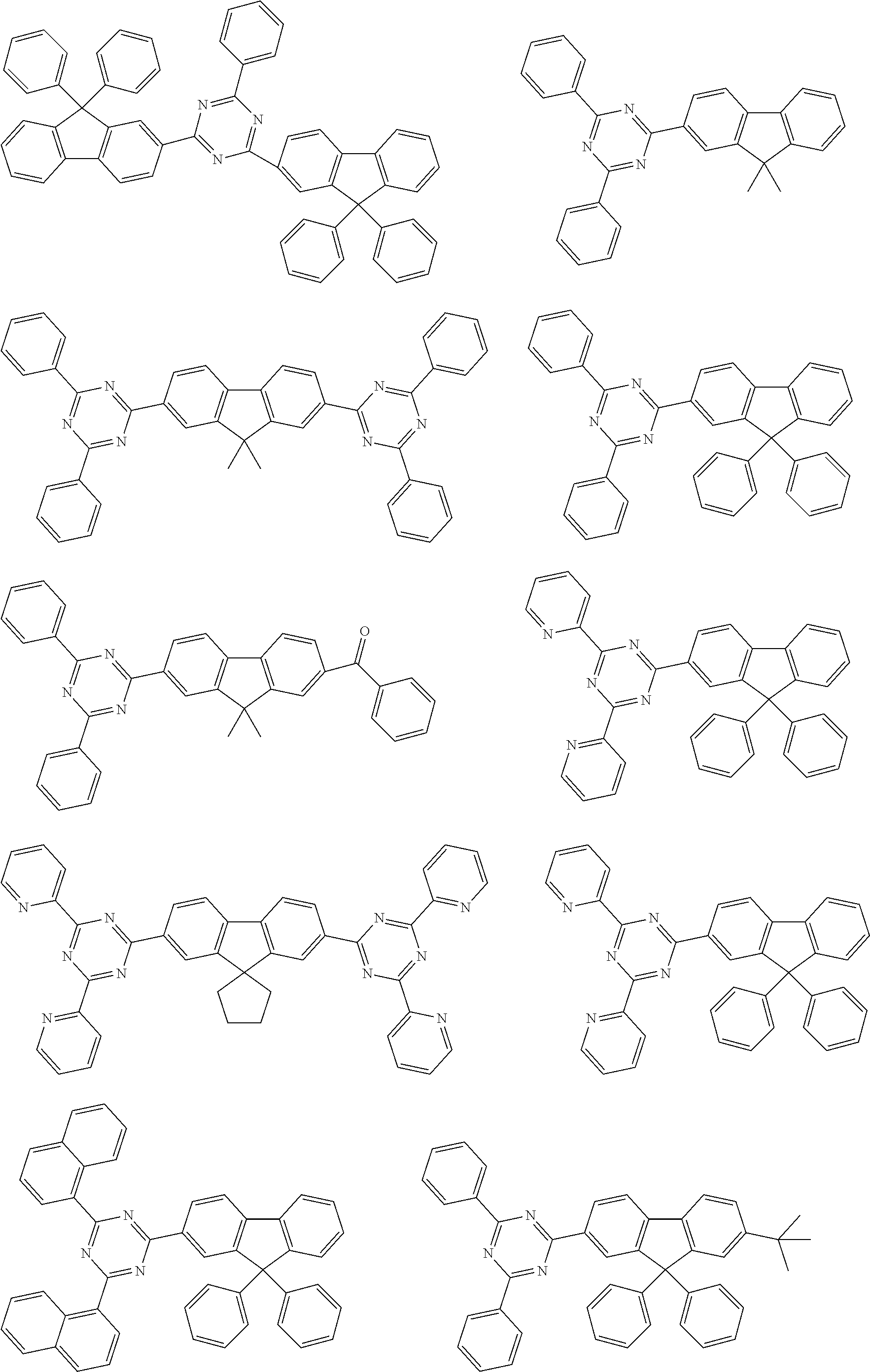

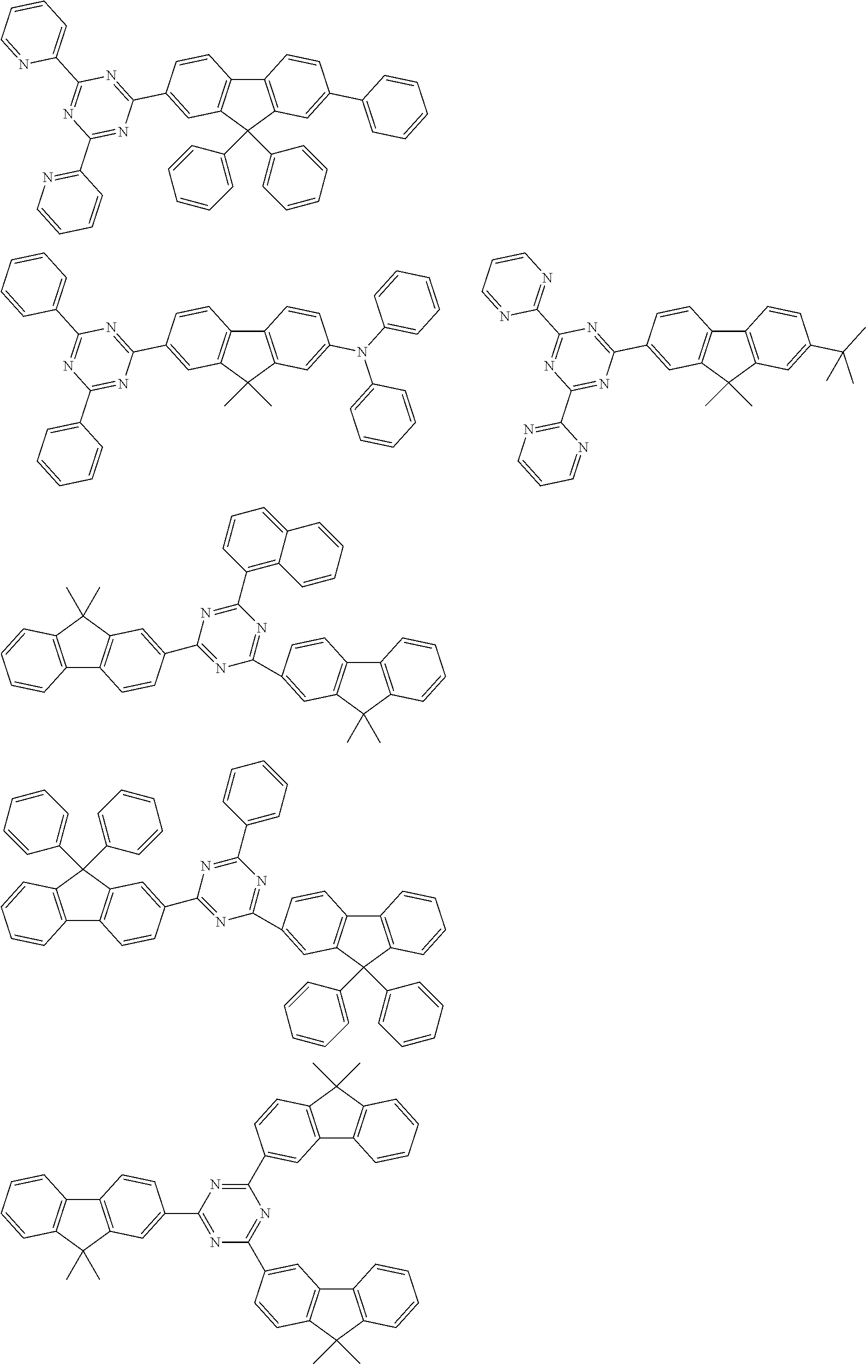

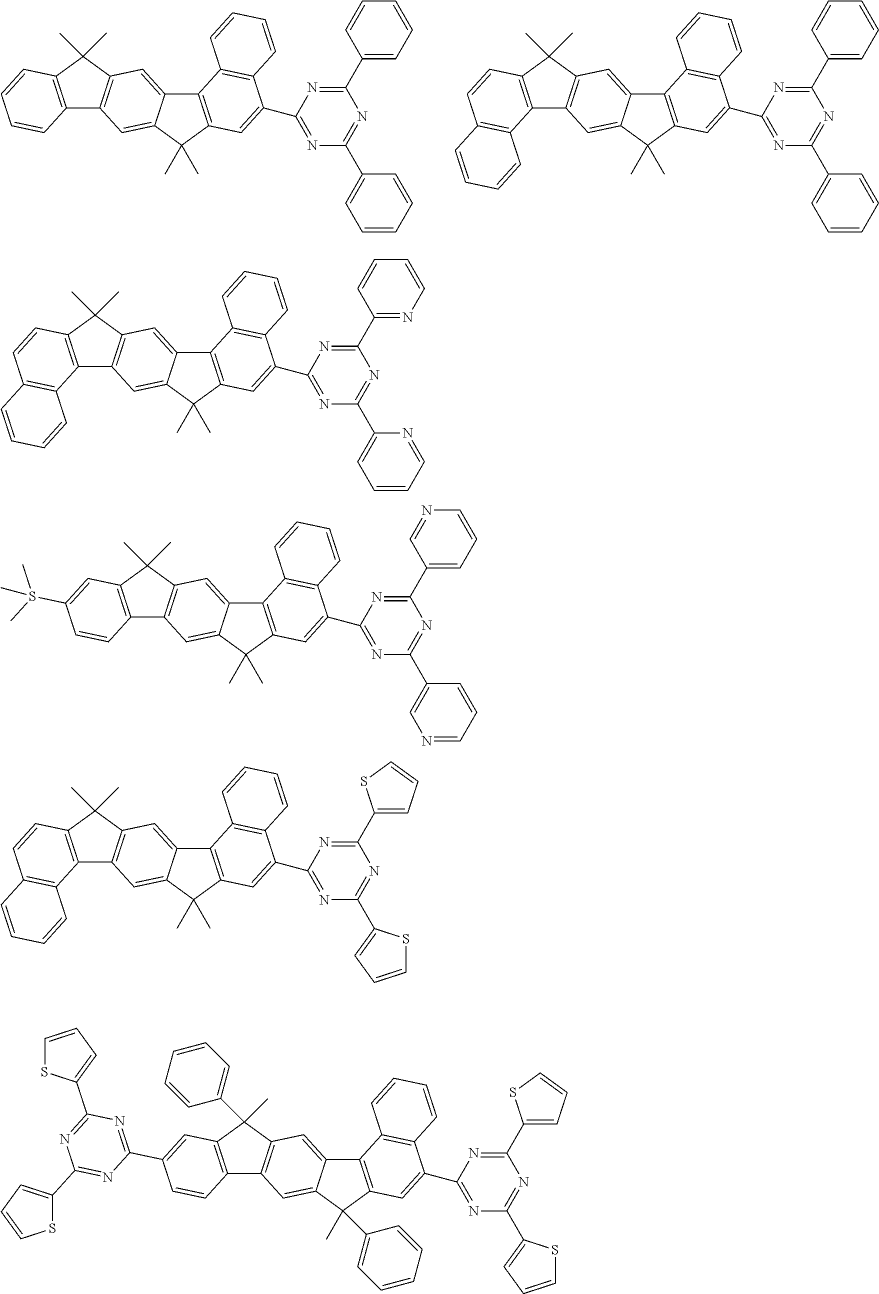

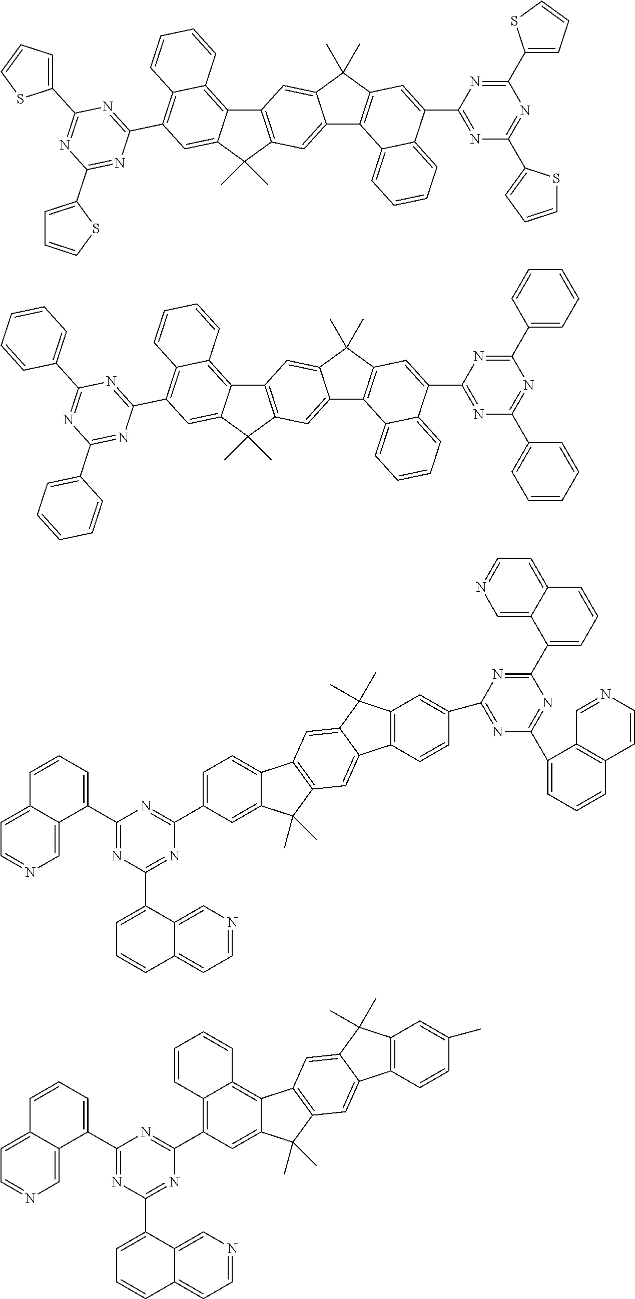 [SMILES: CC1(C)c2cc3c(cc2-c2c1cc(-c1nc(-c4cccs4)nc(-c4cccs4)n1)c1ccccc21)C(C)(C)c1cc(-c2nc(-c4cccs4)nc(-c4cccs4)n2)c2ccccc2c1-3 ; CC1(C)c2cc3c(cc2-c2c1cc(-c1nc(-c4ccccc4)nc(-c4ccccc4)n1)c1ccccc21)C(C)(C)c1cc(-c2nc(-c4ccccc4)nc(-c4ccccc4)n2)c2ccccc2c1-3 ; CC1(C)c2cc(-c3nc(-c4cccc5ccncc45)nc(-c4cccc5ccncc45)n3)ccc2-c2cc3c(cc21)-c1ccc(-c2nc(-c4cccc5ccncc45)nc(-c4cccc5ccncc45)n2)cc1C3(C)C ; Cc1ccc2c(c1)C(C)(C)c1cc3c(cc1-2)C(C)(C)c1cc(-c2nc(-c4cccc5ccncc45)nc(-c4cccc5ccncc45)n2)c2ccccc2c1-3]

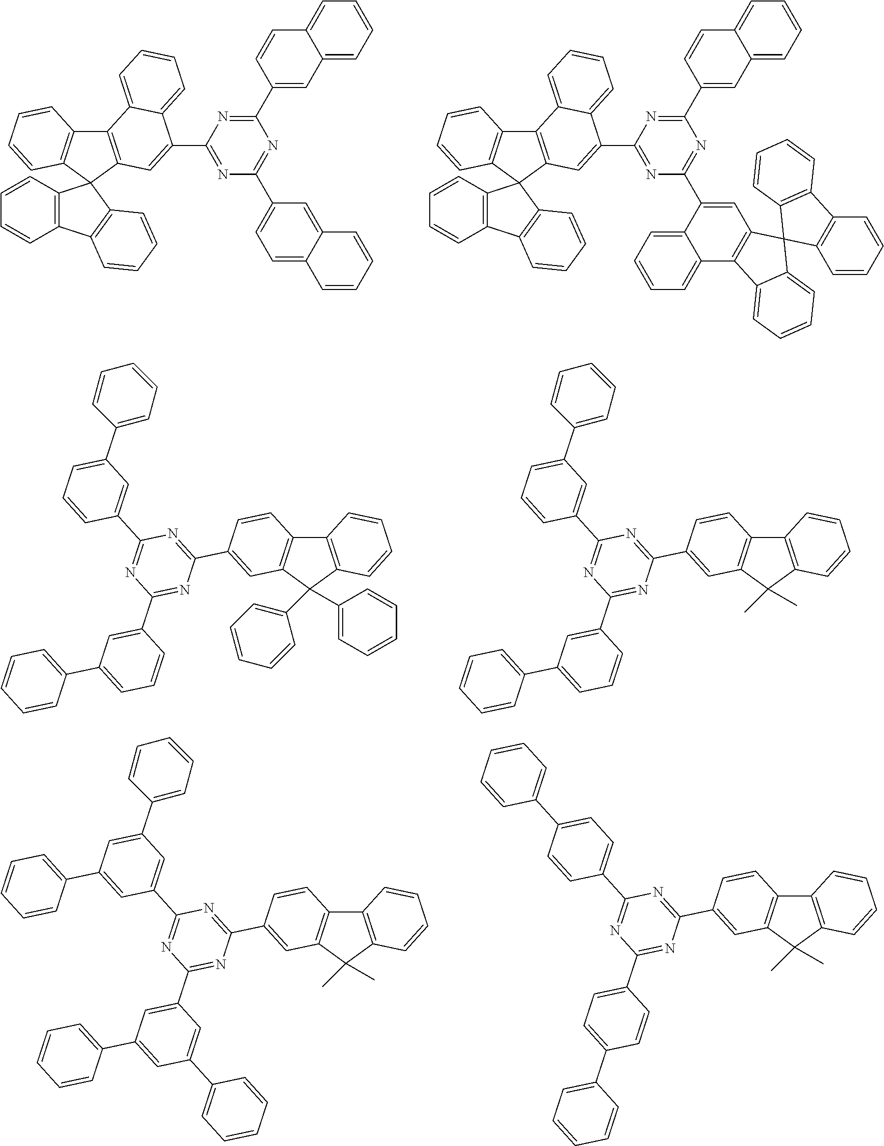

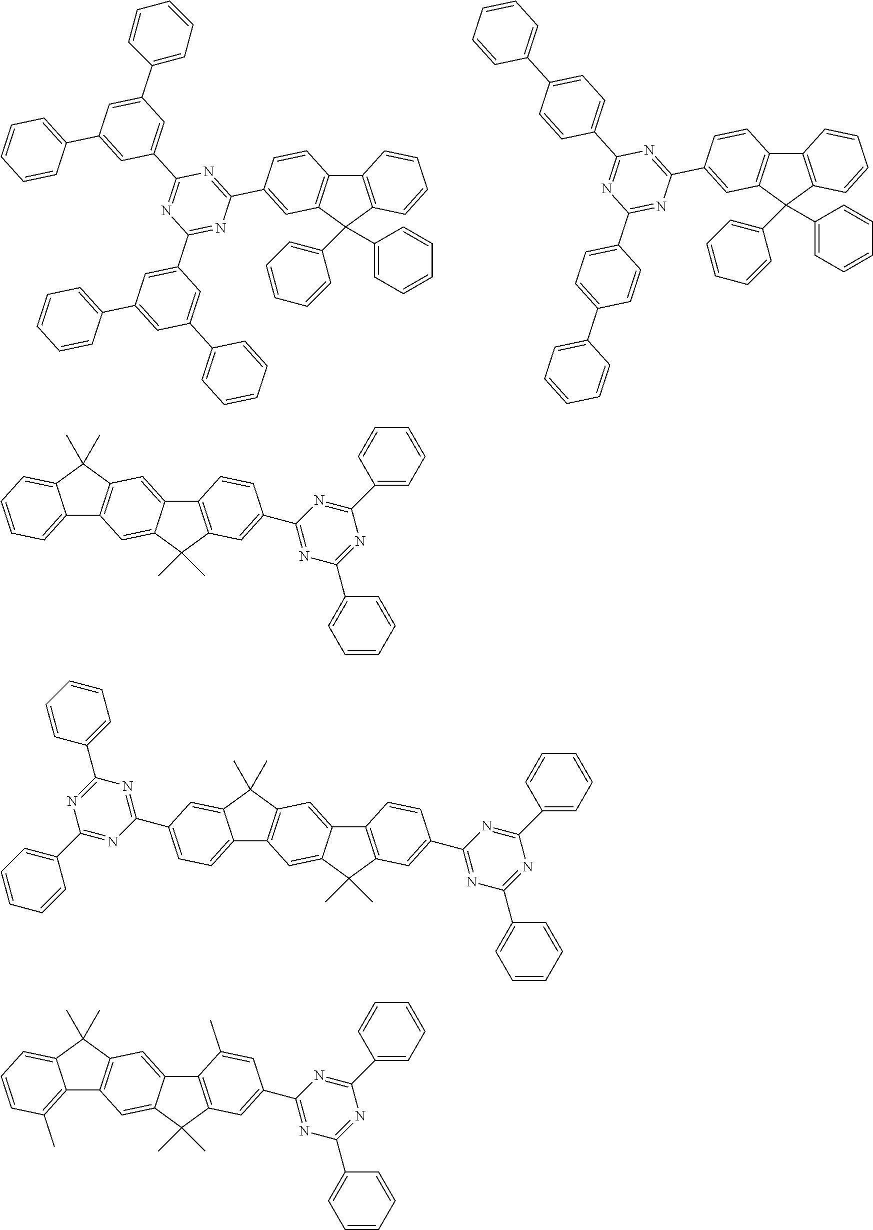 [SMILES: c1ccc(-c2cc(-c3ccccc3)cc(-c3nc(-c4cc(-c5ccccc5)cc(-c5ccccc5)c4)nc(-c4ccc5c(c4)C(c4ccccc4)(c4ccccc4)c4ccccc4-5)n3)c2)cc1 ; c1ccc(-c2ccc(-c3nc(-c4ccc(-c5ccccc5)cc4)nc(-c4ccc5c(c4)C(c4ccccc4)(c4ccccc4)c4ccccc4-5)n3)cc2)cc1 ; CC1(C)c2ccccc2-c2cc3c(cc21)-c1ccc(-c2nc(-c4ccccc4)nc(-c4ccccc4)n2)cc1C3(C)C ; CC1(C)c2cc(-c3nc(-c4ccccc4)nc(-c4ccccc4)n3)ccc2-c2cc3c(cc21)-c1ccc(-c2nc(-c4ccccc4)nc(-c4ccccc4)n2)cc1C3(C)C ; Cc1cccc2c1-c1cc3c(cc1C2(C)C)-c1c(C)cc(-c2nc(-c4ccccc4)nc(-c4ccccc4)n2)cc1C3(C)C]

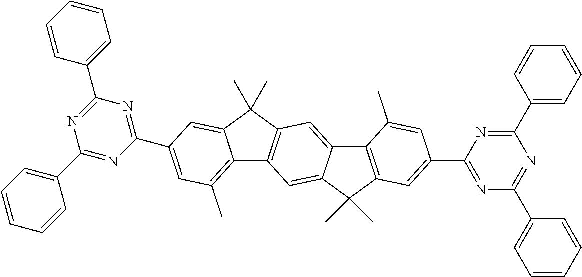 [SMILES: Cc1cc(-c2nc(-c3ccccc3)nc(-c3ccccc3)n2)cc2c1-c1cc3c(cc1C2(C)C)-c1c(C)cc(-c2nc(-c4ccccc4)nc(-c4ccccc4)n2)cc1C3(C)C]

If the electron-transport material in the electron-transport layer according to the invention is a lactam, this compound is then preferably selected from the compounds of the following formulae (45) and (46),

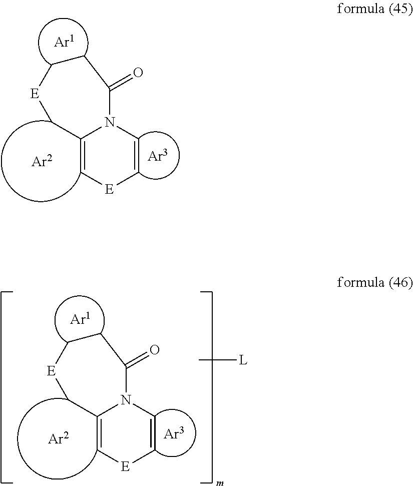

where R, R¹, R² and Ar have the above-mentioned meanings, and the following applies to the other symbols and indices used:
E is, identically or differently on each occurrence, a single bond, NR, CR₂, O or S;
Ar¹ is, together with the carbon atoms explicitly depicted, an aromatic or heteroaromatic ring system having 5 to 30 aromatic ring atoms, which may be substituted by one or more radicals R;
Ar², Ar³ are, identically or differently on each occurrence, together with the carbon atoms explicitly depicted, an aromatic or heteroaromatic ring system having 5 to 30 aromatic ring atoms, which may be substituted by one or more radicals R;
L is for m=2 a single bond or a divalent group, or for m=3 a trivalent group or for m=4 a tetravalent group, which is in each case bonded to Ar¹, Ar² or Ar³ at any desired position or is bonded to E in place of a group R;
m is 2, 3 or 4.

In a preferred embodiment of the compound of the formula (45) or (46), the group Ar¹ stands for a group of the following formula (47), (48), (49) or (50),

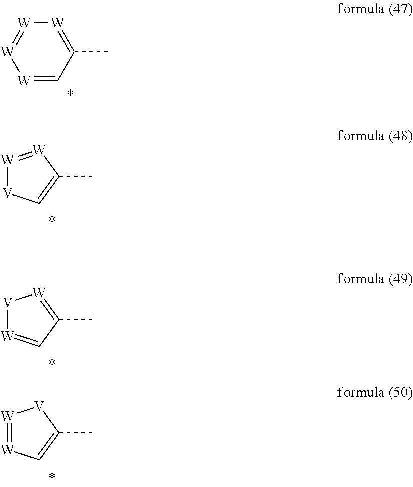

where the dashed bond indicates the link to the carbonyl group, * indicates the position of the link to E or Ar², and furthermore:
W is, identically or differently on each occurrence, CR or N; or two adjacent groups W stand for a group of the following formula (51) or (52),

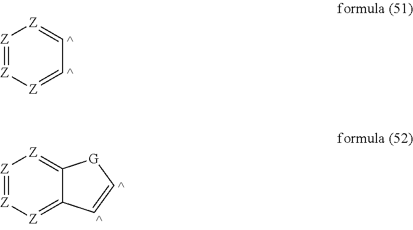

where G stands for CR₂, NR, O or S. Z stands, identically or differently on each occurrence, for CR or N, and ̂ indicate the corresponding adjacent groups W in the formulae (47) to (50);

### V is NR, O or S.

In a further preferred embodiment of the invention, the group Ar² stands for a group of one of the following formulae (53), (54) and (55),

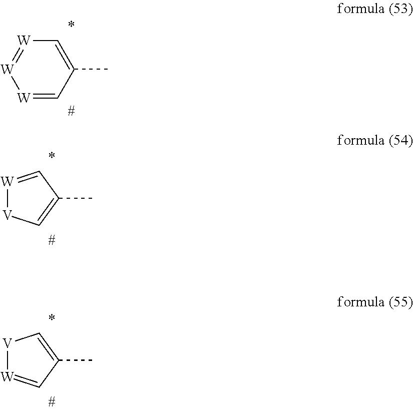

where the dashed bond indicates the link to N, # indicates the position of the link to E or Ar³, * indicates the link to E or Ar¹, and W and V have the above-mentioned meanings.

In a further preferred embodiment of the invention, the group Ar³ stands for a group of one of the following formulae (56), (57), (58) and (59),

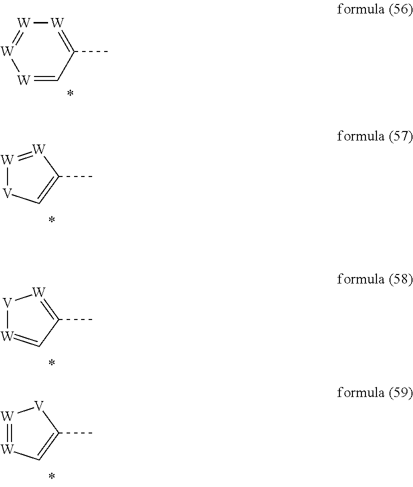

where the dashed bond indicates the link to N, * indicates the link to E or Ar², and W and V have the above-mentioned meanings.

The above-mentioned preferred groups Ar¹, Ar² and Ar³ can be combined with one another as desired here.

In a further preferred embodiment of the invention, at least one group E stands for a single bond.

In a preferred embodiment of the invention, the above-mentioned preferences occur simultaneously. Particular preference is therefore given to compounds of the formulae (45) and (46) for which:
Ar¹ is selected from the groups of the above-mentioned formulae (47), (48), (49) and (50);
Ar² is selected from the groups of the above-mentioned formulae (53), (54) and (55);
Ar³ is selected from the groups of the above-mentioned formulae (56), (57), (58) and (59).

Particularly preferably, at least two of the groups Ar¹, Ar² and Ar³ stand for a 6-membered aryl or 6-membered heteroaryl ring group. Particularly preferably, Ar¹ thus stands for a group of the formula (47) and at the same time Ar² stands for a group of the formula (53), or Ar′ stands for a group of the formula (47) and at the same time Ar³ stands for a group of the formula (56), or Ar² stands for a group of the formula (53) and at the same time Ar³ stands for a group of the formula (59).

Particularly preferred embodiments of the formula (45) are therefore the compounds of the following formulae (60) to (69),

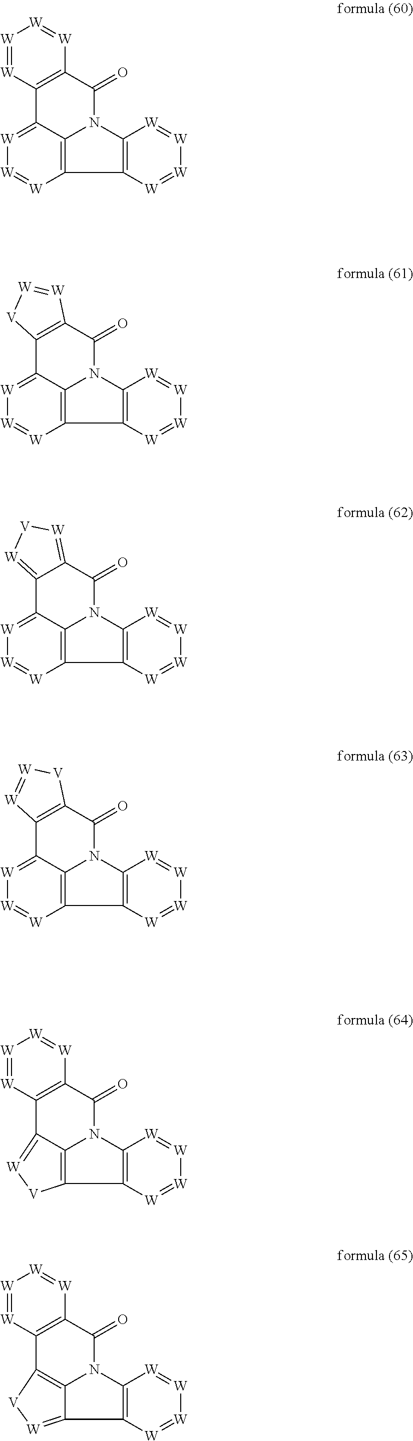

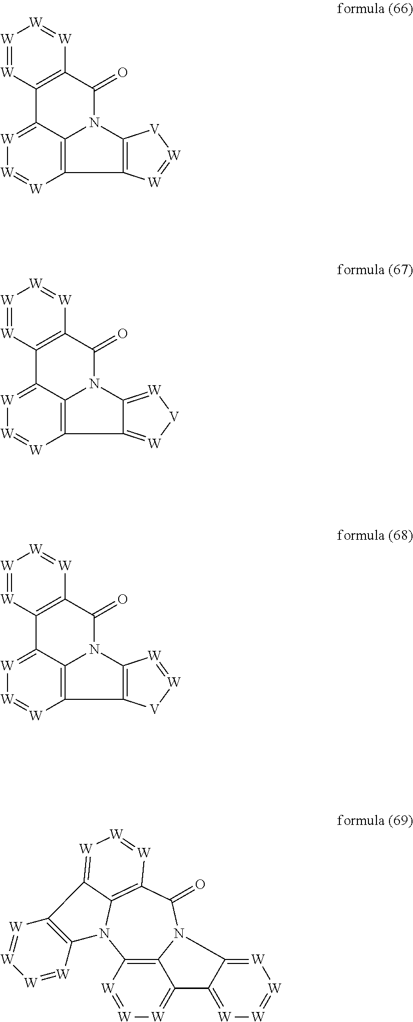

where the symbols used have the above-mentioned meanings.

It is furthermore preferred for W to stand for CR or N and not for a group of the formula (51) or (52). In a preferred embodiment of the compounds of the formulae (60) to (69), in total a maximum of one symbol W per ring stands for N, and the remaining symbols W stand for CR. In a particularly preferred embodiment of the invention, all symbols W stand for CR. Particular preference is therefore given to the compounds of the following formulae (60a) to (69a),

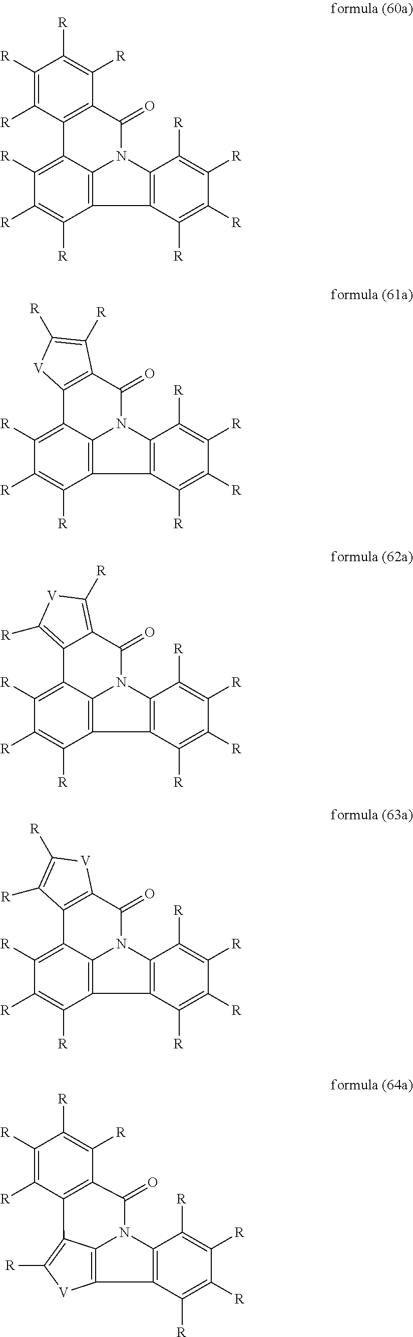

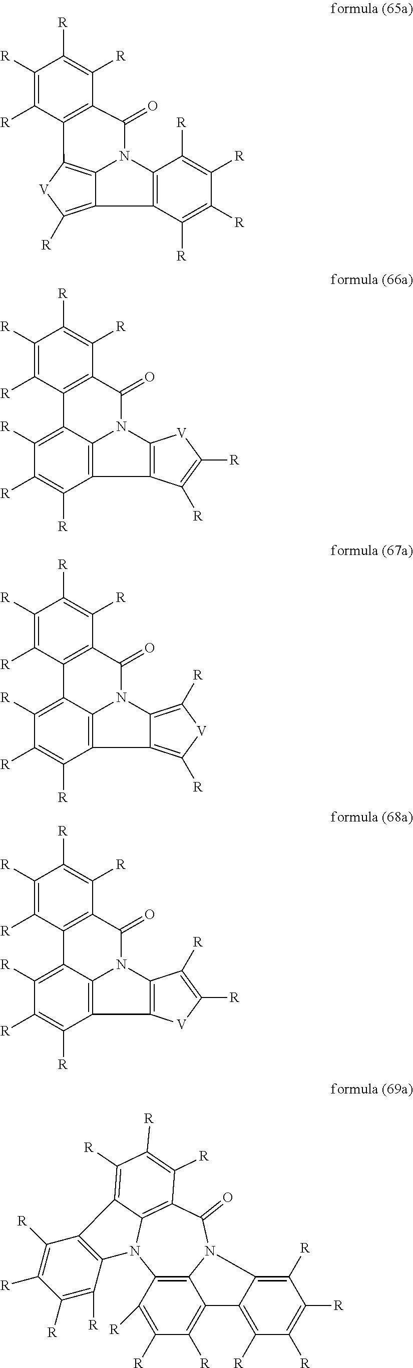

where the symbols used have the above-mentioned meanings.

Very particular preference is given to the structures of the formulae (60b) to (69b),

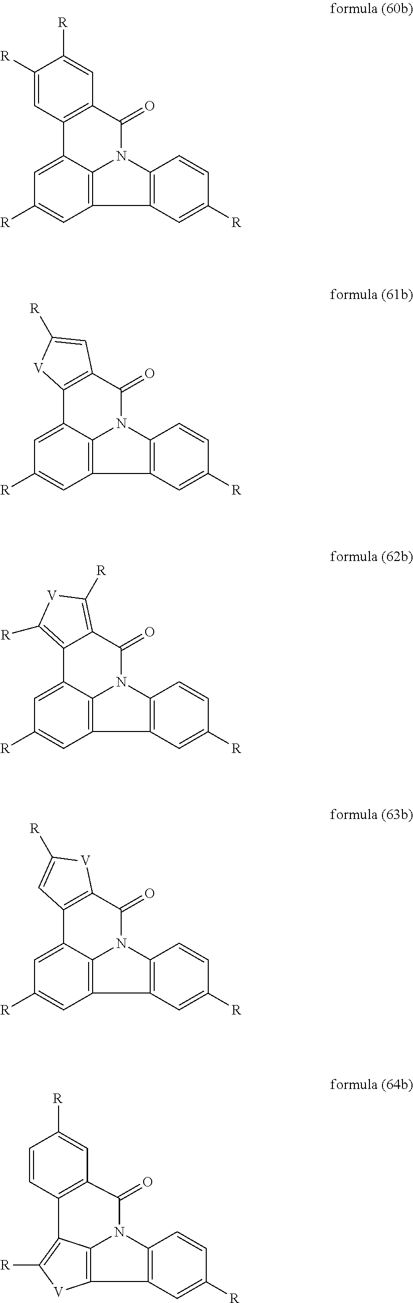

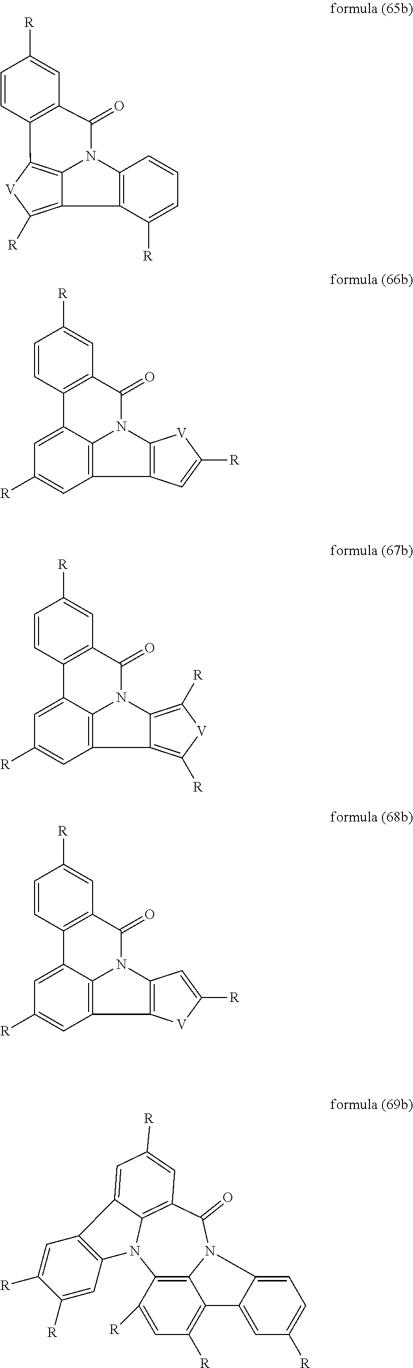

where the symbols used have the above-mentioned meanings.

Very particular preference is given to the compounds of the formulae (60) and (60a) and (60b).

The bridging group L in the compounds of the formula (46a) is preferably selected from a single bond or an aromatic or heteroaromatic ring system having 5 to 30 aromatic ring atoms, which may be substituted by one or more radicals R. The aromatic or heteroaromatic ring systems here preferably contain no condensed aryl or heteroaryl groups in which more than two aromatic six-membered rings are condensed directly onto one another. They particularly preferably contain absolutely no aryl or heteroaryl groups in which aromatic six-membered rings are condensed directly onto one another.

In a further preferred embodiment of the invention, the index m in compounds of the formula (46)=2 or 3, in particular equals 2.

In a preferred embodiment of the invention, R in the above-mentioned formulae is selected, identically or differently on each occurrence, from the group consisting of H, D, F, Cl, Br, CN, N(Ar)₂, C(═O)Ar, a straight-chain alkyl or alkoxy group having 1 to 10 C atoms or a branched or cyclic alkyl or alkoxy group having 3 to 10 C atoms or an alkenyl group having 2 to 10 C atoms, each of which may be substituted by one or more radicals R¹, where one or more non-adjacent CH₂ groups may be replaced by O and where one or more H atoms may be replaced by D or F, an aromatic or heteroaromatic ring system having 5 to 30 aromatic ring atoms, which may in each case be substituted by one or more radicals R¹, an aryloxy or heteroaryloxy group having 5 to 30 aromatic ring atoms, which may be substituted by one or more radicals R¹, or a combination of these systems.

In a particularly preferred embodiment of the invention, R in the above-mentioned formulae is selected, identically or differently on each occurrence, from the group consisting of H, D, F, Cl, Br, CN, a straight-chain alkyl group having 1 to 10 C atoms or a branched or cyclic alkyl group having 3 to 10 C atoms, each of which may be substituted by one or more radicals R¹, where one or more H atoms may be replaced by D or F, an aromatic or heteroaromatic ring system having 5 to 18 aromatic ring atoms, which may in each case be substituted by one or more radicals R¹, or a combination of these systems.

The radicals R, if these contain aromatic or heteroaromatic ring systems, preferably contain no condensed aryl or heteroaryl groups in which more than two aromatic six-membered rings are condensed directly onto one another. They particularly preferably contain absolutely no aryl or heteroaryl groups in which aromatic six-membered rings are condensed directly onto one another. Especial preference is given here to phenyl, biphenyl, terphenyl, quaterphenyl, carbazole, dibenzothiophene, dibenzofuran, indenocarbazole, indolocarbazole, triazine or pyrimidine, each of which may also be substituted by one or more radicals R¹.

For compounds which are processed by vacuum evaporation, the alkyl groups preferably have not more than five C atoms, particularly preferably not more than 4 C atoms, very particularly preferably not more than 1 C atom. For compounds which are processed from solution, compounds which are substituted by alkyl groups having up to 10 C atoms or which are substituted by oligoarylene groups, for example ortho-, meta-, para- or branched terphenyl groups, are also suitable.

The compounds of the formulae (45) and (46) are known in principle. The synthesis of these compounds can be carried out by the processes described in WO 2011/116865 and WO 2011/137951.

Examples of preferred compounds in accordance with the above-mentioned embodiments are the compounds shown in the following table.

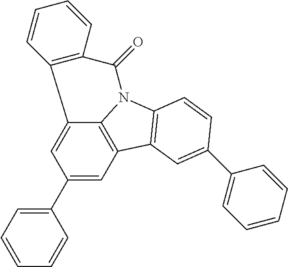 [SMILES: O=c1c2ccccc2c2cc(-c3ccccc3)cc3c4cc(-c5ccccc5)ccc4n1c23]

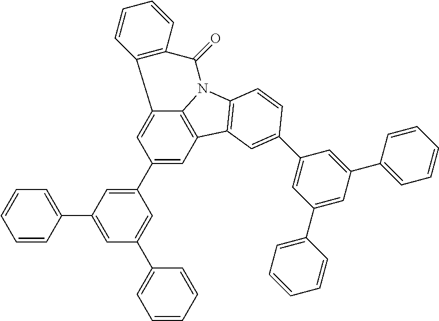 [SMILES: O=c1c2ccccc2c2cc(-c3cc(-c4ccccc4)cc(-c4ccccc4)c3)cc3c4cc(-c5cc(-c6ccccc6)cc(-c6ccccc6)c5)ccc4n1c23]

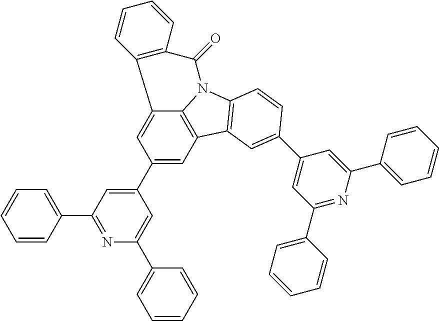 [SMILES: O=c1c2ccccc2c2cc(-c3cc(-c4ccccc4)nc(-c4ccccc4)c3)cc3c4cc(-c5cc(-c6ccccc6)nc(-c6ccccc6)c5)ccc4n1c23]

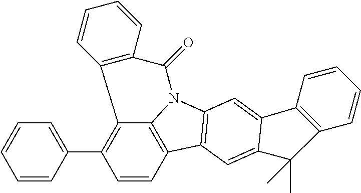 [SMILES: CC1(C)c2ccccc2-c2cc3c(cc21)c1ccc(-c2ccccc2)c2c4ccccc4c(=O)n3c12]

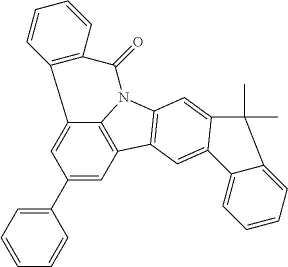 [SMILES: CC1(C)c2ccccc2-c2cc3c4cc(-c5ccccc5)cc5c6ccccc6c(=O)n(c3cc21)c54]

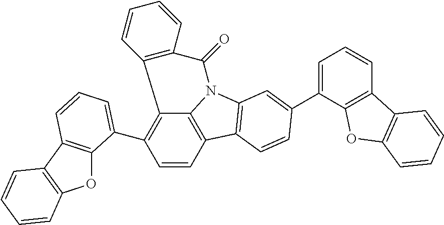 [SMILES: O=c1c2ccccc2c2c(-c3cccc4c3oc3ccccc34)ccc3c4ccc(-c5cccc6c5oc5ccccc56)cc4n1c32]

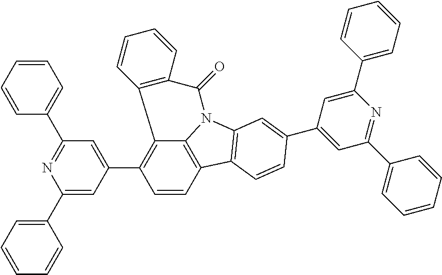 [SMILES: O=c1c2ccccc2c2c(-c3cc(-c4ccccc4)nc(-c4ccccc4)c3)ccc3c4ccc(-c5cc(-c6ccccc6)nc(-c6ccccc6)c5)cc4n1c32]

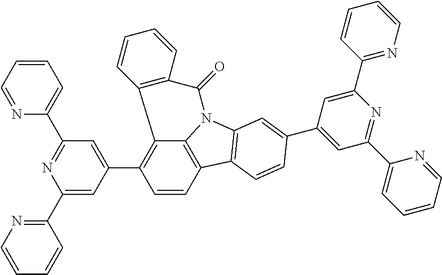 [SMILES: O=c1c2ccccc2c2c(-c3cc(-c4ccccn4)nc(-c4ccccn4)c3)ccc3c4ccc(-c5cc(-c6ccccn6)nc(-c6ccccn6)c5)cc4n1c32]

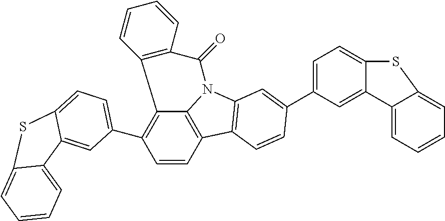 [SMILES: O=c1c2ccccc2c2c(-c3ccc4sc5ccccc5c4c3)ccc3c4ccc(-c5ccc6sc7ccccc7c6c5)cc4n1c32]

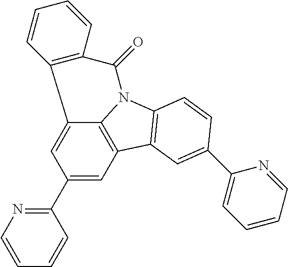 [SMILES: O=c1c2ccccc2c2cc(-c3ccccn3)cc3c4cc(-c5ccccn5)ccc4n1c23]

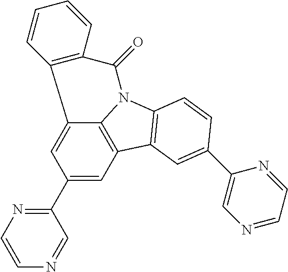 [SMILES: O=c1c2ccccc2c2cc(-c3cnccn3)cc3c4cc(-c5cnccn5)ccc4n1c23]

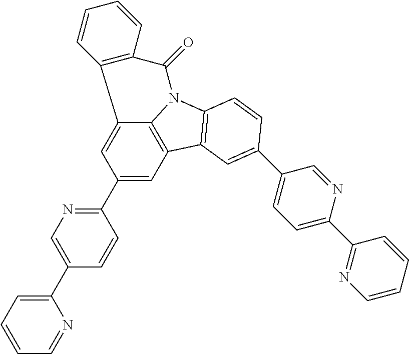 [SMILES: O=c1c2ccccc2c2cc(-c3ccc(-c4ccccn4)cn3)cc3c4cc(-c5ccc(-c6ccccn6)nc5)ccc4n1c23]

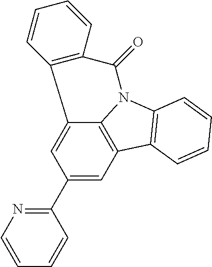 [SMILES: O=c1c2ccccc2c2cc(-c3ccccn3)cc3c4ccccc4n1c23]

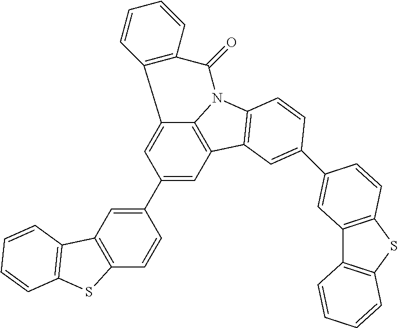 [SMILES: O=c1c2ccccc2c2cc(-c3ccc4sc5ccccc5c4c3)cc3c4cc(-c5ccc6sc7ccccc7c6c5)ccc4n1c23]

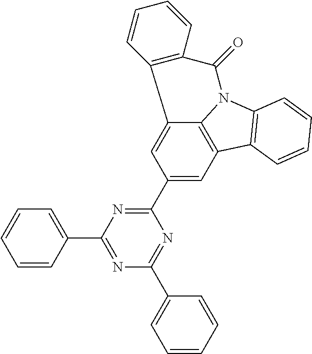 [SMILES: O=c1c2ccccc2c2cc(-c3nc(-c4ccccc4)nc(-c4ccccc4)n3)cc3c4ccccc4n1c23]

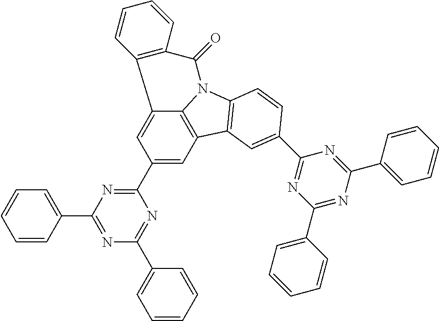 [SMILES: O=c1c2ccccc2c2cc(-c3nc(-c4ccccc4)nc(-c4ccccc4)n3)cc3c4cc(-c5nc(-c6ccccc6)nc(-c6ccccc6)n5)ccc4n1c23]

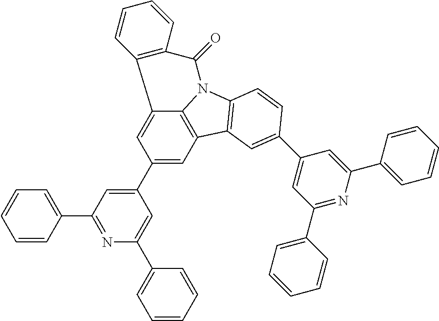 [SMILES: O=c1c2ccccc2c2cc(-c3cc(-c4ccccc4)nc(-c4ccccc4)c3)cc3c4cc(-c5cc(-c6ccccc6)nc(-c6ccccc6)c5)ccc4n1c23]

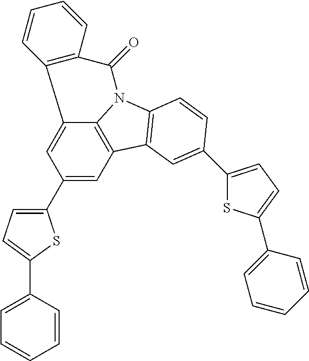 [SMILES: O=c1c2ccccc2c2cc(-c3ccc(-c4ccccc4)s3)cc3c4cc(-c5ccc(-c6ccccc6)s5)ccc4n1c23]

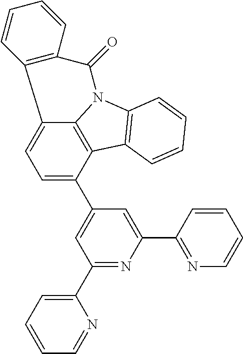 [SMILES: O=c1c2ccccc2c2ccc(-c3cc(-c4ccccn4)nc(-c4ccccn4)c3)c3c4ccccc4n1c23]

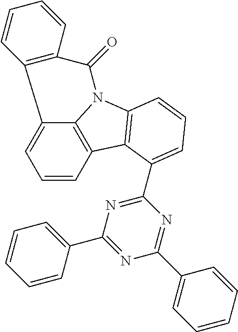 [SMILES: O=c1c2ccccc2c2cccc3c4c(-c5nc(-c6ccccc6)nc(-c6ccccc6)n5)cccc4n1c23]

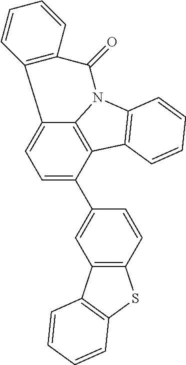 [SMILES: O=c1c2ccccc2c2ccc(-c3ccc4sc5ccccc5c4c3)c3c4ccccc4n1c23]

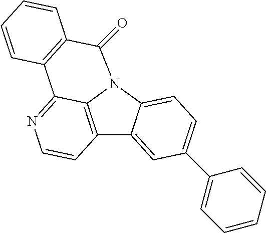 [SMILES: O=c1c2ccccc2c2nccc3c4cc(-c5ccccc5)ccc4n1c32]

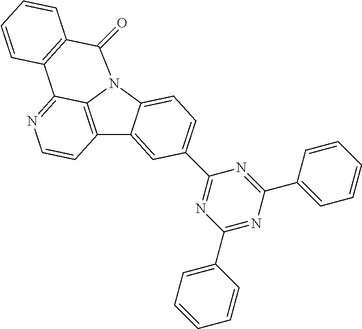 [SMILES: O=c1c2ccccc2c2nccc3c4cc(-c5nc(-c6ccccc6)nc(-c6ccccc6)n5)ccc4n1c32]

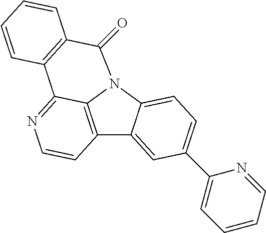 [SMILES: O=c1c2ccccc2c2nccc3c4cc(-c5ccccn5)ccc4n1c32]

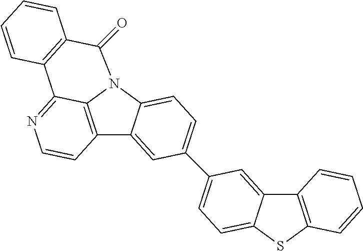 [SMILES: O=c1c2ccccc2c2nccc3c4cc(-c5ccc6sc7ccccc7c6c5)ccc4n1c32]

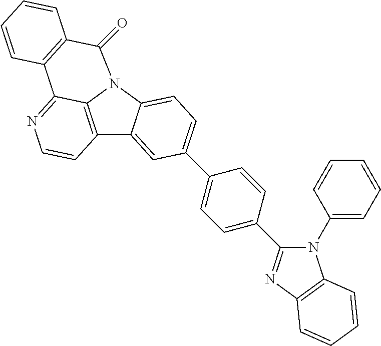 [SMILES: O=c1c2ccccc2c2nccc3c4cc(-c5ccc(-c6nc7ccccc7n6-c6ccccc6)cc5)ccc4n1c32]

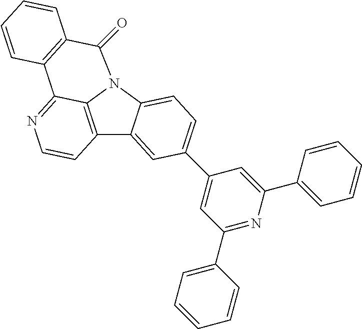 [SMILES: O=c1c2ccccc2c2nccc3c4cc(-c5cc(-c6ccccc6)nc(-c6ccccc6)c5)ccc4n1c32]

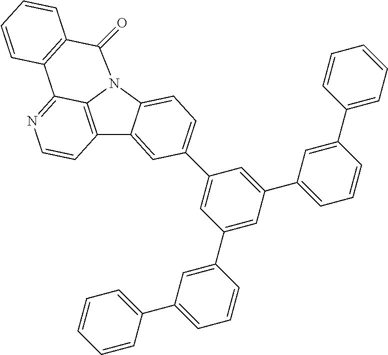 [SMILES: O=c1c2ccccc2c2nccc3c4cc(-c5cc(-c6cccc(-c7ccccc7)c6)cc(-c6cccc(-c7ccccc7)c6)c5)ccc4n1c32]

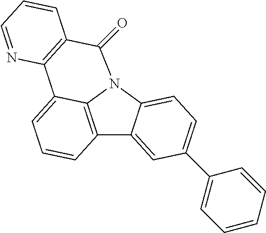 [SMILES: O=c1c2cccnc2c2cccc3c4cc(-c5ccccc5)ccc4n1c32]

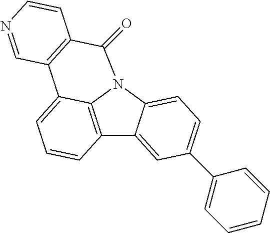 [SMILES: O=c1c2ccncc2c2cccc3c4cc(-c5ccccc5)ccc4n1c23]

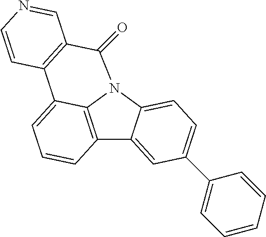 [SMILES: O=c1c2cnccc2c2cccc3c4cc(-c5ccccc5)ccc4n1c23]

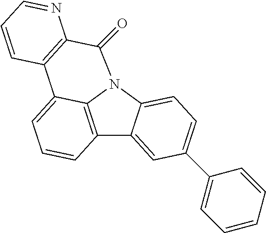 [SMILES: O=c1c2ncccc2c2cccc3c4cc(-c5ccccc5)ccc4n1c23]

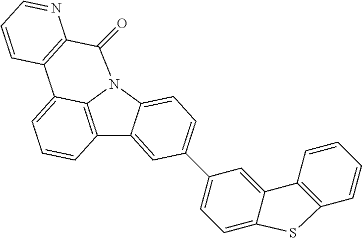 [SMILES: O=c1c2ncccc2c2cccc3c4cc(-c5ccc6sc7ccccc7c6c5)ccc4n1c23]

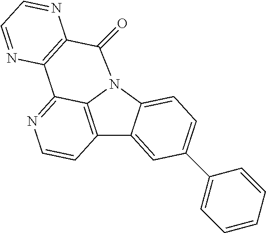 [SMILES: O=c1c2nccnc2c2nccc3c4cc(-c5ccccc5)ccc4n1c32]

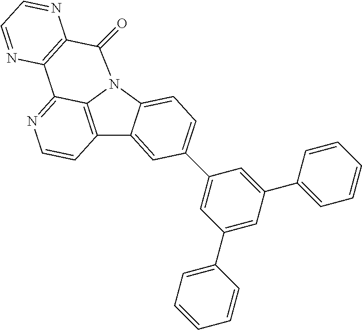 [SMILES: O=c1c2nccnc2c2nccc3c4cc(-c5cc(-c6ccccc6)cc(-c6ccccc6)c5)ccc4n1c32]

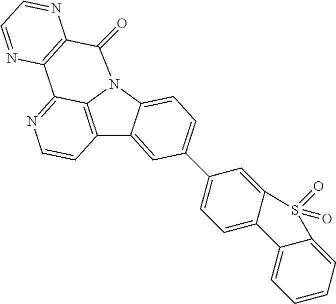 [SMILES: O=c1c2nccnc2c2nccc3c4cc(-c5ccc6c(c5)S(=O)(=O)c5ccccc5-6)ccc4n1c32]

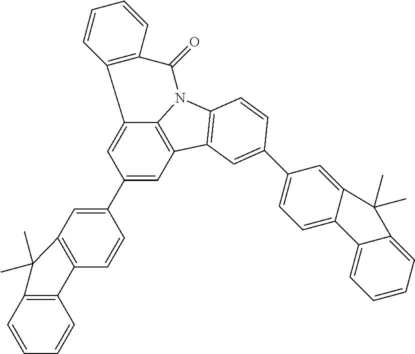 [SMILES: CC1(C)c2ccccc2-c2ccc(-c3ccc4c(c3)c3cc(-c5ccc6c(c5)C(C)(C)c5ccccc5-6)cc5c6ccccc6c(=O)n4c53)cc21]

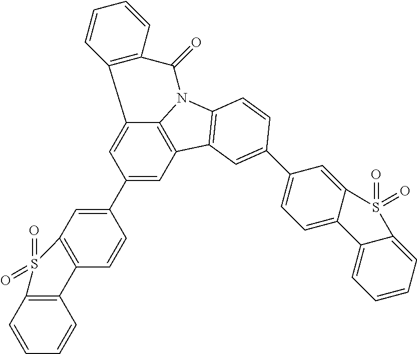 [SMILES: O=c1c2ccccc2c2cc(-c3ccc4c(c3)S(=O)(=O)c3ccccc3-4)cc3c4cc(-c5ccc6c(c5)S(=O)(=O)c5ccccc5-6)ccc4n1c23]

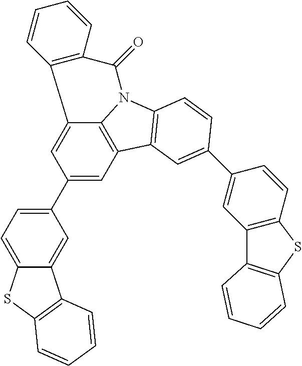 [SMILES: O=c1c2ccccc2c2cc(-c3ccc4sc5ccccc5c4c3)cc3c4cc(-c5ccc6sc7ccccc7c6c5)ccc4n1c23]

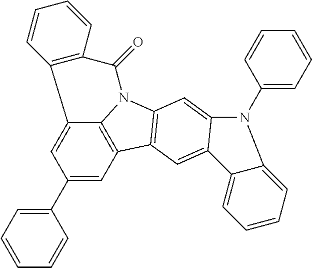 [SMILES: O=c1c2ccccc2c2cc(-c3ccccc3)cc3c4cc5c6ccccc6n(-c6ccccc6)c5cc4n1c23]

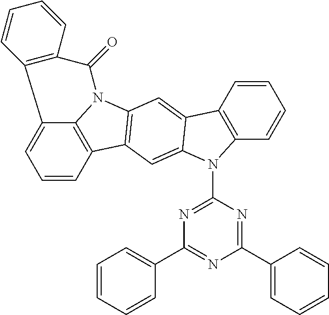 [SMILES: O=c1c2ccccc2c2cccc3c4cc5c(cc4n1c23)c1ccccc1n5-c1nc(-c2ccccc2)nc(-c2ccccc2)n1]

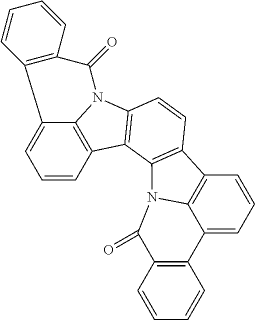 [SMILES: O=c1c2ccccc2c2cccc3c4c(ccc5c6cccc7c8ccccc8c(=O)n(c76)c54)n1c23]

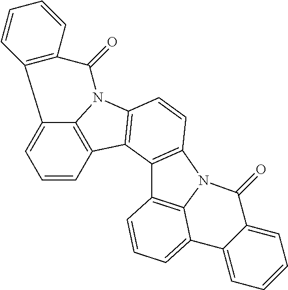 [SMILES: O=c1c2ccccc2c2cccc3c4c5c6cccc7c8ccccc8c(=O)n(c5ccc4n1c23)c76]

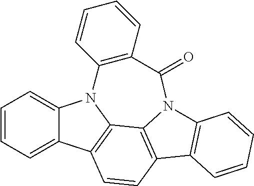 [SMILES: O=c1c2ccccc2n2c3ccccc3c3ccc4c5ccccc5n1c4c32]

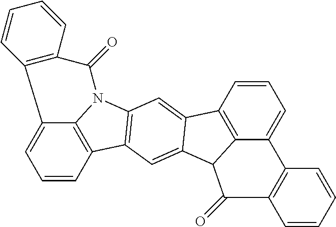 [SMILES: O=C1c2ccccc2-c2cccc3c2C1c1cc2c4cccc5c6ccccc6c(=O)n(c2cc1-3)c54]

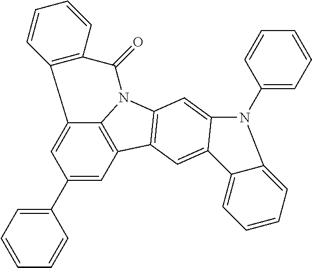 [SMILES: O=c1c2ccccc2c2cc(-c3ccccc3)cc3c4cc5c6ccccc6n(-c6ccccc6)c5cc4n1c23]

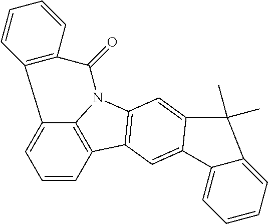 [SMILES: CC1(C)c2ccccc2-c2cc3c4cccc5c6ccccc6c(=O)n(c3cc21)c54]

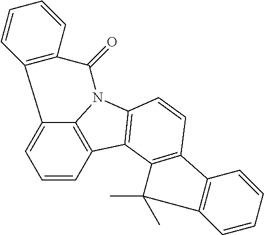 [SMILES: CC1(C)c2ccccc2-c2ccc3c(c21)c1cccc2c4ccccc4c(=O)n3c21]

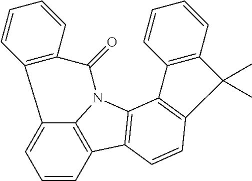 [SMILES: CC1(C)c2ccccc2-c2c1ccc1c3cccc4c5ccccc5c(=O)n(c21)c43]

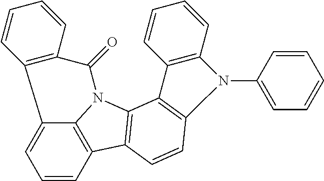 [SMILES: O=c1c2ccccc2c2cccc3c4ccc5c(c6ccccc6n5-c5ccccc5)c4n1c23]

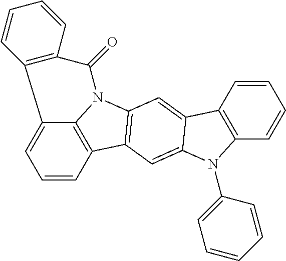 [SMILES: O=c1c2ccccc2c2cccc3c4cc5c(cc4n1c23)c1ccccc1n5-c1ccccc1]

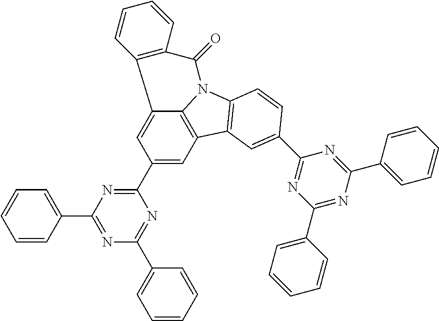 [SMILES: O=c1c2ccccc2c2cc(-c3nc(-c4ccccc4)nc(-c4ccccc4)n3)cc3c4cc(-c5nc(-c6ccccc6)nc(-c6ccccc6)n5)ccc4n1c23]

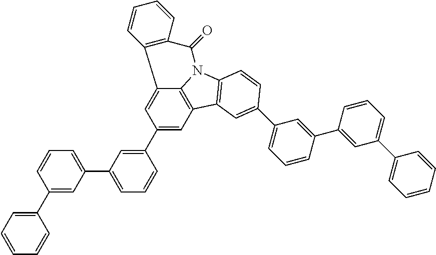 [SMILES: O=c1c2ccccc2c2cc(-c3cccc(-c4cccc(-c5ccccc5)c4)c3)cc3c4cc(-c5cccc(-c6cccc(-c7ccccc7)c6)c5)ccc4n1c23]

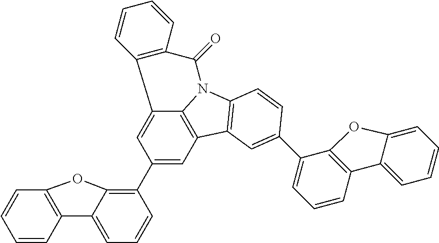 [SMILES: O=c1c2ccccc2c2cc(-c3cccc4c3oc3ccccc34)cc3c4cc(-c5cccc6c5oc5ccccc56)ccc4n1c23]

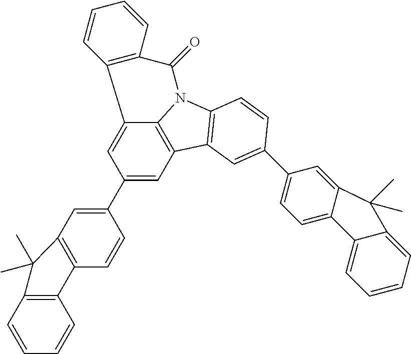 [SMILES: CC1(C)c2ccccc2-c2ccc(-c3ccc4c(c3)c3cc(-c5ccc6c(c5)C(C)(C)c5ccccc5-6)cc5c6ccccc6c(=O)n4c53)cc21]

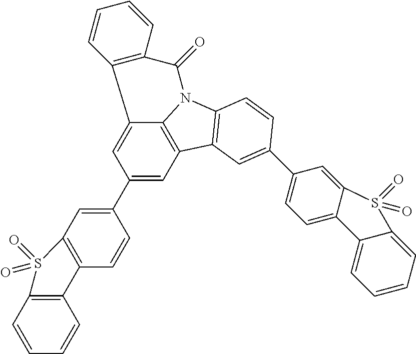

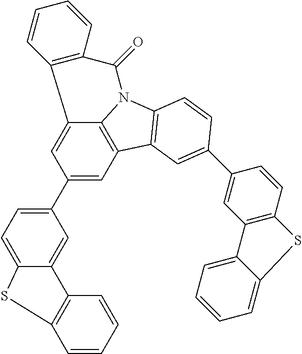

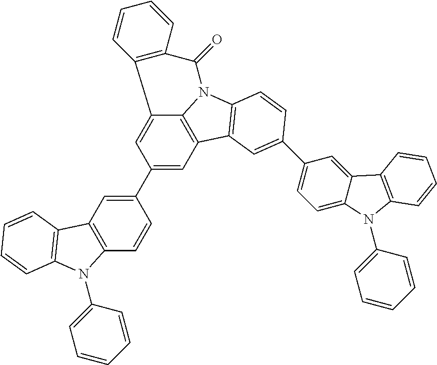 [SMILES: O=c1c2ccccc2c2cc(-c3ccc4c(c3)c3ccccc3n4-c3ccccc3)cc3c4cc(-c5ccc6c(c5)c5ccccc5n6-c5ccccc5)ccc4n1c23]

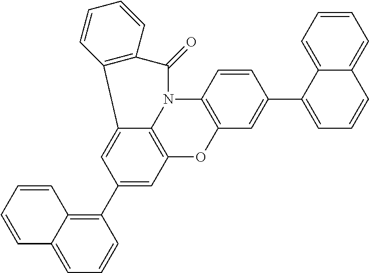 [SMILES: O=c1c2ccccc2c2cc(-c3cccc4ccccc34)cc3c2n1-c1ccc(-c2cccc4ccccc24)cc1O3]

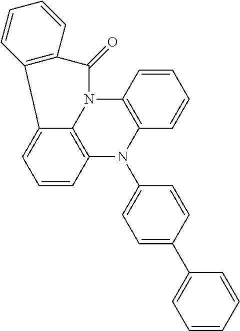 [SMILES: O=c1c2ccccc2c2cccc3c2n1-c1ccccc1N3c1ccc(-c2ccccc2)cc1]

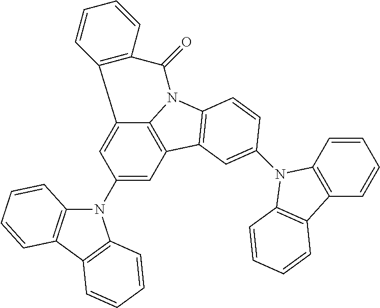 [SMILES: O=c1c2ccccc2c2cc(-n3c4ccccc4c4ccccc43)cc3c4cc(-n5c6ccccc6c6ccccc65)ccc4n1c23]

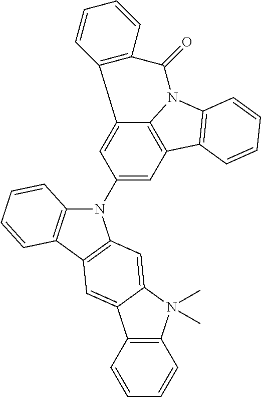

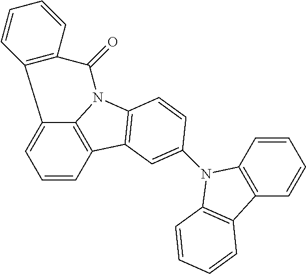 [SMILES: O=c1c2ccccc2c2cccc3c4cc(-n5c6ccccc6c6ccccc65)ccc4n1c23]

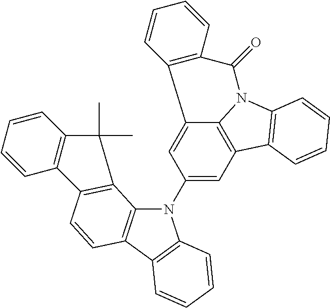 [SMILES: CC1(C)c2ccccc2-c2ccc3c4ccccc4n(-c4cc5c6ccccc6c(=O)n6c7ccccc7c(c4)c56)c3c21]

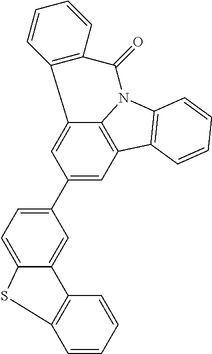 [SMILES: O=c1c2ccccc2c2cc(-c3ccc4sc5ccccc5c4c3)cc3c4ccccc4n1c23]

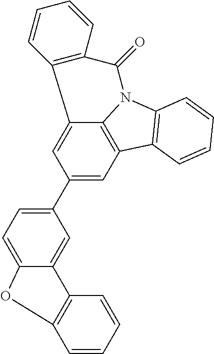 [SMILES: O=c1c2ccccc2c2cc(-c3ccc4oc5ccccc5c4c3)cc3c4ccccc4n1c23]

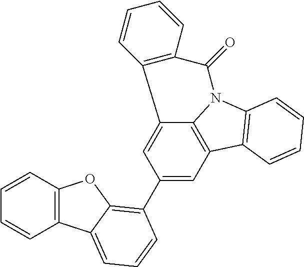 [SMILES: O=c1c2ccccc2c2cc(-c3cccc4c3oc3ccccc34)cc3c4ccccc4n1c23]

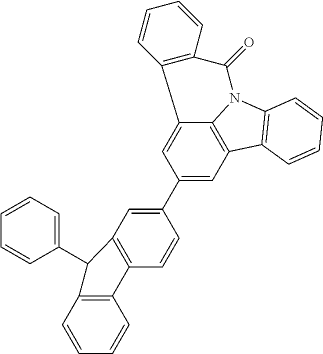 [SMILES: O=c1c2ccccc2c2cc(-c3ccc4c(c3)C(c3ccccc3)c3ccccc3-4)cc3c4ccccc4n1c23]

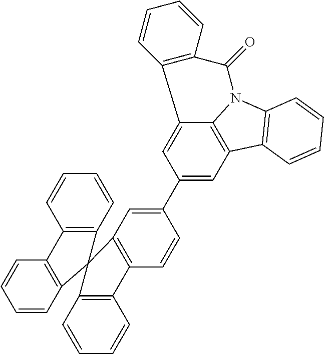 [SMILES: O=c1c2ccccc2c2cc(-c3ccc4c(c3)C3(c5ccccc5-c5ccccc53)c3ccccc3-4)cc3c4ccccc4n1c23]

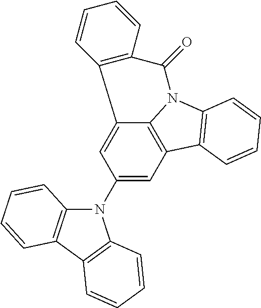 [SMILES: O=c1c2ccccc2c2cc(-n3c4ccccc4c4ccccc43)cc3c4ccccc4n1c23]

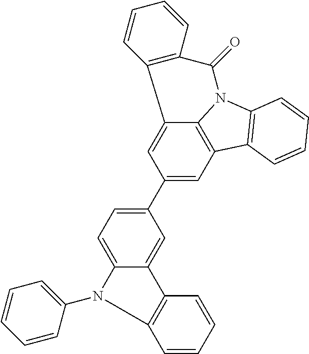 [SMILES: O=c1c2ccccc2c2cc(-c3ccc4c(c3)c3ccccc3n4-c3ccccc3)cc3c4ccccc4n1c23]

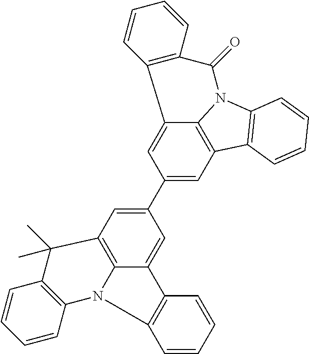 [SMILES: CC1(C)c2ccccc2-n2c3ccccc3c3cc(-c4cc5c6ccccc6c(=O)n6c7ccccc7c(c4)c56)cc1c32]

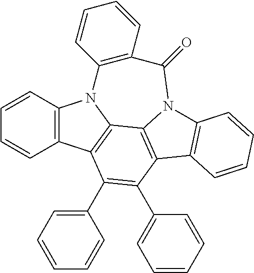 [SMILES: O=c1c2ccccc2n2c3ccccc3c3c(-c4ccccc4)c(-c4ccccc4)c4c5ccccc5n1c4c32]

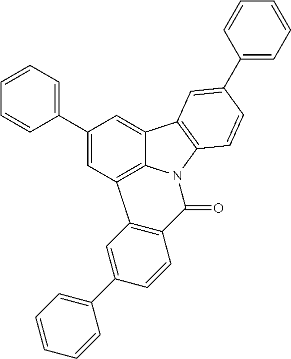 [SMILES: O=c1c2ccc(-c3ccccc3)cc2c2cc(-c3ccccc3)cc3c4cc(-c5ccccc5)ccc4n1c23]

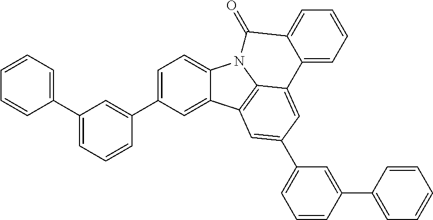 [SMILES: O=c1c2ccccc2c2cc(-c3cccc(-c4ccccc4)c3)cc3c4cc(-c5cccc(-c6ccccc6)c5)ccc4n1c23]

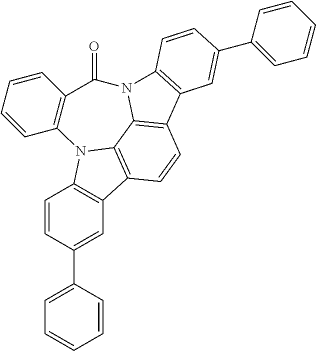 [SMILES: O=c1c2ccccc2n2c3ccc(-c4ccccc4)cc3c3ccc4c5cc(-c6ccccc6)ccc5n1c4c32]

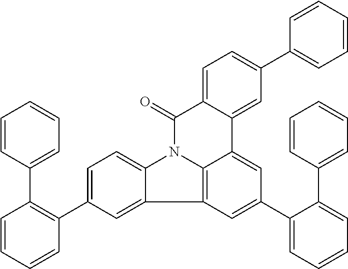 [SMILES: O=c1c2ccc(-c3ccccc3)cc2c2cc(-c3ccccc3-c3ccccc3)cc3c4cc(-c5ccccc5-c5ccccc5)ccc4n1c23]

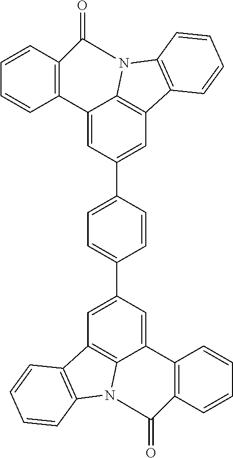 [SMILES: O=c1c2ccccc2c2cc(-c3ccc(-c4cc5c6ccccc6c(=O)n6c7ccccc7c(c4)c56)cc3)cc3c4ccccc4n1c23]

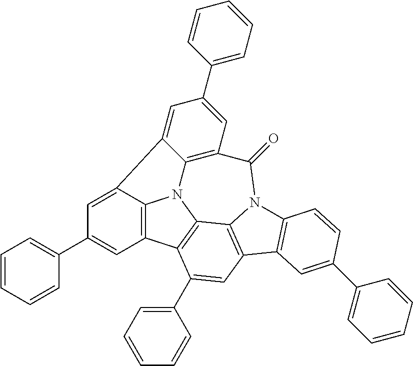 [SMILES: O=c1c2cc(-c3ccccc3)cc3c4cc(-c5ccccc5)cc5c6c(-c7ccccc7)cc7c8cc(-c9ccccc9)ccc8n1c7c6n(c23)c45]

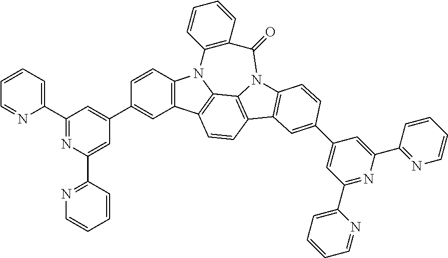 [SMILES: O=c1c2ccccc2n2c3ccc(-c4cc(-c5ccccn5)nc(-c5ccccn5)c4)cc3c3ccc4c5cc(-c6cc(-c7ccccn7)nc(-c7ccccn7)c6)ccc5n1c4c32]

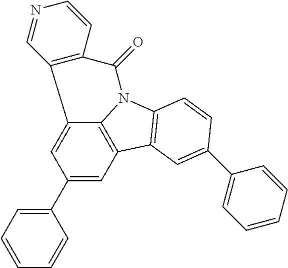 [SMILES: O=c1c2ccncc2c2cc(-c3ccccc3)cc3c4cc(-c5ccccc5)ccc4n1c23]

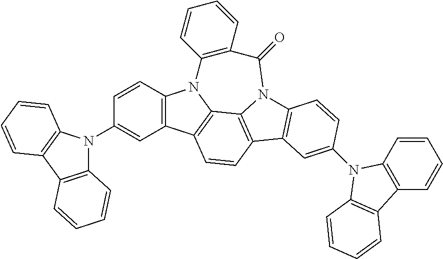 [SMILES: O=c1c2ccccc2n2c3ccc(-n4c5ccccc5c5ccccc54)cc3c3ccc4c5cc(-n6c7ccccc7c7ccccc76)ccc5n1c4c32]

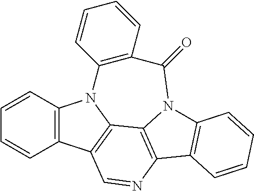 [SMILES: O=c1c2ccccc2n2c3ccccc3c3cnc4c5ccccc5n1c4c32]

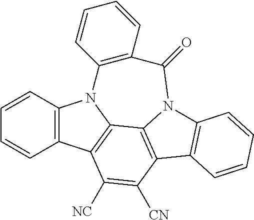 [SMILES: N#Cc1c(C#N)c2c3ccccc3n3c4ccccc4c(=O)n4c5ccccc5c1c4c23]

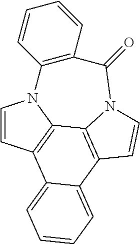 [SMILES: O=c1c2ccccc2n2ccc3c4ccccc4c4ccn1c4c32]

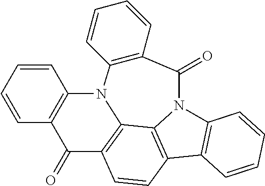 [SMILES: O=c1c2ccccc2n2c3ccccc3c(=O)n3c4ccccc4c4ccc1c2c43]

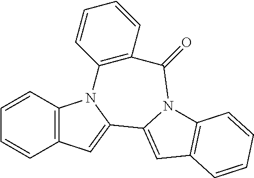 [SMILES: O=c1c2ccccc2n2c3ccccc3cc2c2cc3ccccc3n12]

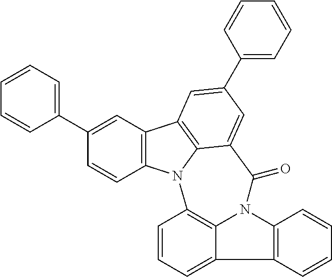 [SMILES: O=c1c2cc(-c3ccccc3)cc3c4cc(-c5ccccc5)ccc4n(c4cccc5c6ccccc6n1c54)c23]

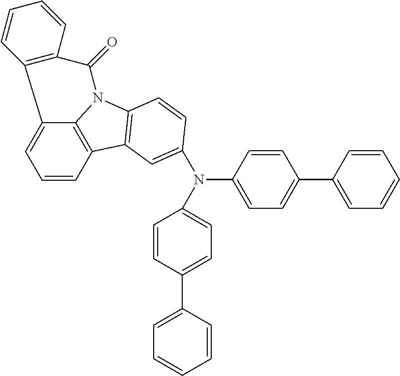 [SMILES: O=c1c2ccccc2c2cccc3c4cc(N(c5ccc(-c6ccccc6)cc5)c5ccc(-c6ccccc6)cc5)ccc4n1c23]

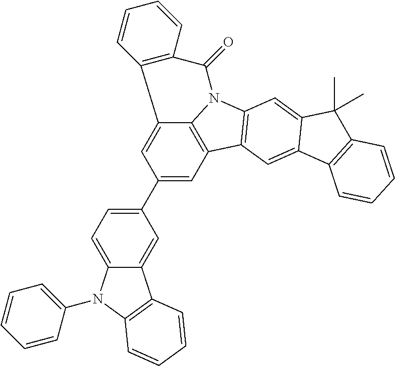 [SMILES: CC1(C)c2ccccc2-c2cc3c4cc(-c5ccc6c(c5)c5ccccc5n6-c5ccccc5)cc5c6ccccc6c(=O)n(c3cc21)c54]

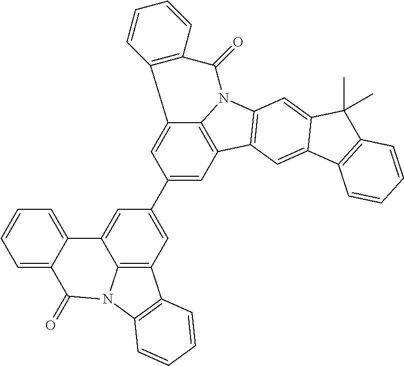 [SMILES: CC1(C)c2ccccc2-c2cc3c4cc(-c5cc6c7ccccc7c(=O)n7c8ccccc8c(c5)c67)cc5c6ccccc6c(=O)n(c3cc21)c54]

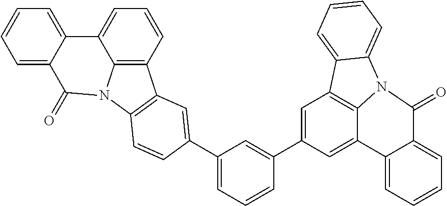 [SMILES: O=c1c2ccccc2c2cccc3c4cc(-c5cccc(-c6cc7c8ccccc8c(=O)n8c9ccccc9c(c6)c78)c5)ccc4n1c23]

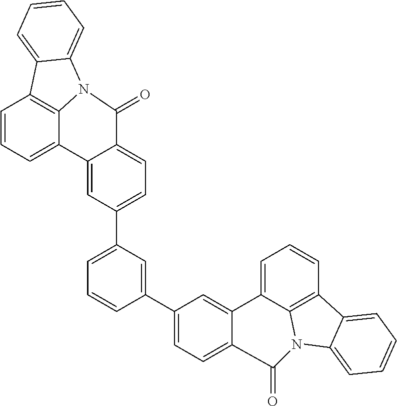 [SMILES: O=c1c2ccc(-c3cccc(-c4ccc5c(=O)n6c7ccccc7c7cccc(c5c4)c76)c3)cc2c2cccc3c4ccccc4n1c23]

Furthermore, aromatic ketones or aromatic phosphine oxides are suitable as electron-transport material in the electron-transport layer according to the invention. An aromatic ketone in the sense of this application is taken to mean a carbonyl group to which two aromatic or heteroaromatic groups or aromatic or heteroaromatic ring systems are bonded directly. An aromatic phosphine oxide in the sense of this application is taken to mean a P═O group to which three aromatic or heteroaromatic groups or aromatic or heteroaromatic ring systems are bonded directly.

If the electron-transport material in the electron-transport layer according to the invention is an aromatic ketone or an aromatic phosphine oxide, this compound is then preferably selected from the compounds of the following formulae (70) and (71),

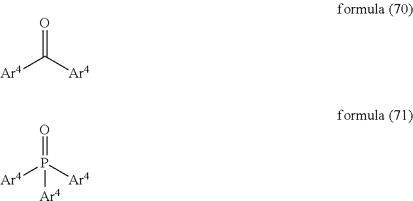

where R, R¹, R² and Ar have the above-mentioned meanings, and the following applies to the other symbols used:
Ar⁴ is on each occurrence, identically or differently, an aromatic or heteroaromatic ring system having 5 to 80 aromatic ring atoms, preferably up to 60 aromatic ring atoms, which may in each case be substituted by one or more groups R.

Suitable compounds of the formulae (70) and (71) are, in particular, the ketones disclosed in WO 2004/093207 and WO 2010/006680 and the phosphine oxides disclosed in WO 2005/003253. These are incorporated into the present invention by way of reference.

It is evident from the definition of the compounds of the formulae (70) and (71) that they do not have to contain just one carbonyl group or phosphine oxide group, but instead may also contain a plurality of these groups.

The group Ar⁴ in compounds of the formulae (70) and (71) is preferably an aromatic ring system having 6 to 40 aromatic ring atoms, i.e. it does not contain any heteroaryl groups. As defined above, the aromatic ring system does not necessarily have to contain only aromatic groups, but instead two aryl groups may also be interrupted by a non-aromatic group, for example by a further carbonyl group or phosphine oxide group.

In a further preferred embodiment of the invention, the group Ar⁴ contains not more than two condensed rings. It is thus preferably built up only from phenyl and/or naphthyl groups, particularly preferably only from phenyl groups, but does not contain any larger condensed aromatic groups, such as, for example, anthracene.

Preferred groups Ar⁴ which are bonded to the carbonyl group are phenyl, 2-, 3- or 4-tolyl, 3- or 4-o-xylyl, 2- or 4-m-xylyl, 2-p-xylyl, o-, m- or p-tert-butylphenyl, o-, m- or p-fluorophenyl, benzophenone, 1-, 2- or 3-phenylmethanone, 2-, 3- or 4-biphenyl, 2-, 3- or 4-o-terphenyl, 2-, 3- or 4-m-terphenyl, 2-, 3- or 4-p-terphenyl, 2′-p-terphenyl, 2′-, 4′- or 5′-m-terphenyl, 3′- or 4′-o-terphenyl, p-, m,p-, o,p-, m,m-, o,m- or o,o-quaterphenyl, quinquephenyl, sexiphenyl, 1-, 2-, 3- or 4-fluorenyl, 2-, 3- or 4-spiro-9,9′-bifluorenyl, 1-, 2-, 3- or 4-(9,10-dihydro)phenanthrenyl, 1- or 2-naphthyl, 2-, 3-, 4-, 5-, 6-, 7- or 8-quinolinyl, 1-, 3-, 4-, 5-, 6-, 7- or 8-isoquinolinyl, 1- or 2-(4-methylnaphthyl), 1- or 2-(4-phenylnaphthyl), 1- or 2-(4-naphthylnaphthyl), 1-, 2- or 3-(4-naphthylphenyl), 2-, 3- or 4-pyridyl, 2-, 4- or 5-pyrimidinyl, 2- or 3-pyrazinyl, 3- or 4-pyridanzinyl, 2-(1,3,5-triazin)yl-, 2-, 3- or 4-(phenylpyridyl), 3-, 4-, 5- or 6-(2,2′-bipyridyl), 2-, 4-, 5- or 6-(3,3′-bipyridyl), 2- or 3-(4,4′-bipyridyl), and combinations of one or more of these radicals.

The groups Ar⁴ may be substituted by one or more radicals R. These radicals R are preferably selected, identically or differently on each occurrence, from the group consisting of H, D, F, C(═O)Ar, P(═O)(Ar)₂, S(═O)Ar, S(═O)₂Ar, a straight-chain alkyl group having 1 to 4 C atoms or a branched or cyclic alkyl group having 3 to 5 C atoms, each of which may be substituted by one or more radicals R¹, where one or more H atoms may be replaced by F, or an aromatic ring system having 6 to 24 aromatic ring atoms, which may be substituted by one or more radicals R¹, or a combination of these systems; two or more adjacent substituents R here may also form a mono- or polycyclic, aliphatic or aromatic ring system with one another. If the organic electroluminescent device is applied from solution, straight-chain, branched or cyclic alkyl groups having up to 10 C atoms are also preferred as substituents R. The radicals R are particularly preferably selected, identically or differently on each occurrence, from the group consisting of H, C(═O)Ar or an aromatic ring system having 6 to 24 aromatic ring atoms, which may be substituted by one or more radicals R¹, but is preferably unsubstituted.

In a further preferred embodiment of the invention, the group Ar is, identically or differently on each occurrence, an aromatic ring system having 6 to 24 aromatic ring atoms, which may be substituted by one or more radicals R¹. Ar is particularly preferably, identically or differently on each occurrence, an aromatic ring system having 6 to 12 aromatic ring atoms.

Particular preference is given to benzophenone derivatives which are substituted in each of the 3,5,3′,5′-positions by an aromatic or heteroaromatic ring system having 5 to 30 aromatic ring atoms, which may in turn be substituted by one or more radicals R in accordance with the above definition. Preference is furthermore given to ketones which are substituted by at least one spirobifluorene group.

Preferred aromatic ketones and phosphine oxides are therefore the compounds of the following formulae (72) to (75),

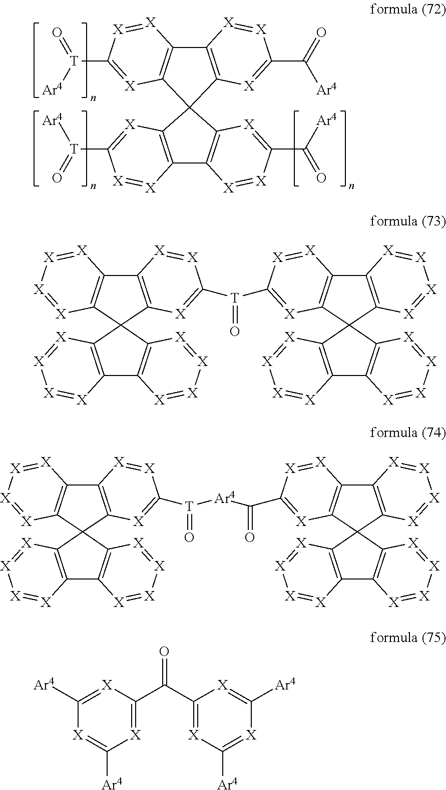

where X, Ar⁴, R, R¹ and R² have the same meaning as described above, and furthermore:
T is, identically or differently on each occurrence, C or P(Ar⁴);
n is, identically or differently on each occurrence, 0 or 1.

Ar⁴ in the above-mentioned formulae (72) and (75) preferably stands for an aromatic or heteroaromatic ring system having 5 to 30 aromatic ring atoms, which may be substituted by one or more radicals R¹. Particular preference is given to the groups Ar⁴ mentioned above.

Examples of suitable compounds of the formulae (70) and (71) are the compounds depicted in the following table.

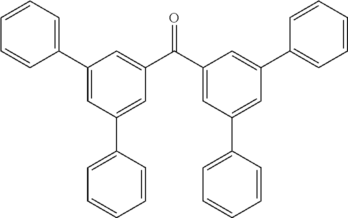 [SMILES: O=C(c1cc(-c2ccccc2)cc(-c2ccccc2)c1)c1cc(-c2ccccc2)cc(-c2ccccc2)c1]

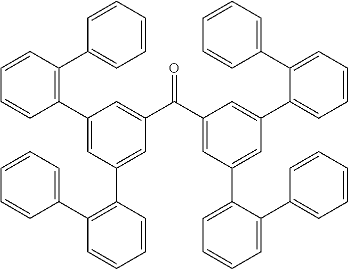 [SMILES: O=C(c1cc(-c2ccccc2-c2ccccc2)cc(-c2ccccc2-c2ccccc2)c1)c1cc(-c2ccccc2-c2ccccc2)cc(-c2ccccc2-c2ccccc2)c1]

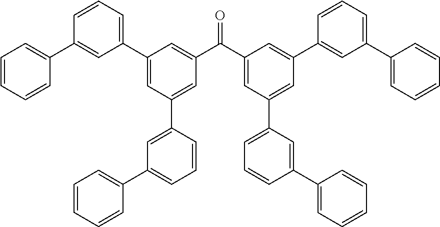 [SMILES: O=C(c1cc(-c2cccc(-c3ccccc3)c2)cc(-c2cccc(-c3ccccc3)c2)c1)c1cc(-c2cccc(-c3ccccc3)c2)cc(-c2cccc(-c3ccccc3)c2)c1]

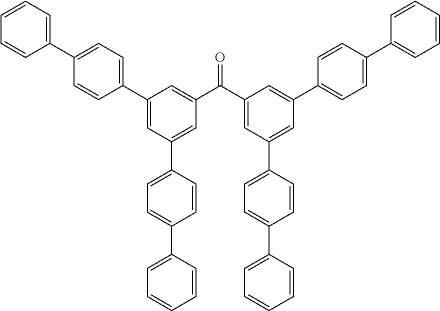 [SMILES: O=C(c1cc(-c2ccc(-c3ccccc3)cc2)cc(-c2ccc(-c3ccccc3)cc2)c1)c1cc(-c2ccc(-c3ccccc3)cc2)cc(-c2ccc(-c3ccccc3)cc2)c1]

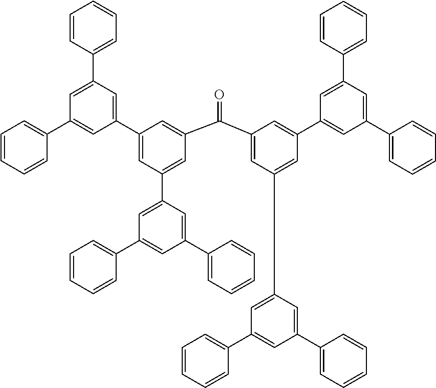 [SMILES: O=C(c1cc(-c2cc(-c3ccccc3)cc(-c3ccccc3)c2)cc(-c2cc(-c3ccccc3)cc(-c3ccccc3)c2)c1)c1cc(-c2cc(-c3ccccc3)cc(-c3ccccc3)c2)cc(-c2cc(-c3ccccc3)cc(-c3ccccc3)c2)c1]

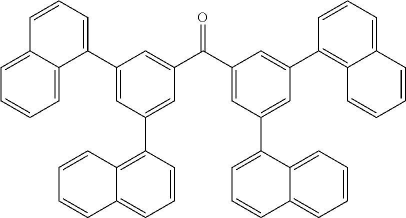 [SMILES: O=C(c1cc(-c2cccc3ccccc23)cc(-c2cccc3ccccc23)c1)c1cc(-c2cccc3ccccc23)cc(-c2cccc3ccccc23)c1]

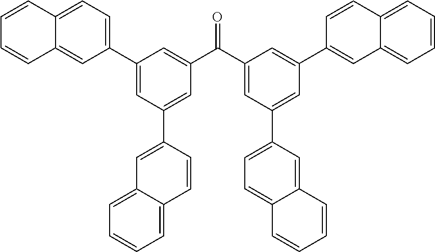 [SMILES: O=C(c1cc(-c2ccc3ccccc3c2)cc(-c2ccc3ccccc3c2)c1)c1cc(-c2ccc3ccccc3c2)cc(-c2ccc3ccccc3c2)c1]

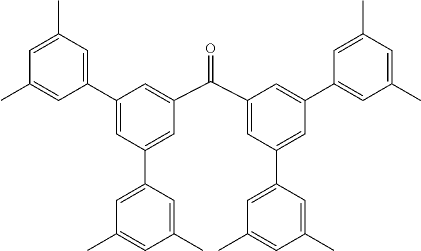

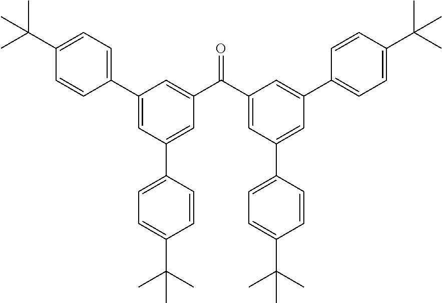 [SMILES: CC(C)(C)c1ccc(-c2cc(C(=O)c3cc(-c4ccc(C(C)(C)C)cc4)cc(-c4ccc(C(C)(C)C)cc4)c3)cc(-c3ccc(C(C)(C)C)cc3)c2)cc1]

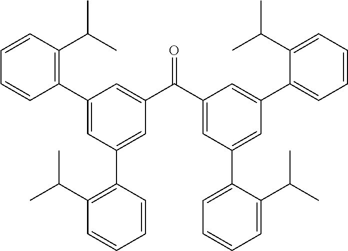 [SMILES: CC(C)c1ccccc1-c1cc(C(=O)c2cc(-c3ccccc3C(C)C)cc(-c3ccccc3C(C)C)c2)cc(-c2ccccc2C(C)C)c1]

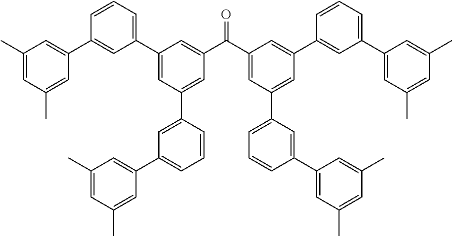

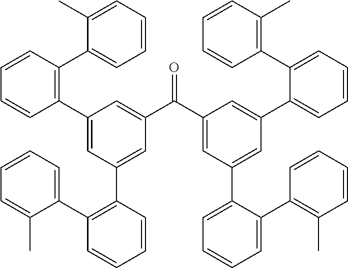 [SMILES: Cc1ccccc1-c1ccccc1-c1cc(C(=O)c2cc(-c3ccccc3-c3ccccc3C)cc(-c3ccccc3-c3ccccc3C)c2)cc(-c2ccccc2-c2ccccc2C)c1]

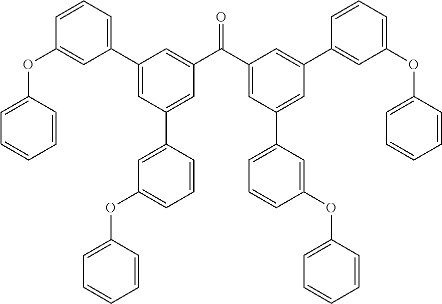 [SMILES: O=C(c1cc(-c2cccc(Oc3ccccc3)c2)cc(-c2cccc(Oc3ccccc3)c2)c1)c1cc(-c2cccc(Oc3ccccc3)c2)cc(-c2cccc(Oc3ccccc3)c2)c1]

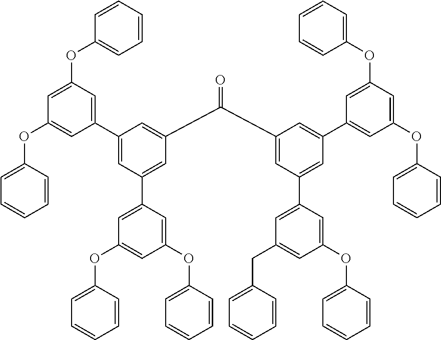 [SMILES: O=C(c1cc(-c2cc(Cc3ccccc3)cc(Oc3ccccc3)c2)cc(-c2cc(Oc3ccccc3)cc(Oc3ccccc3)c2)c1)c1cc(-c2cc(Oc3ccccc3)cc(Oc3ccccc3)c2)cc(-c2cc(Oc3ccccc3)cc(Oc3ccccc3)c2)c1]

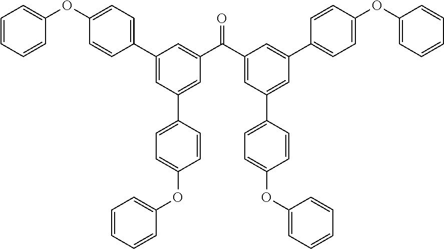 [SMILES: O=C(c1cc(-c2ccc(Oc3ccccc3)cc2)cc(-c2ccc(Oc3ccccc3)cc2)c1)c1cc(-c2ccc(Oc3ccccc3)cc2)cc(-c2ccc(Oc3ccccc3)cc2)c1]

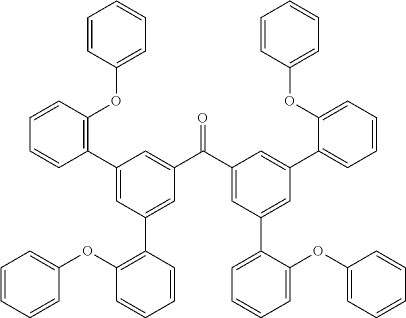 [SMILES: O=C(c1cc(-c2ccccc2Oc2ccccc2)cc(-c2ccccc2Oc2ccccc2)c1)c1cc(-c2ccccc2Oc2ccccc2)cc(-c2ccccc2Oc2ccccc2)c1]

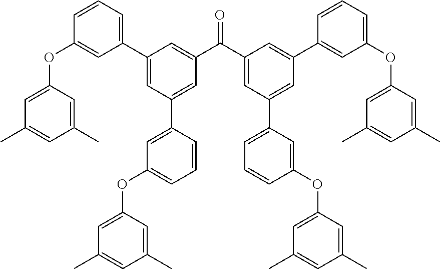

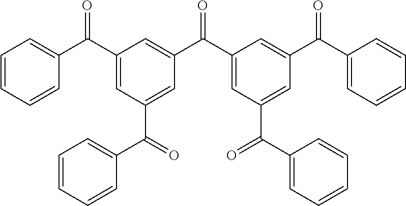 [SMILES: O=C(c1ccccc1)c1cc(C(=O)c2ccccc2)cc(C(=O)c2cc(C(=O)c3ccccc3)cc(C(=O)c3ccccc3)c2)c1]

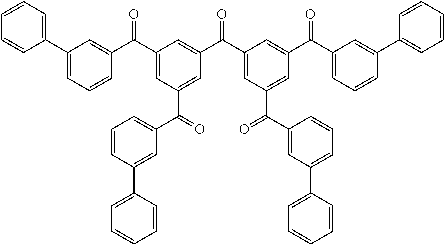 [SMILES: O=C(c1cc(C(=O)c2cccc(-c3ccccc3)c2)cc(C(=O)c2cccc(-c3ccccc3)c2)c1)c1cc(C(=O)c2cccc(-c3ccccc3)c2)cc(C(=O)c2cccc(-c3ccccc3)c2)c1]

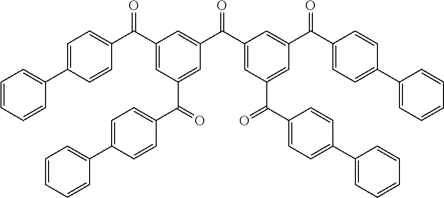 [SMILES: O=C(c1ccc(-c2ccccc2)cc1)c1cc(C(=O)c2ccc(-c3ccccc3)cc2)cc(C(=O)c2cc(C(=O)c3ccc(-c4ccccc4)cc3)cc(C(=O)c3ccc(-c4ccccc4)cc3)c2)c1]

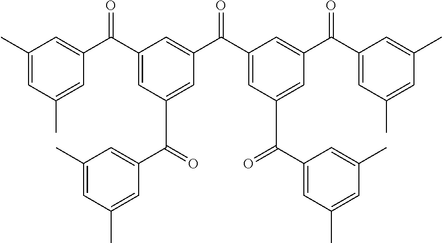

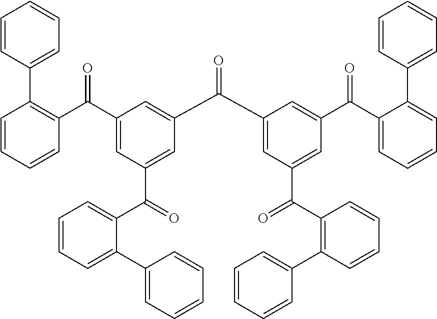 [SMILES: O=C(c1cc(C(=O)c2ccccc2-c2ccccc2)cc(C(=O)c2ccccc2-c2ccccc2)c1)c1cc(C(=O)c2ccccc2-c2ccccc2)cc(C(=O)c2ccccc2-c2ccccc2)c1]

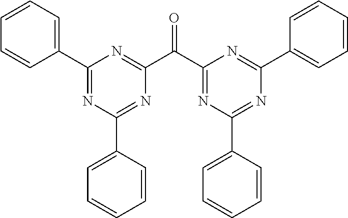 [SMILES: O=C(c1nc(-c2ccccc2)nc(-c2ccccc2)n1)c1nc(-c2ccccc2)nc(-c2ccccc2)n1]

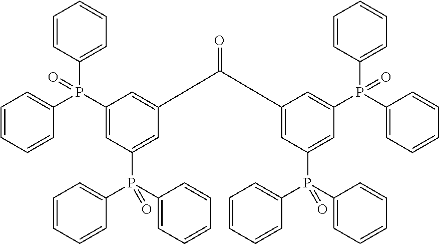 [SMILES: O=C(c1cc(P(=O)(c2ccccc2)c2ccccc2)cc(P(=O)(c2ccccc2)c2ccccc2)c1)c1cc(P(=O)(c2ccccc2)c2ccccc2)cc(P(=O)(c2ccccc2)c2ccccc2)c1]

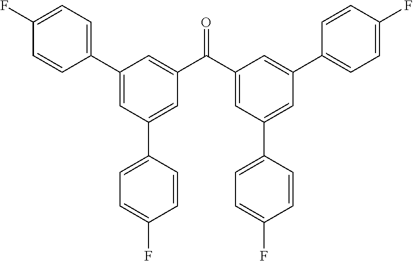 [SMILES: O=C(c1cc(-c2ccc(F)cc2)cc(-c2ccc(F)cc2)c1)c1cc(-c2ccc(F)cc2)cc(-c2ccc(F)cc2)c1]

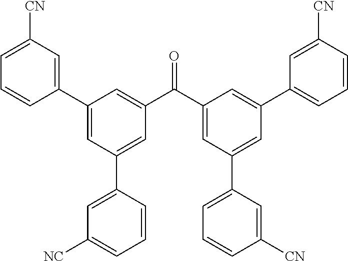 [SMILES: N#Cc1cccc(-c2cc(C(=O)c3cc(-c4cccc(C#N)c4)cc(-c4cccc(C#N)c4)c3)cc(-c3cccc(C#N)c3)c2)c1]

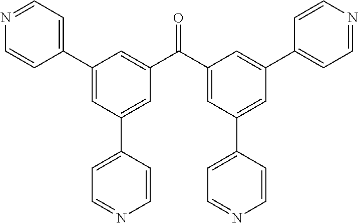 [SMILES: O=C(c1cc(-c2ccncc2)cc(-c2ccncc2)c1)c1cc(-c2ccncc2)cc(-c2ccncc2)c1]

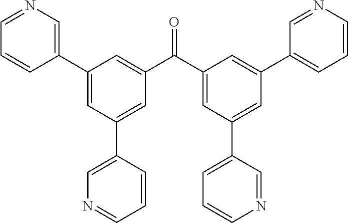 [SMILES: O=C(c1cc(-c2cccnc2)cc(-c2cccnc2)c1)c1cc(-c2cccnc2)cc(-c2cccnc2)c1]

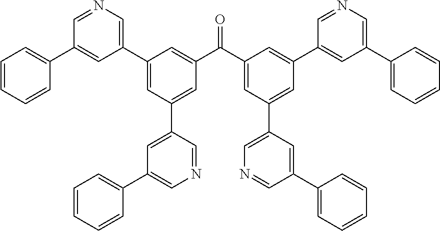 [SMILES: O=C(c1cc(-c2cncc(-c3ccccc3)c2)cc(-c2cncc(-c3ccccc3)c2)c1)c1cc(-c2cncc(-c3ccccc3)c2)cc(-c2cncc(-c3ccccc3)c2)c1]

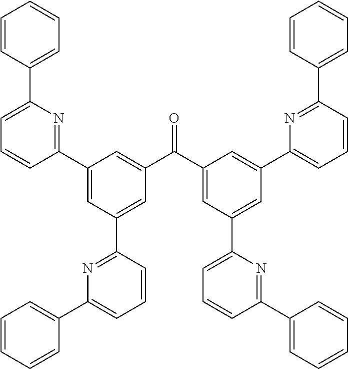 [SMILES: O=C(c1cc(-c2cccc(-c3ccccc3)n2)cc(-c2cccc(-c3ccccc3)n2)c1)c1cc(-c2cccc(-c3ccccc3)n2)cc(-c2cccc(-c3ccccc3)n2)c1]

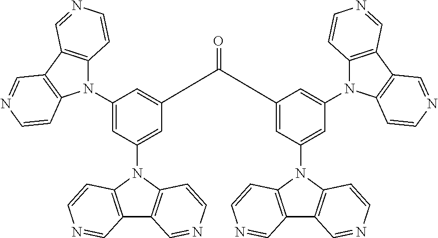 [SMILES: O=C(c1cc(-n2c3ccncc3c3cnccc32)cc(-n2c3ccncc3c3cnccc32)c1)c1cc(-n2c3ccncc3c3cnccc32)cc(-n2c3ccncc3c3cnccc32)c1]

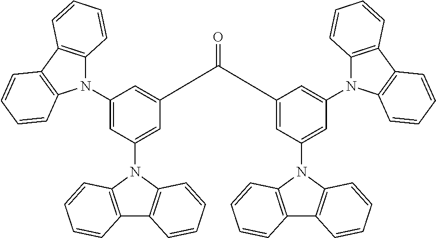 [SMILES: O=C(c1cc(-n2c3ccccc3c3ccccc32)cc(-n2c3ccccc3c3ccccc32)c1)c1cc(-n2c3ccccc3c3ccccc32)cc(-n2c3ccccc3c3ccccc32)c1]

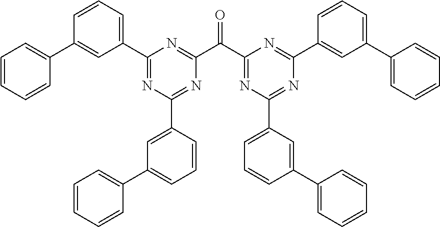 [SMILES: O=C(c1nc(-c2cccc(-c3ccccc3)c2)nc(-c2cccc(-c3ccccc3)c2)n1)c1nc(-c2cccc(-c3ccccc3)c2)nc(-c2cccc(-c3ccccc3)c2)n1]

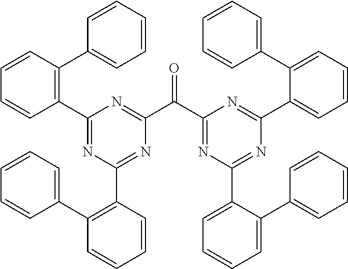 [SMILES: O=C(c1nc(-c2ccccc2-c2ccccc2)nc(-c2ccccc2-c2ccccc2)n1)c1nc(-c2ccccc2-c2ccccc2)nc(-c2ccccc2-c2ccccc2)n1]

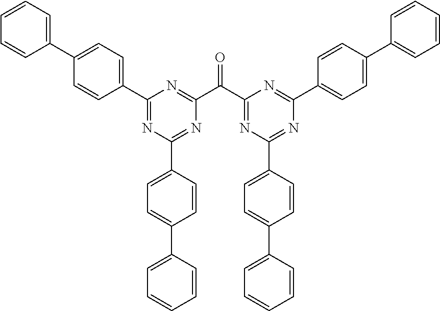 [SMILES: O=C(c1nc(-c2ccc(-c3ccccc3)cc2)nc(-c2ccc(-c3ccccc3)cc2)n1)c1nc(-c2ccc(-c3ccccc3)cc2)nc(-c2ccc(-c3ccccc3)cc2)n1]

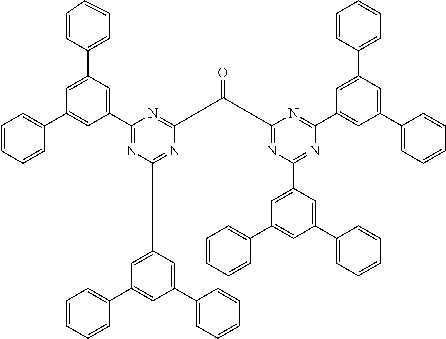 [SMILES: O=C(c1nc(-c2cc(-c3ccccc3)cc(-c3ccccc3)c2)nc(-c2cc(-c3ccccc3)cc(-c3ccccc3)c2)n1)c1nc(-c2cc(-c3ccccc3)cc(-c3ccccc3)c2)nc(-c2cc(-c3ccccc3)cc(-c3ccccc3)c2)n1]

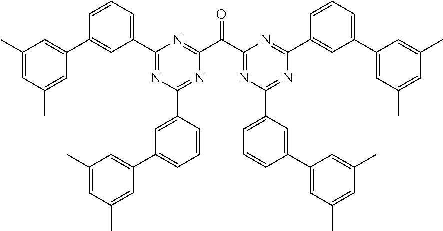

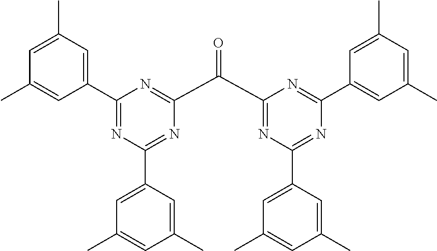

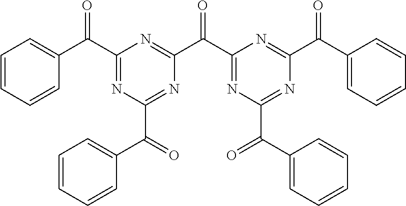 [SMILES: O=C(c1ccccc1)c1nc(C(=O)c2ccccc2)nc(C(=O)c2nc(C(=O)c3ccccc3)nc(C(=O)c3ccccc3)n2)n1]

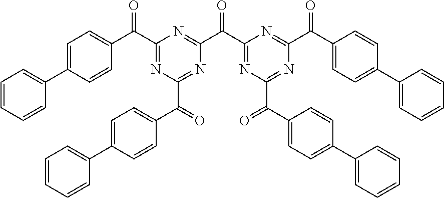 [SMILES: O=C(c1ccc(-c2ccccc2)cc1)c1nc(C(=O)c2ccc(-c3ccccc3)cc2)nc(C(=O)c2nc(C(=O)c3ccc(-c4ccccc4)cc3)nc(C(=O)c3ccc(-c4ccccc4)cc3)n2)n1]

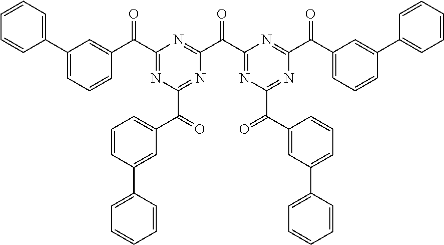 [SMILES: O=C(c1cccc(-c2ccccc2)c1)c1nc(C(=O)c2cccc(-c3ccccc3)c2)nc(C(=O)c2nc(C(=O)c3cccc(-c4ccccc4)c3)nc(C(=O)c3cccc(-c4ccccc4)c3)n2)n1]

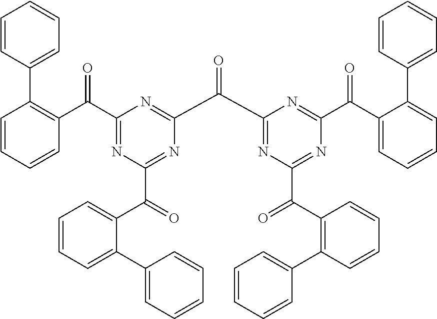 [SMILES: O=C(c1nc(C(=O)c2ccccc2-c2ccccc2)nc(C(=O)c2ccccc2-c2ccccc2)n1)c1nc(C(=O)c2ccccc2-c2ccccc2)nc(C(=O)c2ccccc2-c2ccccc2)n1]

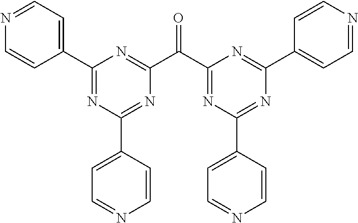 [SMILES: O=C(c1nc(-c2ccncc2)nc(-c2ccncc2)n1)c1nc(-c2ccncc2)nc(-c2ccncc2)n1]

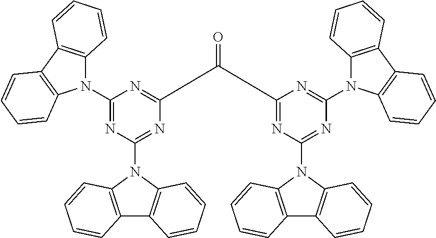 [SMILES: O=C(c1nc(-n2c3ccccc3c3ccccc32)nc(-n2c3ccccc3c3ccccc32)n1)c1nc(-n2c3ccccc3c3ccccc32)nc(-n2c3ccccc3c3ccccc32)n1]

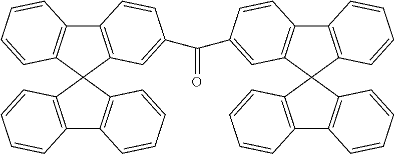 [SMILES: O=C(c1ccc2c(c1)C1(c3ccccc3-c3ccccc31)c1ccccc1-2)c1ccc2c(c1)C1(c3ccccc3-c3ccccc31)c1ccccc1-2]

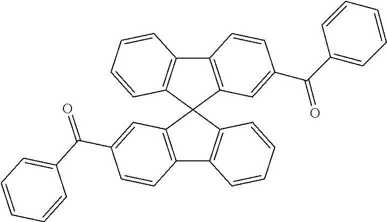 [SMILES: O=C(c1ccccc1)c1ccc2c(c1)C1(c3ccccc3-2)c2ccccc2-c2ccc(C(=O)c3ccccc3)cc21]

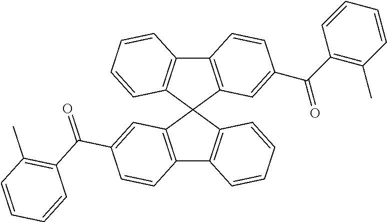 [SMILES: Cc1ccccc1C(=O)c1ccc2c(c1)C1(c3ccccc3-2)c2ccccc2-c2ccc(C(=O)c3ccccc3C)cc21]

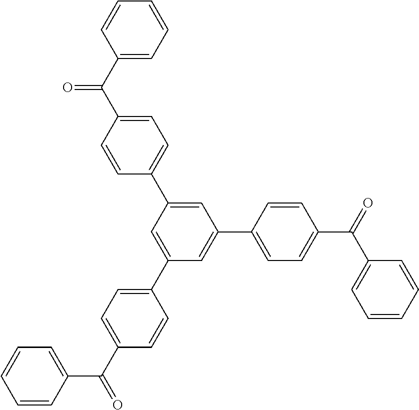 [SMILES: O=C(c1ccccc1)c1ccc(-c2cc(-c3ccc(C(=O)c4ccccc4)cc3)cc(-c3ccc(C(=O)c4ccccc4)cc3)c2)cc1]

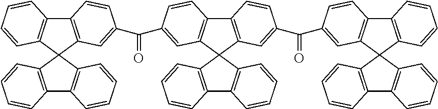 [SMILES: O=C(c1ccc2c(c1)C1(c3ccccc3-c3ccccc31)c1ccccc1-2)c1ccc2c(c1)C1(c3ccccc3-c3ccccc31)c1cc(C(=O)c3ccc4c(c3)C3(c5ccccc5-c5ccccc53)c3ccccc3-4)ccc1-2]

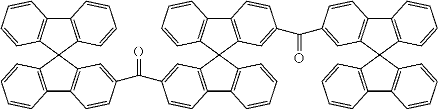 [SMILES: O=C(c1ccc2c(c1)C1(c3ccccc3-c3ccccc31)c1ccccc1-2)c1ccc2c(c1)C1(c3ccccc3-2)c2ccccc2-c2ccc(C(=O)c3ccc4c(c3)C3(c5ccccc5-c5ccccc53)c3ccccc3-4)cc21]

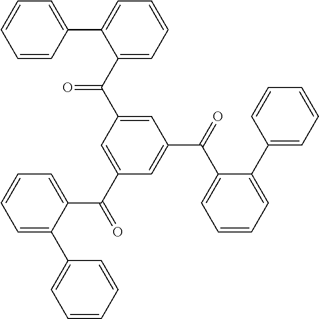 [SMILES: O=C(c1cc(C(=O)c2ccccc2-c2ccccc2)cc(C(=O)c2ccccc2-c2ccccc2)c1)c1ccccc1-c1ccccc1]

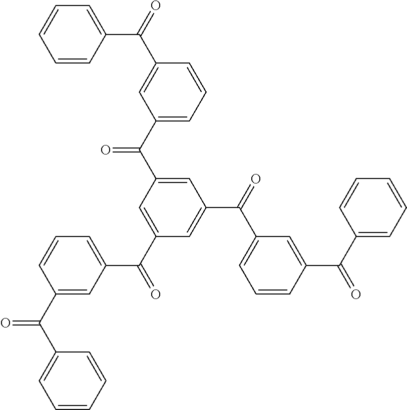 [SMILES: O=C(c1ccccc1)c1cccc(C(=O)c2cc(C(=O)c3cccc(C(=O)c4ccccc4)c3)cc(C(=O)c3cccc(C(=O)c4ccccc4)c3)c2)c1]

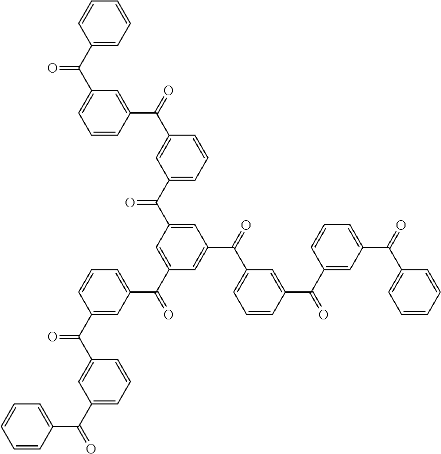 [SMILES: O=C(c1ccccc1)c1cccc(C(=O)c2cccc(C(=O)c3cc(C(=O)c4cccc(C(=O)c5cccc(C(=O)c6ccccc6)c5)c4)cc(C(=O)c4cccc(C(=O)c5cccc(C(=O)c6ccccc6)c5)c4)c3)c2)c1]

Suitable metal complexes which can be employed as electron-transport material in the electron-transport layer according to the invention are Be, Zn and Al complexes so long as the LUMO of these compounds is ≦−2.55 eV.

Examples of suitable metal complexes are the compounds depicted in the following table.

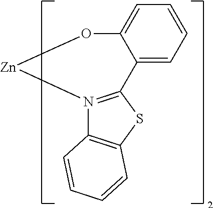

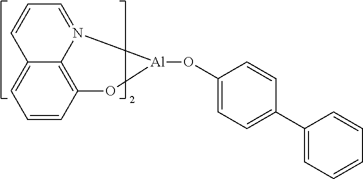

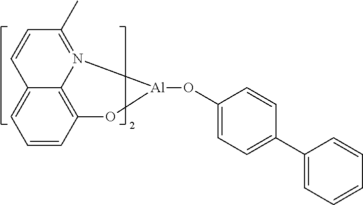

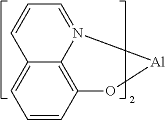

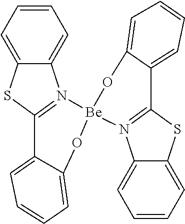

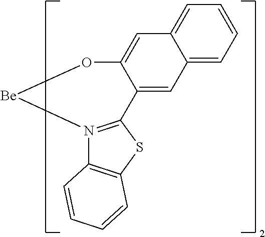

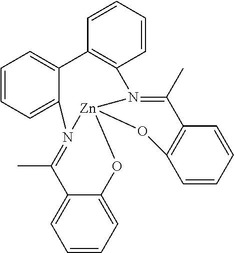

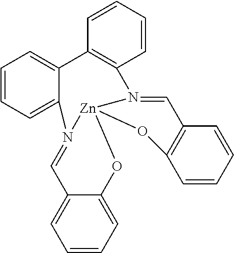

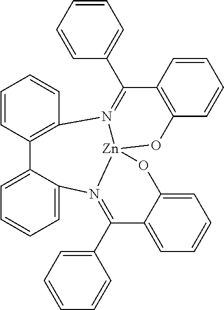

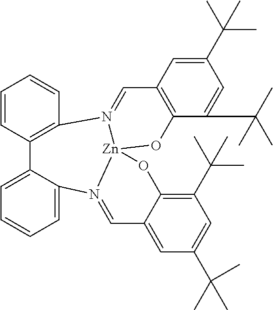

In a preferred embodiment of the invention, the electron-transport materials having an LUMO≦−2.55 eV in the electron-transport layers according to the invention are, however, purely organic materials, i.e. materials which contain no metal.

Suitable azaphospholes which can be employed as electron-conducting matrix material in the organic electroluminescent device according to the invention are compounds as disclosed in WO 2010/054730 so long as the LUMO of these compounds is ≦−2.55 eV. This application is incorporated into the present invention by way of reference.

Suitable azaboroles which can be employed as electron-conducting matrix material in the organic electroluminescent device according to the invention are azaborole derivatives which are substituted by at least one electron-conducting substituent, so long as the LUMO of these compounds is ≦−2.55 eV. Compounds of this type are disclosed in the as yet unpublished application EP 11010103.7. This application is incorporated into the present invention by way of reference.

Furthermore suitable are benzimidazole derivatives. In order that these have an LUMO≦−2.55 eV, it is preferred for a condensed aryl group, in particular an anthracene, benzanthracene or pyrene, to be bonded to the benzimidazole directly or via an optionally substituted divalent aromatic or heteroaromatic group. Both the benzimidazole and also the condensed aryl group here may optionally be substituted. Suitable substituents for the benzimidazole derivatives are the radicals R described above.

The organic electroluminescent device is described in greater detail below,

The organic electroluminescent device comprises cathode, anode, emitting layer and at least one electron-transport layer adjacent thereto on the cathode side. Apart from these layers, it may also comprise further layers, for example in each case one or more hole-injection layers, hole-transport layers, further electron-transport layers, electron-injection layers, exciton-blocking layers, electron-blocking layers and/or charge-generation layers. However, it should be pointed out that each of these layers does not necessarily have to be present.

In the other layers of the organic electroluminescent device according to the invention, in particular in the hole-injection and -transport layers and in the electron-injection and -transport layers, use can be made of all materials as are usually employed in accordance with the prior art. The hole-transport layers here may also be p-doped and the electron-transport layers may also be n-doped. A p-doped layer here is taken to mean a layer in which free holes have been generated and whose conductivity has thereby been increased. A comprehensive discussion of doped transport layers in OLEDs can be found in Chem. Rev. 2007, 107, 1233. The p-dopant is particularly preferably capable of oxidising the hole-transport material in the hole-transport layer, i.e. has a sufficiently high redox potential, in particular a higher redox potential than the hole-transport material. Suitable dopants are in principle all compounds which are electron-acceptor compounds and are able to increase the conductivity of the organic layer by oxidation of the host. The person skilled in the art will be able to identify suitable compounds without major effort on the basis of his general expert knowledge. Particularly suitable dopants are the compounds disclosed in WO 2011/073149, EP 1968131, EP 2276085, EP 2213662, EP 1722602, EP 2045848, DE 102007031220, U.S. Pat. No. 8,044,390, U.S. Pat. No. 8,057,712, WO 2009/003455, WO 2010/094378, WO 2011/120709 and US 2010/0096600.

The person skilled in the art will therefore be able to employ, without inventive step, all materials known for organic electroluminescent devices in combination with the emitting layer according to the invention.

In particular, it may be preferred for further electron-transport layers and/or electron-injection layers to be present between the electron-transport layer according to the invention and the cathode. In a preferred embodiment of the invention, the further electron-transport layer and/or electron-injection layer comprises a lithium compound, for example LiQ (lithium quinolinate). Further suitable lithium compounds are revealed by WO 2010/072300.

Furthermore, it may be preferred for the electron-transport layer which is adjacent to the cathode or, if present, to the electron-injection layer to comprise a mixture of an electron-transport material having an LUMO≦−2.55 eV and a lithium compound, in particular lithium quinolinate or a lithium quinolinate derivative.

The cathode of the electroluminescent device according to the invention preferably comprises metals having a low work function, metal alloys or multilayered structures comprising different metals, such as, for example, alkaline-earth metals, alkali metals, main-group metals or lanthanoids (for example Ca, Ba, Mg, Al, In, Mg, Yb, Sm, etc.). In the case of multilayered structures, further metals which have a relatively high work function, such as, for example, Ag, may also be used in addition to the said metals, in which case combinations of the metals, such as, for example, Mg/Ag, Ca/Ag or Ba/Ag, are generally used. Preference is likewise given to metal alloys, in particular alloys comprising an alkali-metal or alkaline-earth metal and silver, particularly preferably an alloy of Mg and Ag. It may also be preferred to introduce a thin interlayer of a material having a high dielectric constant between a metallic cathode and the organic semiconductor. Suitable for this purpose are, for example, alkali metal or alkaline-earth metal fluorides, but also the corresponding oxides or carbonates (for example LiF, Li₂O, CsF, Cs₂CO₃, BaF₂, MgO, NaF, etc.). Organic alkali-metal or alkaline-earth metal complexes, such as, for example, lithium quinolinate (LiQ), are likewise suitable. The layer thickness of this layer, which is to be regarded as the electron-injection layer, is preferably between 0.5 and 5 nm.

The anode of the electroluminescent device according to the invention preferably comprises materials having a high work function. The anode preferably has a work function of greater than 4.5 eV vs. vacuum. Suitable for this purpose are on the one hand metals having a high redox potential, such as, for example, Ag, Pt or Au. On the other hand, metal/metal oxide electrodes (for example Al/Ni/NiOₓ, Al/PtOₓ) may also be preferred. At least one of the electrodes here must be transparent or partially transparent in order to facilitate the coupling-out of light. Preferred transparent or partially transparent anode materials are conductive mixed metal oxides. Particular preference is given to indium tin oxide (ITO) or indium zinc oxide (IZO). Preference is furthermore given to conductive, doped organic materials, in particular conductive doped polymers.

The device is correspondingly (depending on the application) structured, provided with contacts and finally hermetically sealed, since the lifetime of devices of this type is drastically shortened in the presence of water and/or air. Preference is furthermore given to an organic electroluminescent device, characterised in that one or more layers are applied by means of a sublimation process, in which the materials are vapour-deposited in vacuum sublimation units at an initial pressure of less than 10⁻⁵ mbar, preferably less than 10⁻⁶ mbar. However, it is also possible for the pressure to be even lower, for example less than 10⁻⁷ mbar.

Preference is likewise given to an organic electroluminescent device, characterised in that one or more layers are applied by means of the OVPD (organic vapour-phase deposition) process or with the aid of carrier-gas sublimation, in which the materials are applied at a pressure between 10⁻⁵ mbar and 1 bar. A special case of this process is the OVJP (organic vapour jet printing) process, in which the materials are applied directly through a nozzle and thus structured (for example M. S. Arnold et al., Appl. Phys. Lett. 2008, 92, 053301).

Preference is furthermore given to an organic electroluminescent device, characterised in that one or more layers are produced from solution, such as, for example, by spin coating, or by means of any desired printing process, such as, for example, screen printing, flexographic printing, offset printing, LITI (light induced thermal imaging, thermal transfer printing), ink-jet printing or nozzle printing. Soluble compounds are necessary for this purpose, which are obtained, for example, by suitable substitution. These processes are also suitable, in particular, for oligomers, dendrimers and polymers.

These processes are generally known to the person skilled in the art and can be applied by him without inventive step to organic electroluminescent devices comprising the compounds according to the invention.

The present invention therefore furthermore relates to a process for the production of an organic electroluminescent device according to the invention, characterised in that at least one layer is applied by means of a sublimation process and/or in that at least one layer is applied by means of an OVPD (organic vapour phase deposition) process or with the aid of carrier-gas sublimation and/or in that at least one layer is applied from solution, by spin coating or by means of a printing process.

The organic electroluminescent devices according to the invention are distinguished over the prior art by one or more of the following surprising advantages:
1. The organic electroluminescent devices according to the invention have very good efficiency which is improved compared with devices in accordance with the prior art which likewise exhibit TADF.
2. The organic electroluminescent devices according to the invention have a very low voltage.
3. The organic electroluminescent devices according to the invention have a very good lifetime which is improved compared with devices in accordance with the prior art which likewise exhibit TADF.
4. Compared with organic electroluminescent devices in accordance with the prior art which comprise iridium or platinum complexes as emitting compounds, the electroluminescent devices according to the invention have an improved lifetime at elevated temperature.

These above-mentioned advantages are not accompanied by an impairment in the other electronic properties.

The invention is explained in greater detail by the following examples without wishing to restrict it thereby. The person skilled in the art will be able to carry out the invention throughout the range disclosed on the basis of the descriptions and produce further organic electroluminescent devices according to the invention without inventive step.

### EXAMPLES

### Determination of HOMO, LUMO, Singlet and Triplet Level

The HOMO and LUMO energy levels and the energy of the lowest triplet state T₁ or of the lowest excited singlet state S₁ of the materials are determined via quantum-chemical calculations. To this end, the “Gaussian09W” software package (Gaussian Inc.) is used. In order to calculate organic substances without metals (denoted by “org.” method in Table 4), firstly a geometry optimisation is carried out using the “Ground State/Semi-empirical/Default Spin/AM1/Charge 0/Spin Singlet” method. This is followed by an energy calculation on the basis of the optimised geometry. The “TD-SFC/DFT/Default Spin/B3PW91” method with the “6-31G(d)” base set is used here (Charge 0, Spin Singlet). For metal-containing compounds (denoted by “organom.” method in Table 4), the geometry is optimised via the “Ground State/HartreeFock/Default Spin/LanL2 MB/Charge 0/Spin Singlet” method. The energy calculation is carried out analogously to the organic substances as described above, with the difference that the “LanL2DZ” base set is used for the metal atom and the “6-31 G(d)” base set is used for the ligands. The energy calculation gives the HOMO energy level HEh or LUMO energy level LEh in hartree units. The HOMO and LUMO energy levels calibrated with reference to cyclic voltammetry measurements are determined therefrom in electron volts as follows:

HOMO(eV)=((HEh*27.212)−0.9899)/1.1206

LUMO(eV)=((LEh*27.212)−2.0041)/1.385

These values are to be regarded in the sense of this application as HOMO and LUMO energy levels of the materials.

The lowest triplet state T₁ is defined as the energy of the triplet state having the lowest energy which arises from the quantum-chemical calculation described.

The lowest excited singlet state S₁ is defined as the energy of the excited singlet state having the lowest energy which arises from the quantum-chemical calculation described.

Table 4 below shows the HOMO and LUMO energy levels and S₁ and T₁ of the various materials.

### Determination of the PL Quantum Efficiency (PLQE)

A 50 nm thick film of the emission layers used in the various OLEDs is applied to a suitable transparent substrate, preferably quartz, i.e. the layer comprises the same materials in the same concentration as the OLED. The same production conditions are used here as in the production of the emission layer for the OLEDs. An absorption spectrum of this film is measured in the wavelength range from 350-500 nm. To this end, the reflection spectrum R(λ) and the transmission spectrum T(λ) of the sample are determined at an angle of incidence of 6° (i.e. virtually perpendicular incidence). The absorption spectrum in the sense of this application is defined as A(λ)=1−R(λ)−T(λ).

If A(λ)≦0.3 in the range 350-500 nm, the wavelength belonging to the maximum of the absorption spectrum in the range 350-500 nm is defined as λ_{exc}. If A(λ)>0.3 for any wavelength, the greatest wavelength at which A(λ) changes from a value less than 0.3 to a value greater than 0.3 or from a value greater than 0.3 to a value less than 0.3 is defined as λ_{exc}.

The PLQE is determined using a Hamamatsu C9920-02 measurement system. The principle is based on excitation of the sample by light of defined wavelength and measurement of the absorbed and emitted radiation. The sample is located in an Ulbricht sphere (“integrating sphere”) during measurement. The spectrum of the excitation light is approximately Gaussian with a full width at half maximum of <10 nm and a peak wavelength λ_{exc} as defined above. The PLQE is determined by the evaluation method which is usual for the said measurement system. It is vital to ensure that the sample does not come into contact with oxygen at any time, since the PLQE of materials having a small energetic separation between S₁ and T₁ is reduced very considerably by oxygen (H. Uoyama et al., Nature 2012, Vol. 492, 234).

Table 2 shows the PLQE for the emission layers of the OLEDs as defined above together with the excitation wavelength used.

### Determination of the Decay Time

The decay time is determined using a sample produced as described above under “Determination of the PL quantum efficiency (PLQE)”. The sample is excited at a temperature of 295 K by a laser pulse (wavelength 266 nm, pulse duration 1.5 ns, pulse energy 200 μJ, ray diameter 4 mm). The sample is located in a vacuum (<10⁻⁵ mbar) here. After the excitation (defined as t=0), the change in the intensity of the emitted photoluminescence over time is measured. The photoluminescence exhibits a steep drop at the beginning, which is attributable to the prompt fluorescence of the TADF compound. As time continues, a slower drop is observed, the delayed fluorescence (see, for example, H. Uoyama et al., Nature, vol. 492, no. 7428, pp. 234-238, 2012 and K. Masui et al., Organic Electronics, vol. 14, no. 11, pp. 2721-2726, 2013). The decay time tₐ in the sense of this application is the decay time of the delayed fluorescence and is determined as follows: a time t_{d} is selected at which the prompt fluorescence has decayed significantly below the intensity of the delayed fluorescence (<1%), so that the following determination of the decay time is not influenced thereby. This choice can be made by a person skilled in the art. For the measurement data from time t_{d}, the decay time tₐ=tₑ−t_{d} is determined. tₑ here is the time after t=t_{d} at which the intensity has for the first time dropped to 1/e of its value at t=t_{d}.

Table 2 shows the values of tₐ and t_{d} which are determined for the emission layers of the OLEDs according to the invention.

### Examples

### Production of the OLEDs

The data of various OLEDs are presented in Examples V1 to E16 below (see Tables 1 and 2).

Glass plates coated with structured ITO (indium tin oxide) in a thickness of 50 nm form the substrates for the OLEDs. The substrates are wet-cleaned (dishwasher, Merck Extran detergent), subsequently dried by heating at 250° C. for 15 min and treated with an oxygen plasma for 130 s before the coating. These plasma-treated glass plates form the substrates to which the OLEDs are applied. The substrates remain in vacuo before the coating. The coating begins at the latest 10 min after the plasma treatment.

The OLEDs have in principle the following layer structure: substrate/optional hole-injection layer (HIL)/optional hole-transport layer (HTL)/optional interlayer (IL)/electron-blocking layer (EBL)/emission layer (EML)/optional hole-blocking layer (HBL)/electron-transport layer (ETL)/optional electron-injection layer (EIL) and finally a cathode. The cathode is formed by an aluminium layer with a thickness of 100 nm. The precise structure of the OLEDs is shown in Table 2. The materials required for the production of the OLEDs are shown in Table 3.

All materials are applied by thermal vapour deposition in a vacuum chamber. The emission layer here always consists of a matrix material (host material) and the emitting TADF compound, i.e. the material which exhibits a small energetic difference between S₁ and T₁. This is admixed with the matrix material in a certain proportion by volume by co-evaporation. An expression such as IC1:D1 (95%:5%) here means that material IC1 is present in the layer in a proportion by volume of 95% and D1 is present in the layer in a proportion of 5%. Analogously, the electron-transport layer may also consist of a mixture of two materials.

The OLEDs are characterised by standard methods. For this purpose, the electroluminescence spectra, the current efficiency (measured in cd/A), the power efficiency (measured in lm/W) and the external quantum efficiency (EQE, measured in percent) as a function of the luminous density, calculated from current/voltage/luminous density characteristic lines (IUL characteristic lines) assuming Lambert emission characteristics, and the lifetime are determined. The electroluminescence spectra are determined at a luminous density of 1000 cd/m², and the CIE 1931 x and y colour coordinates are calculated therefrom. The term U1000 in Table 2 denotes the voltage required for a luminous density of 1000 cd/m². CE1000 and PE1000 denote the current and power efficiency respectively which are achieved at 1000 cd/m². Finally, EQE1000 denotes the external quantum efficiency at an operating luminous density of 1000 cd/m².

The roll-off is defined as EQE at 5000 cd/m² divided by EQE at 500 cd/m², i.e. a high value corresponds to a small drop in the efficiency at high luminous densities, which is advantageous.

The lifetime LT is defined as the time after which the luminous density drops from the initial luminous density to a certain proportion L1 on operation at constant current. An expression of j0=10 mA/cm², L1=80% in Table 2 means that the luminous density drops to 80% of its initial value after time LT on operation at 10 mA/cm².

The emitting dopant employed in the emission layer is compound D1, which has an energetic separation between S₁ and T₁ of 0.09 eV, or compound D2, for which the difference between S₁ and T₁ is 0.06 eV

The data of the various OLEDs are summarised in Table 3. Examples V1-V6 are comparative examples in accordance with the prior art, Examples E1-E7 show data of OLEDs according to the invention.

As can be seen from the table, significant improvements with respect to voltage and efficiency are obtained with electron-transport layers according to the invention, which results in a significant improvement in the power efficiency. Furthermore, better lifetimes and in many cases additionally an improvement in the roll-off behaviour are obtained. These advantages apply if only one layer is arranged between EML and cathode (Examples V1, V2 and E7-E10), but also if a plurality of layers are arranged between EML and cathode and all layers have such a low LUMO (Examples V3-V11, E1-E6, E11-E16).

TABLE 1
Structure of the OLEDs

| | HIL | HTL | IL | EBL | EML | HBL | ETL | EIL |
|---|---|---|---|---|---|---|---|---|
| | Thick- | Thick- | Thick- | Thick- | Thick- | Thick- | Thick- | Thick- |
| Ex. | ness | ness | ness | ness | ness | ness | ness | ness |
| V1 | — | — | — | NPB | CBP:D1 | — | BCP | LiQ |
| | | | | 90 nm | (95%:5%) | | 50 nm | 3 nm |
| | | | | | 15 nm | | | |
| V2 | NPB:F4T | — | — | NPB | CBP:D1 | — | BCP | LiQ |
| | (95%:5%) | | | 80 nm | (95%:5%) | | 50 nm | 3 nm |
| | 10 nm | | | | 15 nm | | | |
| V3 | HAT | SpA1 | HAT | SpMA1 | BCP:D1 | BCP | ST2 | LiQ |
| | 5 nm | 70 nm | 5 nm | 20 nm | (95%:5%) | 10 nm | 40 nm | 3 nm |
| | | | | | 15 nm | | | |
| V4 | HAT | SpA1 | HAT | SpMA1 | BCP:D1 | CBP | ST2 | LiQ |
| | 5 nm | 70 nm | 5 nm | 20 nm | (95%:5%) | 10 nm | 40 nm | 3 nm |
| | | | | | 15 nm | | | |
| V5 | SpMA1:F4T | — | | SpMA1 | IC1:D1 | BCP | ST2 | LiQ |
| | (95%:5%) | | | 80 nm | (95%:5%) | 10 nm | 40 nm | 3 nm |
| | 10 nm | | | | 15 nm | | | |
| V6 | SpMA1:F4T | — | | SpMA1 | IC1:D1 | CBP | ST2 | LiQ |
| | (95%:5%) | | | 80 nm | (95%:5%) | 10 nm | 40 nm | 3 nm |
| | 10 nm | | | | 15 nm | | | |
| V7 | HAT | SpA1 | HAT | SpMA1 | IC1:D1 | BCP | ST2 | LiQ |
| | 5 nm | 70 nm | 5 nm | 20 nm | (95%:5%) | 10 nm | 40 nm | 3 nm |
| | | | | | 15 nm | | | |
| V8 | — | — | — | SpMA1 | CBP:D2 | IC1 | TPBI | LiQ |
| | | | | 90 nm | (95%:5%) | 10 nm | 45 nm | 3 nm |
| | | | | | 15 nm | | | |
| V9 | — | — | — | SpMA1 | IC1:D2 | IC1 | TPBI | LiQ |
| | | | | 90 nm | (95%:5%) | 10 nm | 45 nm | 3 nm |
| | | | | | 15 nm | | | |
| V10 | — | — | — | SpMA1 | IC6:D2 | IC1 | TPBI | LiQ |
| | | | | 90 nm | (95%:5%) | 10 nm | 45 nm | 3 nm |
| | | | | | 15 nm | | | |
| V11 | — | — | — | SpMA1 | L1:D2 | IC1 | TPBI | LiQ |
| | | | | 90 nm | (95%:5%) | 10 nm | 45 nm | 3 nm |
| | | | | | 15 nm | | | |
| E1 | HAT | SpA1 | HAT | SpMA1 | IC1:D1 | IC1 | ST2:LiQ | — |
| | 5 nm | 70 nm | 5 nm | 20 nm | (95%:5%) | 10 nm | (50%:50%) | |
| | | | | | 15 nm | | 40 nm | |
| E2 | HAT | SpA1 | HAT | SpMA1 | IC5:D1 | IC1 | ST2:LiQ | — |
| | 5 nm | 70 nm | 5 nm | 20 nm | (95%:5%) | 10 nm | (50%:50%) | |
| | | | | | 15 nm | | 40 nm | |
| E3 | HAT | SpA1 | HAT | SpMA1 | IC1:D1 | IC1 | ST2 | LiQ |
| | 5 nm | 70 nm | 5 nm | 20 nm | (95%:5%) | 10 nm | 40 nm | 3 nm |
| | | | | | 15 nm | | | |
| E4 | HAT | SpA1 | HAT | SpMA1 | IC1:D1 | IC5 | ST2 | LiQ |
| | 5 nm | 70 nm | 5 nm | 20 nm | (95%:5%) | 10 nm | 40 nm | 3 nm |
| | | | | | 15 nm | | | |
| E5 | SpMA1:F4T | SpMA1 | — | IC2 | IC1:D1 | IC1 | ST2:LiQ | — |
| | (95%:5%) | 80 nm | | 10 nm | (95%:5%) | 10 nm | (50%:50%) | |
| | 10 nm | | | | 15 nm | | 40 nm | |
| E6 | HAT | SpA1 | HAT | SpMA1 | IC3:D1 | IC1 | ST2:LiQ | — |
| | 5 nm | 70 nm | 5 nm | 20 nm | (95%:5%) | 10 nm | (50%:50%) | |
| | | | | | 15 nm | | 40 nm | |
| E7 | — | — | — | NPB | CBP:D1 | — | ST2 | LiQ |
| | | | | 90 nm | (95%:5%) | | 50 nm | 3 nm |
| | | | | | 15 nm | | | |
| E8 | NPB:F4T | — | — | NPB | CBP:D1 | — | ST2 | LiQ |
| | (95%:5%) | | | 90 nm | (95%:5%) | | 50 nm | 3 nm |
| | 10 nm | | | | 15 nm | | | |
| E9 | — | — | — | NPB | CBP:D1 | — | IC1 | LiQ |
| | | | | 90 nm | (95%:5%) | | 50 nm | 3 nm |
| | | | | | 15 nm | | | |
| E10 | NPB:F4T | — | — | NPB | CBP:D1 | — | IC1 | LiQ |
| | (95%:5%) | | | 80 nm | (95%:5%) | | 50 nm | 3 nm |
| | 10 nm | | | | 15 nm | | | |
| E11 | HAT | SpA1 | HAT | SpMA1 | BCP:D1 | IC1 | ST2 | LiQ |
| | 5 nm | 70 nm | 5 nm | 20 nm | (95%:5%) | 10 nm | 40 nm | 3 nm |
| | | | | | 15 nm | | | |
| E12 | SpMA1:F4T | — | | SpMA1 | IC1:D1 | IC1 | ST2 | LiQ |
| | (95%:5%) | | | 80 nm | (95%:5%) | 10 nm | 40 nm | 3 nm |
| | 10 nm | | | | 15 nm | | | |
| E13 | SpMA1:F4T | — | | SpMA1 | IC1:D1 | IC5 | ST2 | LiQ |
| | (95%:5%) | | | 80 nm | (95%:5%) | 10 nm | 40 nm | 3 nm |
| | 10 nm | | | | 15 nm | | | |
| E14 | HAT | SpA1 | HAT | SpMA1 | CBP:D1 | IC1 | ST2:LiQ | — |
| | 5 nm | 70 nm | 5 nm | 20 nm | (95%:5%) | 10 nm | (50%:50%) | |
| | | | | | 15 nm | | 40 nm | |
| E15 | HAT | SpA1 | HAT | SpMA1 | CBP:D1 | IC1 | ST2 | LiQ |
| | 5 nm | 70 nm | 5 nm | 20 nm | (95%:5%) | 10 nm | 40 nm | 3 nm |
| | | | | | 30 nm | | | |
| E16 | SpMA1:F4T | SpMA1 | — | IC2 | CBP:D1 | IC1 | ST2:LiQ | — |
| | (95%:5%) | 80 nm | | 10 nm | (95%:5%) | 10 nm | (50%:50%) | |
| | 10 nm | | | | 15 nm | | 40 nm | |
| E17 | — | — | — | SpMA1 | CBP:D2 | IC1 | ST2 | LiQ |
| | | | | 90 nm | (95%:5%) | 10 nm | 45 nm | 3 nm |
| | | | | | 15 nm | | | |
| E18 | — | — | — | SpMA1 | IC1:D2 | IC1 | ST2 | LiQ |
| | | | | 90 nm | (95%:5%) | 10 nm | 45 nm | 3 nm |
| | | | | | 15 nm | | | |
| E19 | — | — | — | SpMA1 | IC6:D2 | IC1 | ST2 | LiQ |
| | | | | 90 nm | (95%:5%) | 10 nm | 45 nm | 3 nm |
| | | | | | 15 nm | | | |
| E20 | — | — | — | SpMA1 | L1:D2 | IC1 | ST2 | LiQ |
| | | | | 90 nm | (95%:5%) | 10 nm | 45 nm | 3 nm |
| | | | | | 15 nm | | | |

TABLE 2
Data of the OLEDs

| | U1000 | CE1000 | PE1000 | EQE | CIE x/y at | Roll- | | L1 | LT | PLQE | λ_{exc} | t_{d} | tₐ |
|---|---|---|---|---|---|---|---|---|---|---|---|---|---|
| Ex. | (V) | (cd/A) | (lm/W) | 1000 | 1000 cd/m² | off | L0; j0 | % | (h) | % | nm | μs | μs |
| V1 | 6.0 | 30 | 16 | 9.3% | 0.28/0.59 | 0.68 | 10 mA/cm² | 80 | 2 | 100 | 350 | 7 | 4.5 |
| V2 | 5.6 | 31 | 18 | 9.7% | 0.27/0.59 | 0.70 | 10 mA/cm² | 80 | 3 | 100 | 350 | 7 | 4.5 |
| V3 | 7.8 | 4.2 | 1.7 | 1.4% | 0.27/0.55 | 0.63 | 10 mA/cm² | 80 | 1 | 59 | 350 | 6 | 5.9 |
| V4 | 10.8 | 1.5 | 0.4 | 0.5% | 0.28/0.54 | 0.73 | 10 mA/cm² | 80 | 1 | 59 | 350 | 6 | 5.9 |
| V5 | 4.1 | 16.6 | 12.8 | 5.2% | 0.26/0.58 | 0.60 | 10 mA/cm² | 80 | 8 | 92 | 350 | 7 | 5.4 |
| V8 | 4.2 | 11.0 | 8.2 | 3.6% | 0.25/0.55 | 0.46 | 10 mA/cm² | 80 | 4 | 92 | 350 | 7 | 5.4 |
| V7 | 4.1 | 17.2 | 13.2 | 5.4% | 0.26/0.58 | 0.69 | 10 mA/cm² | 80 | 12 | 92 | 350 | 7 | 5.4 |
| V8 | 9.2 | 12.5 | 4.3 | 4.7% | 0.49/0.47 | 0.72 | 10 mA/cm² | 80 | 5 | 43 | 350 | 6 | 5.1 |
| V9 | 7.0 | 15.0 | 6.7 | 5.6% | 0.50/0.48 | 0.84 | 10 mA/cm² | 80 | 15 | 41 | 350 | 7 | 4.6 |
| V10 | 9.2 | 10.5 | 3.6 | 4.3% | 0.51/0.46 | 0.81 | 10 mA/cm² | 80 | 26 | 37 | 350 | 6 | 5.3 |
| V11 | 7.1 | 15.5 | 6.9 | 6.1% | 0.51/0.47 | 0.79 | 10 mA/cm² | 80 | 31 | 46 | 368 | 7 | 4.3 |
| E1 | 3.6 | 65 | 56 | 20.8% | 0.25/0.58 | 0.72 | 10 mA/cm² | 80 | 44 | 92 | 350 | 7 | 5.4 |
| E2 | 3.5 | 43 | 39 | 13.3% | 0.32/0.58 | 0.66 | 10 mA/cm² | 80 | 63 | 57 | 350 | 4 | 4.0 |
| E3 | 3.3 | 67 | 64 | 21.0% | 0.26/0.58 | 0.79 | 10 mA/cm² | 80 | 28 | 92 | 350 | 7 | 5.4 |
| E4 | 3.2 | 58 | 56 | 17.6% | 0.27/0.58 | 0.75 | 10 mA/cm² | 80 | 22 | 92 | 350 | 7 | 5.4 |
| E5 | 3.6 | 68 | 59 | 21.5% | 0.26/0.58 | 0.73 | 10 mA/cm² | 80 | 52 | 92 | 350 | 7 | 5.4 |
| E6 | 3.2 | 52 | 52 | 15.7% | 0.31/0.60 | 0.71 | 10 mA/cm² | 80 | 88 | 77 | 350 | 7 | 7.0 |
| E7 | 4.3 | 36 | 27 | 11.3% | 0.28/0.59 | 0.65 | 10 mA/cm² | 80 | 59 | 100 | 350 | 7 | 4.5 |
| E8 | 3.7 | 55 | 38 | 13.7% | 0.27/0.59 | 0.66 | 10 mA/cm² | 80 | 84 | 100 | 350 | 7 | 4.5 |
| E9 | 4.7 | 34 | 23 | 10.6% | 0.27/0.58 | 0.58 | 10 mA/cm² | 80 | 8 | 100 | 350 | 7 | 4.5 |
| E10 | 4.3 | 37 | 27 | 11.8% | 0.26/0.58 | 0.61 | 10 mA/cm² | 80 | 9 | 100 | 350 | 7 | 4.5 |
| E11 | 6.7 | 4.9 | 2.3 | 1.6% | 0.26/0.56 | 0.65 | 10 mA/cm² | 80 | 1 | 59 | 350 | 6 | 5.9 |
| E12 | 3.2 | 64 | 62 | 20.1% | 0.26/0.58 | 0.74 | 10 mA/cm² | 80 | 30 | 92 | 350 | 7 | 5.4 |
| E13 | 3.2 | 56 | 56 | 17.6% | 0.27/0.58 | 0.70 | 10 mA/cm² | 80 | 24 | 92 | 350 | 7 | 5.4 |
| E14 | 4.2 | 44 | 33 | 14.1% | 0.25/0.58 | 0.60 | 10 mA/cm² | 80 | 23 | 100 | 350 | 7 | 4.5 |
| E15 | 5.1 | 44 | 27 | 13.6% | 0.27/0.58 | 0.73 | 10 mA/cm² | 80 | 21 | 100 | 350 | 7 | 4.5 |
| E16 | 4.1 | 49 | 38 | 15.4% | 0.27/0.58 | 0.63 | 10 mA/cm² | 80 | 34 | 100 | 350 | 7 | 4.5 |
| E17 | 8.1 | 20 | 7.6 | 6.7% | 0.49/0.49 | 0.64 | 10 mA/cm² | 80 | 14 | 43 | 350 | 6 | 5.1 |
| E18 | 5.3 | 27 | 16 | 9.6% | 0.51/0.48 | 0.80 | 10 mA/cm² | 80 | 69 | 41 | 350 | 7 | 4.6 |
| E19 | 8.1 | 14.4 | 5.6 | 5.8% | 0.52/0.46 | 0.77 | 10 mA/cm² | 80 | 68 | 37 | 350 | 6 | 5.3 |
| E20 | 5.8 | 20 | 10.8 | 7.8% | 0.52/0.47 | 0.76 | 10 mA/cm² | 80 | 165 | 46 | 368 | 7 | 4.3 |

TABLE 3
Structural formulae of the materials for the OLEDs

| | |
|---|---|
| 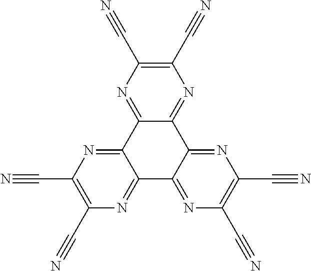 HAT | 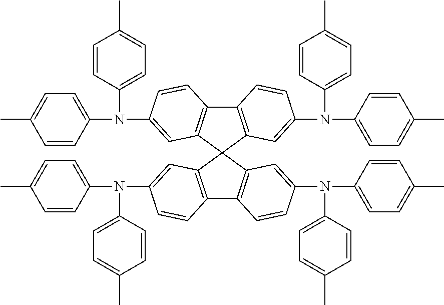 |
| | SpA1 |
| 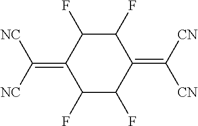 F4T | 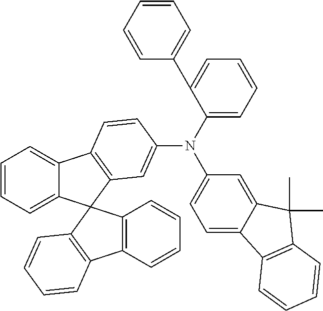 [SMILES: CC1(C)c2ccccc2-c2ccc(N(c3ccc4c(c3)C3(c5ccccc5-c5ccccc53)c3ccccc3-4)c3ccccc3-c3ccccc3)cc21] |
| | SpMA1 |
| 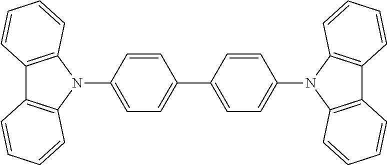 CBP | 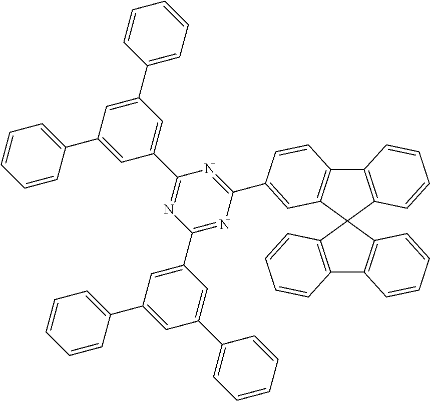 [SMILES: c1ccc(-c2cc(-c3ccccc3)cc(-c3nc(-c4cc(-c5ccccc5)cc(-c5ccccc5)c4)nc(-c4ccc5c(c4)C4(c6ccccc6-c6ccccc64)c4ccccc4-5)n3)c2)cc1] |
| | ST2 |
| 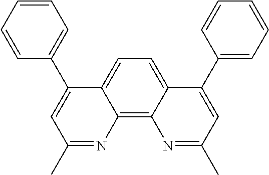 | 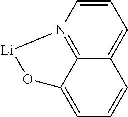 LiQ |
| BCP | |
| 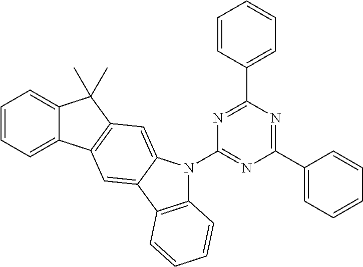 | 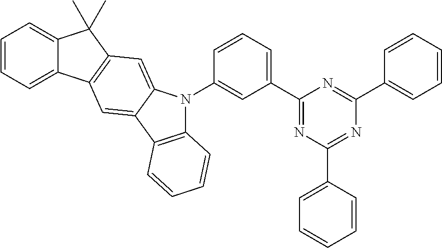 [SMILES: CC1(C)c2ccccc2-c2cc3c4ccccc4n(-c4cccc(-c5nc(-c6ccccc6)nc(-c6ccccc6)n5)c4)c3cc21] |
| | IC5 |
| IC1 | |
| 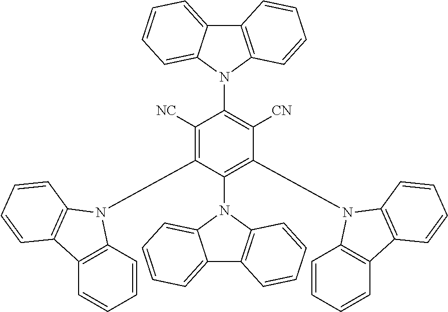 | 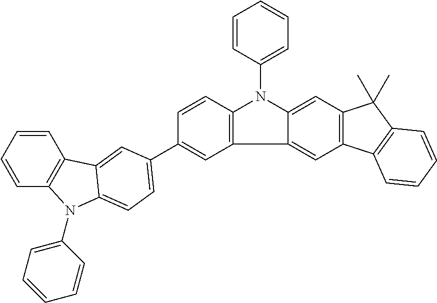 [SMILES: CC1(C)c2ccccc2-c2cc3c4cc(-c5ccc6c(c5)c5ccccc5n6-c5ccccc5)ccc4n(-c4ccccc4)c3cc21] |
| D1 | IC2 |
| 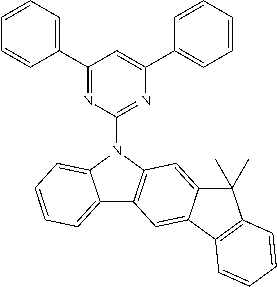 IC3 | 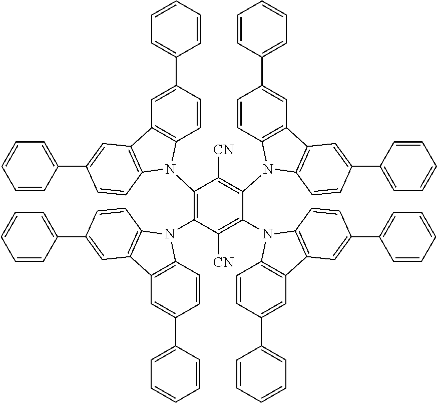 [SMILES: N#Cc1c(-n2c3ccc(-c4ccccc4)cc3c3cc(-c4ccccc4)ccc32)c(-n2c3ccc(-c4ccccc4)cc3c3cc(-c4ccccc4)ccc32)c(C#N)c(-n2c3ccc(-c4ccccc4)cc3c3cc(-c4ccccc4)ccc32)c1-n1c2ccc(-c3ccccc3)cc2c2cc(-c3ccccc3)ccc21] |
| | D2 |
| 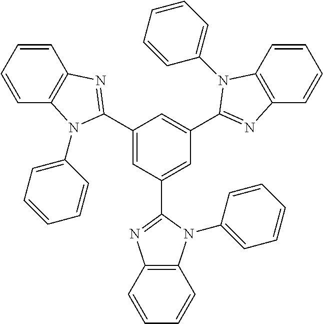 | 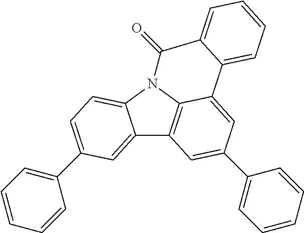 [SMILES: O=c1c2ccccc2c2cc(-c3ccccc3)cc3c4cc(-c5ccccc5)ccc4n1c23] L1 |
| TPB1 | |
| 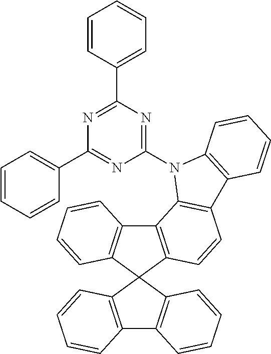 | |
| IC6 | |

TABLE 4
HOMO, LUMO, T₁, S₁ of
the relevant materials

| | | HOMO | LUMO | S₁ | T₁ |
|---|---|---|---|---|---|
| Material | Method | (eV) | (eV) | (eV) | (eV) |
| D1 | org. | −6.11 | −3.40 | 2.50 | 2.41 |
| D2 | org. | −5.92 | −3.61 | 2.09 | 2.03 |
| CBP | org. | −5.67 | −2.38 | 3.59 | 3.11 |
| BCP | org. | −6.15 | −2.44 | 3.61 | 2.70 |
| IC1 | org. | −5.79 | −2.83 | 3.09 | 2.69 |
| IC5 | org. | −5.56 | 2.87 | 2.87 | 2.72 |
| IC3 | org. | −5.62 | −2.75 | 3.02 | 2.75 |
| SpA1 | org. | −4.87 | −2.14 | 2.94 | 2.34 |
| SpMA1 | org. | −5.25 | −2.18 | 3.34 | 2.58 |
| IC2 | org. | −5.40 | −2.11 | 3.24 | 2.80 |
| HAT | org. | −8.86 | −4.93 | | |
| F4T | org. | −7.91 | −5.21 | | |
| ST2 | org. | −6.03 | −2.82 | 3.32 | 2.68 |
| LiQ | organom. | −5.17 | −2.39 | 2.85 | 2.13 |
| TPBI | org. | −6.26 | −2.48 | 3.47 | 3.04 |
| L1 | org. | −6.09 | −2.80 | 2.70 | 3.46 |
| IC6 | org. | −5.87 | −2.85 | 2.72 | 3.14 |

1.-19. (canceled)

20. An organic electroluminescent device comprising cathode, anode and emitting layer which comprises at least one luminescent organic compound which has a separation between the lowest triplet state T₁ and the first excited singlet state S₁ of ≦0.15 eV (TADF compound), wherein the electroluminescent device comprises one or more electron-transport layers, each of which comprises at least one compound having an LUMO≦−2.55 eV, on the cathode side of the emitting layer.

21. The organic electroluminescent device according to claim 20, wherein all electron-transport layers which are present between the cathode or, if present, the electron-injection layer and the emitting layer comprise at least one compound having an LUMO≦−2.55 eV.

22. The organic electroluminescent device according to claim 20, wherein the separation between S₁ and T₁ of the TADF compound is ≦0.10 eV.

23. The organic electroluminescent device according to claim 20, wherein the TADF compound is an aromatic compound which has both donor and also acceptor substituents.

24. The organic electroluminescent device according to claim 20, wherein the TADF compound is present in a matrix, and the following applies to the LUMO of the TADF compound LUMO(TADF) and the HOMO of the matrix HOMO(matrix):
LUMO(TADF)−HOMO(matrix)>S₁(TADF)−0.4 eV,
where S₁(TADF) is the first excited singlet state S₁ of the TADF compound.

25. The organic electroluminescent device according to claim 20, wherein the electron-transport material in the electron-transport layer has an LUMO≦−2.60 eV.

26. The organic electroluminescent device according to claim 20, wherein one, two or three electron-transport layers are present.

27. The organic electroluminescent device according to claim 20, wherein the layer thickness of the electron-transport layers is in total between 10 and 100 nm.

28. The organic electroluminescent device according to claim 20, wherein the lowest triplet energy of the electron-transport layer directly adjacent to the emitting layer is a maximum of 0.1 eV lower than the triplet energy of the TADF compound.

29. The organic electroluminescent device according to claim 20, wherein the following applies to the electron-transport material of the electron-transport layer directly adjacent to the emitting layer:
HOMO(EML)−HOMO(ETL)>0.2 eV,
where HOMO(ETL) is the HOMO of the material of the electron-transport layer or, in the case of a plurality of materials in the layer, the highest HOMO of these materials, and
HOMO(EML) is the HOMO of the material of the emitting layer or, in the case of a plurality of materials in the layer, the highest HOMO of these materials.

30. The organic electroluminescent device according to claim 20, wherein at least one electron-injection layer is present between the electron-transport layer comprising the electron-transport material having an LUMO≦−2.55 eV and the cathode.

31. The organic electroluminescent device according to claim 20, wherein at least one electron-injection layer, which is selected from lithium compounds and/or alkali-metal or alkaline-earth metal fluorides, oxides or carbonates, is present between the electron-transport layer comprising the electron-transport material having an LUMO≦−2.55 eV and the cathode.

32. The organic electroluminescent device according to claim 20, wherein the electron-transport layer which is adjacent to the cathode or, if present, to the electron-injection layer comprises a mixture of an electron-transport material having an LUMO≦−2.55 eV and a lithium compound.

33. The organic electroluminescent device according to claim 20, wherein the electron-transport material is selected from the substance classes consisting of the triazines, the pyrimidines, the lactams, the metal complexes, the aromatic ketones, the aromatic phosphine oxides, the azaphospholes, the azaboroles, which are substituted by at least one electron-conducting substituent, the benzimidazoles and the quinoxalines.

34. The organic electroluminescent device according to claim 20, wherein the electron-transport material is selected from the compounds of the following formulae (1) and (2), 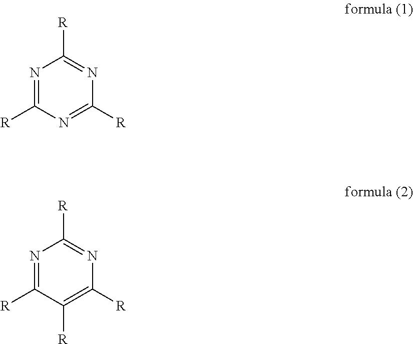
wherein the following applies to the symbols used:
R is selected on each occurrence, identically or differently, from the group consisting of H, D, F, Cl, Br, I, CN, NO₂, N(Ar)₂, N(R¹)₂, C(═O)Ar, C(═O)R¹, P(═O)(Ar)₂, a straight-chain alkyl, alkoxy or thioalkyl group having 1 to 40 C atoms or a branched or cyclic alkyl, alkoxy or thioalkyl group having 3 to 40 C atoms or an alkenyl or alkynyl group having 2 to 40 C atoms, each of which may be substituted by one or more radicals R¹, where one or more non-adjacent CH₂ groups may be replaced by R¹C═CR¹, C≡C, Si(R¹)₂, C═O, C═S, C═NR¹, P(═O)(R¹), SO, SO₂, NR¹, O, S or CONR¹ and where one or more H atoms may be replaced by D, F, Cl, Br, I, CN or NO₂, an aromatic or heteroaromatic ring system having 5 to 80, aromatic ring atoms, which may in each case be substituted by one or more radicals R¹, an aryloxy or heteroaryloxy group having 5 to 60 aromatic ring atoms, which may be substituted by one or more radicals R¹, or an aralkyl or heteroaralkyl group having 5 to 60 aromatic ring atoms, which may be substituted by one or more radicals R¹, where two or more adjacent substituents R may optionally form a monocyclic or polycyclic, aliphatic, aromatic or heteroaromatic ring system, which may be substituted by one or more radicals R¹;
R¹ is selected on each occurrence, identically or differently, from the group consisting of H, D, F, Cl, Br, I, CN, NO₂, N(Ar)₂, N(R²)₂, C(═O)Ar, C(═O)R², P(═O)(Ar)₂, a straight-chain alkyl, alkoxy or thioalkyl group having 1 to 40 C atoms or a branched or cyclic alkyl, alkoxy or thioalkyl group having 3 to 40 C atoms or an alkenyl or alkynyl group having 2 to 40 C atoms, each of which may be substituted by one or more radicals R², where one or more non-adjacent CH₂ groups may be replaced by R²C═CR², C≡C, Si(R²)₂, C═O, C═S, C═NR², P(═O)(R²), SO, SO₂, NR², O, S or CONR² and where one or more H atoms may be replaced by D, F, Cl, Br, I, CN or NO₂, an aromatic or heteroaromatic ring system having 5 to 60 aromatic ring atoms, which may in each case be substituted by one or more radicals R², an aryloxy or heteroaryloxy group having 5 to 60 aromatic ring atoms, which may be substituted by one or more radicals R², or an aralkyl or heteroaralkyl group having 5 to 60 aromatic ring atoms, where two or more adjacent substituents R¹ may optionally form a monocyclic or polycyclic, aliphatic, aromatic or heteroaromatic ring system, which may be substituted by one or more radicals R²;
Ar is on each occurrence, identically or differently, an aromatic or heteroaromatic ring system having 5-30 aromatic ring atoms, which may be substituted by one or more non-aromatic radicals R²; two radicals Ar which are bonded to the same N atom or P atom here may also be bridged to one another by a single bond or a bridge selected from N(R²), C(R²)₂, O or S; and
R² is selected from the group consisting of H, D, F, CN, an aliphatic hydrocarbon radical having 1 to 20 C atoms, an aromatic or heteroaromatic ring system having 5 to 30 aromatic ring atoms, in which one or more H atoms may be replaced by D, F, Cl, Br, I or CN, where two or more adjacent substituents R² may form a mono- or polycyclic, aliphatic, aromatic or heteroaromatic ring system with one another.

35. The organic electroluminescent device according to claim 34, wherein at least one radical R is selected, identically or differently on each occurrence, from the group consisting of benzene, ortho-, meta- or para-biphenyl, ortho-, meta-, para- or branched terphenyl, ortho-, meta-, para- or branched quaterphenyl, 1-, 2-, 3- or 4-fluorenyl, 1-, 2-, 3- or 4-spirobifluorenyl, 1- or 2-naphthyl, pyrrole, furan, thiophene, indole, benzofuran, benzothiophene, 1-, 2- or 3-carbazole, 1-, 2- or 3-dibenzofuran, 1-, 2- or 3-dibenzothiophene, indenocarbazole, indolocarbazole, 2-, 3- or 4-pyridine, 2-, 4- or 5-pyrimidine, pyrazine, pyridazine, triazine, anthracene, phenanthrene, triphenylene, pyrene, benzanthracene or combinations of two or three of these groups, each of which may be substituted by one or more radicals R′, or from the structures of the following formulae (3) to (44), 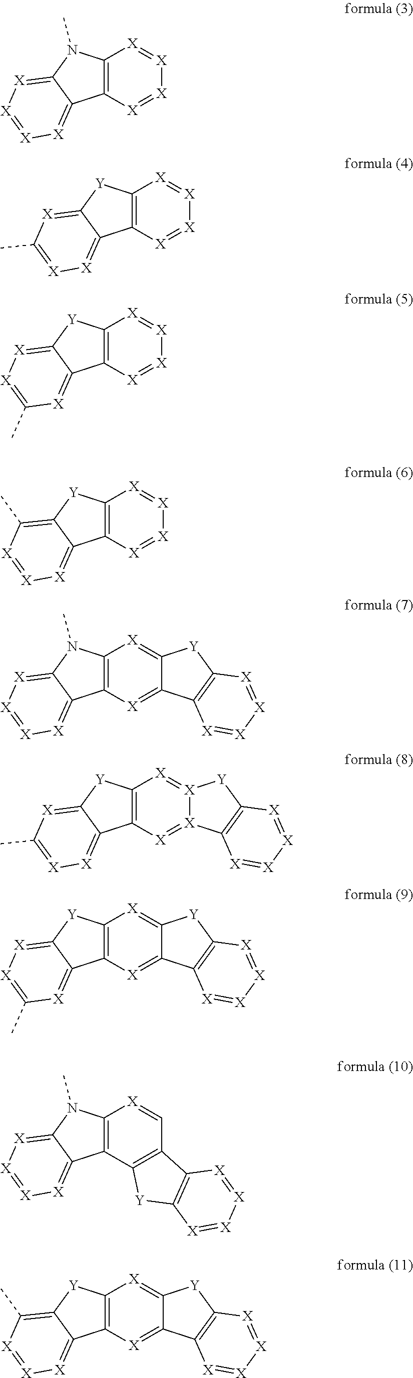 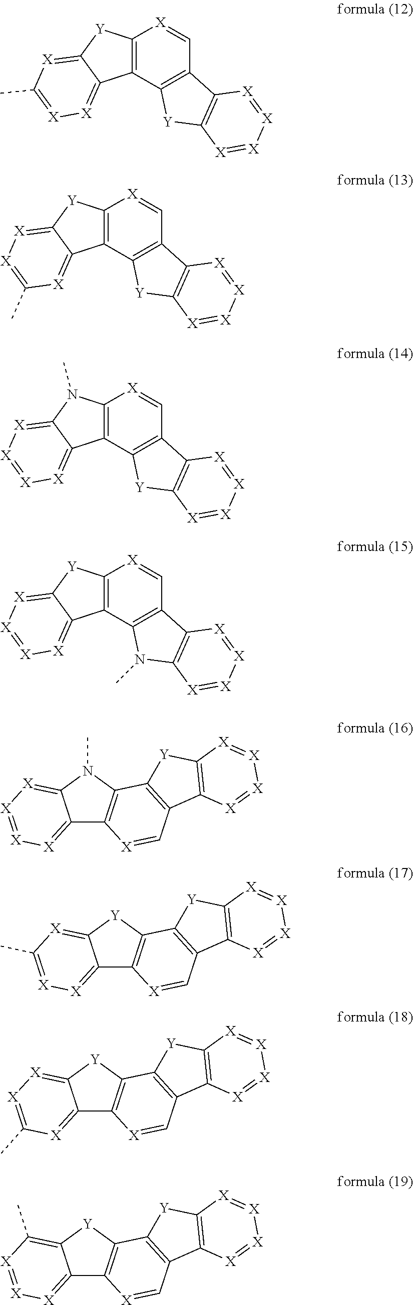 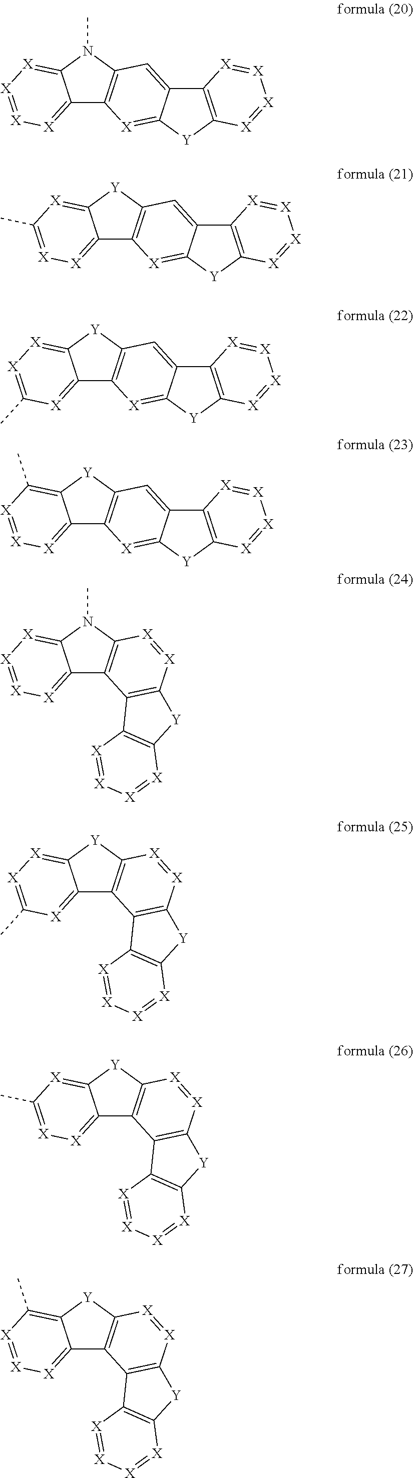 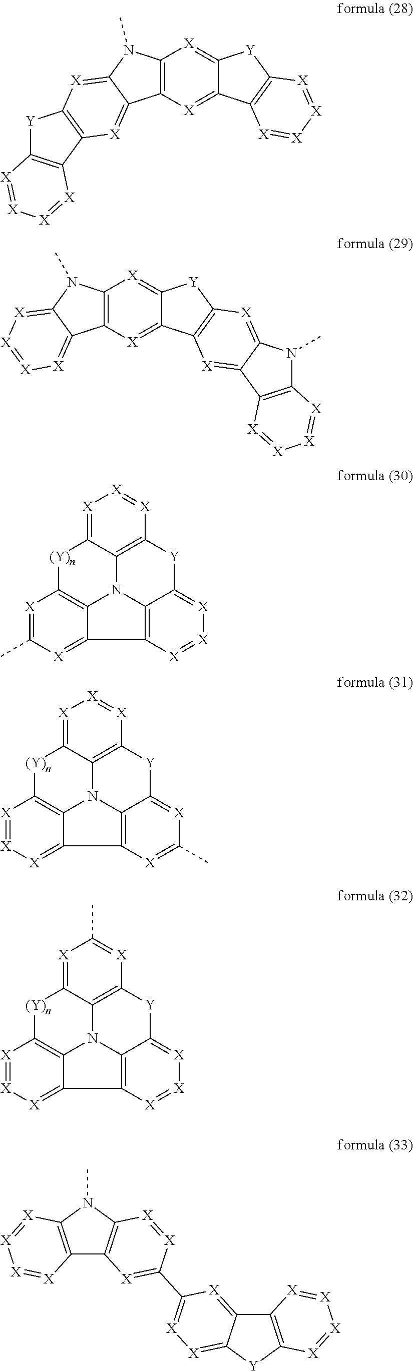 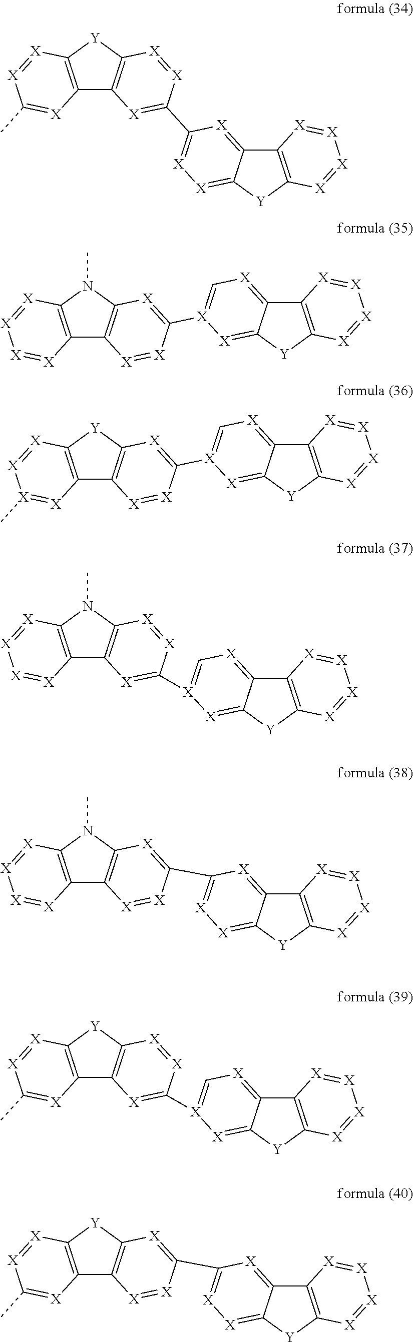 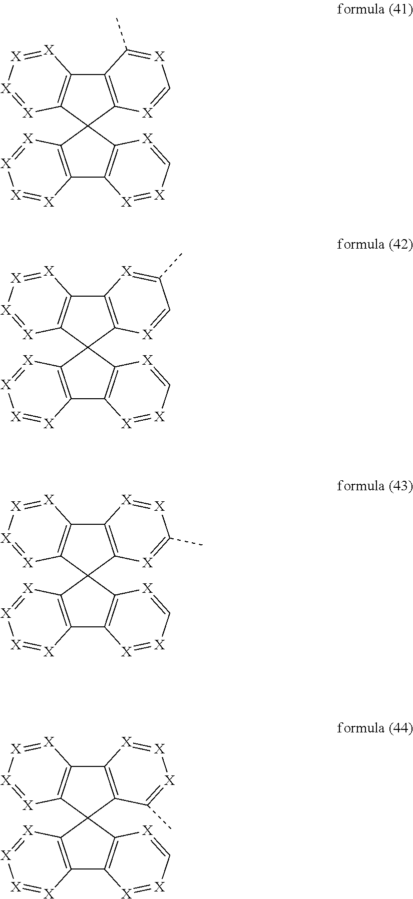
where
the dashed bond represents the bond to the group of the formula (1) or (2), and furthermore:
X is on each occurrence, identically or differently, CR¹ or N;
Y is on each occurrence, identically or differently, C(R¹)₂, NR¹, O or S;
R¹ is selected on each occurrence, identically or differently, from the group consisting of H, D, F, Cl, Br, I, CN, NO₂, N(Ar)₂, N(R²)₂, C(═O)Ar, C(═O)R², P(═O)(Ar)₂, a straight-chain alkyl, alkoxy or thioalkyl group having 1 to 40 C atoms or a branched or cyclic alkyl, alkoxy or thioalkyl group having 3 to 40 C atoms or an alkenyl or alkynyl group having 2 to 40 C atoms, each of which may be substituted by one or more radicals R², where one or more non-adjacent CH₂ groups may be replaced by R²C═CR², C≡C, Si(R²)₂, C═O, C═S, C═NR², P(═O)(R²), SO, SO₂, NR², O, S or CONR² and where one or more H atoms may be replaced by D, F, Cl, Br, I, CN or NO₂, an aromatic or heteroaromatic ring system having 5 to 60 aromatic ring atoms, which may in each case be substituted by one or more radicals R², an aryloxy or heteroaryloxy group having 5 to 60 aromatic ring atoms, which may be substituted by one or more radicals R², or an aralkyl or heteroaralkyl group having 5 to 60 aromatic ring atoms, where two or more adjacent substituents R¹ may optionally form a monocyclic or polycyclic, aliphatic, aromatic or heteroaromatic ring system, which may be substituted by one or more radicals R²;
Ar is on each occurrence, identically or differently, an aromatic or heteroaromatic ring system having 5-30 aromatic ring atoms, which may be substituted by one or more non-aromatic radicals R²; two radicals Ar which are bonded to the same N atom or P atom here may also be bridged to one another by a single bond or a bridge selected from N(R²), C(R²)₂, O or S;
R² is selected from the group consisting of H, D, F, CN, an aliphatic hydrocarbon radical having 1 to 20 C atoms, an aromatic or heteroaromatic ring system having 5 to 30 aromatic ring atoms, in which one or more H atoms may be replaced by D, F, Cl, Br, I or CN, where two or more adjacent substituents R² may form a mono- or polycyclic, aliphatic, aromatic or heteroaromatic ring system with one another.

36. The organic electroluminescent device according to claim 33, wherein the electron-transport material is selected from the compounds of the formulae (45) and (46), 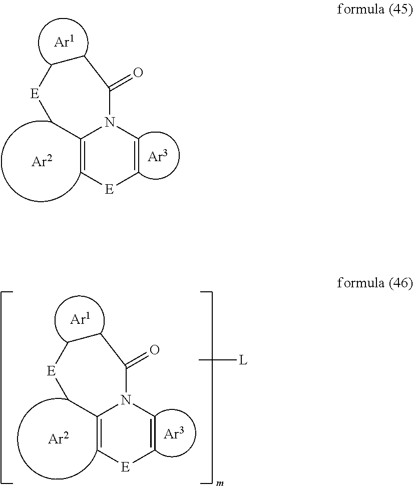
wherein
E is, identically or differently on each occurrence, a single bond, NR, CR₂, O or S;
Ar¹ is, together with the carbon atoms explicitly depicted, an aromatic or heteroaromatic ring system having 5 to 30 aromatic ring atoms, which may be substituted by one or more radicals R;
Ar² and Ar³ are, identically or differently on each occurrence, together with the carbon atoms explicitly depicted, an aromatic or heteroaromatic ring system having 5 to 30 aromatic ring atoms, which may be substituted by one or more radicals R;
L is for m=2 a single bond or a divalent group, or for m=3 a trivalent group or for m=4 a tetravalent group, which is in each case bonded to Ar¹, Ar² or Ar³ at any desired position or is bonded to E in place of a radical R;
m is 2, 3 or 4;
R is selected on each occurrence, identically or differently, from the group consisting of H, D, F, Cl, Br, I, CN, NO₂, N(Ar)₂, N(R¹)₂, C(═O)Ar, C(═O)R¹, P(═O)(Ar)₂, a straight-chain alkyl, alkoxy or thioalkyl group having 1 to 40 C atoms or a branched or cyclic alkyl, alkoxy or thioalkyl group having 3 to 40 C atoms or an alkenyl or alkynyl group having 2 to 40 C atoms, each of which may be substituted by one or more radicals R¹, where one or more non-adjacent CH₂ groups may be replaced by R¹C═CR¹, C≡C, Si(R¹)₂, C═O, C═S, C═NR¹, P(═O)(R¹), SO, SO₂, NR¹, O, S or CONR¹ and where one or more H atoms may be replaced by D, F, Cl, Br, I, CN or NO₂, an aromatic or heteroaromatic ring system having 5 to 80, aromatic ring atoms, which may in each case be substituted by one or more radicals R¹, an aryloxy or heteroaryloxy group having 5 to 60 aromatic ring atoms, which may be substituted by one or more radicals R¹, or an aralkyl or heteroaralkyl group having 5 to 60 aromatic ring atoms, which may be substituted by one or more radicals R¹, where two or more adjacent substituents R may optionally form a monocyclic or polycyclic, aliphatic, aromatic or heteroaromatic ring system, which may be substituted by one or more radicals R¹;
R¹ is selected on each occurrence, identically or differently, from the group consisting of H, D, F, Cl, Br, I, CN, NO₂, N(Ar)₂, N(R²)₂, C(═O)Ar, C(═O)R², P(═O)(Ar)₂, a straight-chain alkyl, alkoxy or thioalkyl group having 1 to 40 C atoms or a branched or cyclic alkyl, alkoxy or thioalkyl group having 3 to 40 C atoms or an alkenyl or alkynyl group having 2 to 40 C atoms, each of which may be substituted by one or more radicals R², where one or more non-adjacent CH₂ groups may be replaced by R²C═CR², C≡C, Si(R²)₂, C═O, C═S, C═NR², P(═O)(R²), SO, SO₂, NR², O, S or CONR² and where one or more H atoms may be replaced by D, F, Cl, Br, I, CN or NO₂, an aromatic or heteroaromatic ring system having 5 to 60 aromatic ring atoms, which may in each case be substituted by one or more radicals R², an aryloxy or heteroaryloxy group having 5 to 60 aromatic ring atoms, which may be substituted by one or more radicals R², or an aralkyl or heteroaralkyl group having 5 to 60 aromatic ring atoms, where two or more adjacent substituents R¹ may optionally form a monocyclic or polycyclic, aliphatic, aromatic or heteroaromatic ring system, which may be substituted by one or more radicals R²;
Ar is on each occurrence, identically or differently, an aromatic or heteroaromatic ring system having 5-30 aromatic ring atoms, which may be substituted by one or more non-aromatic radicals R²; two radicals Ar which are bonded to the same N atom or P atom here may also be bridged to one another by a single bond or a bridge selected from N(R²), C(R²)₂, O or S; and
R² is selected from the group consisting of H, D, F, CN, an aliphatic hydrocarbon radical having 1 to 20 C atoms, an aromatic or heteroaromatic ring system having 5 to 30 aromatic ring atoms, in which one or more H atoms may be replaced by D, F, Cl, Br, I or CN, where two or more adjacent substituents R² may form a mono- or polycyclic, aliphatic, aromatic or heteroaromatic ring system with one another.

37. The organic electroluminescent device according to claim 36, wherein the group Ar¹ stands for a group of the following formula (47), (48), (49) or (50), 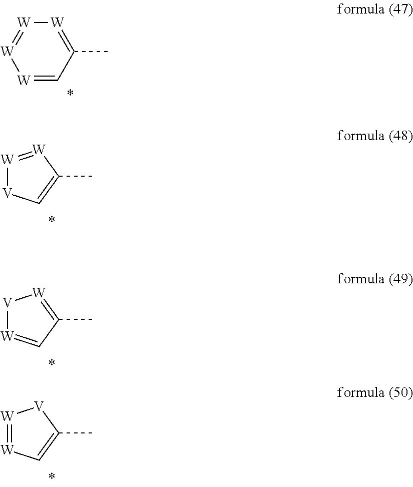
where the dashed bond indicates the link to the carbonyl group, * indicates the position of the link to E or Ar², and furthermore:
W is, identically or differently on each occurrence, CR or N; or two adjacent groups W stand for a group of the formula (51) or (52), 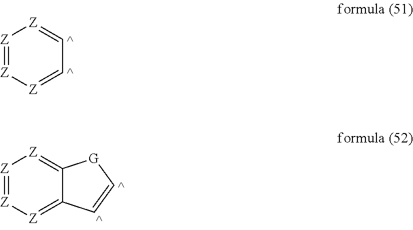
where G stands for CR₂, NR, O or S, Z stands, identically or differently on each occurrence, for CR or N, and ̂ indicate the corresponding adjacent groups W in the formulae (47) to (50);
V is NR, 0 or S;
and/or in that the group Ar² stands for a group of one of the formulae (53), (54) and (55), 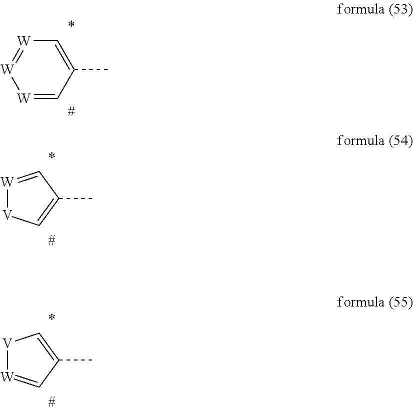
where the dashed bond indicates the link to N, # indicates the position of the link to E or Ar³, * indicates the link to E or Ar¹, and W and V have the above-mentioned meanings;
and/or in that the group Ar³ stands for a group of one of the formulae (56), (57), (58) and (59), 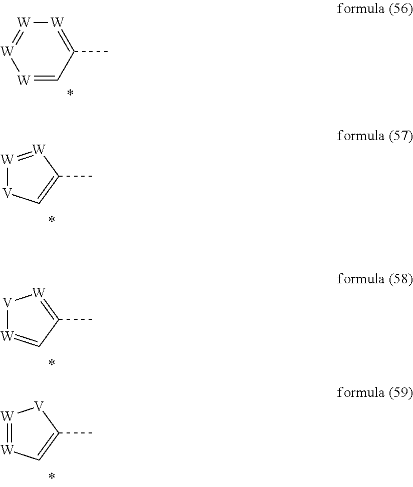
where the dashed bond indicates the link to N, * indicates the link to E or Ar², and W and V have the above-mentioned meanings.

38. The organic electroluminescent device according to claim 33, wherein the electron-transport material is selected from the compounds of the formulae (70) and (71), 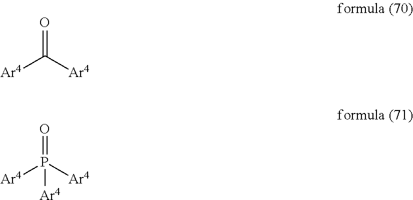
wherein
Ar⁴ is on each occurrence, identically or differently, an aromatic or heteroaromatic ring system having 5 to 80 aromatic ring atoms, which may in each case be substituted by one or more groups R;
R is selected on each occurrence, identically or differently, from the group consisting of H, D, F, Cl, Br, I, CN, NO₂, N(Ar)₂, N(R¹)₂, C(═O)Ar, C(═O)R¹, P(═O)(Ar)₂, a straight-chain alkyl, alkoxy or thioalkyl group having 1 to 40 C atoms or a branched or cyclic alkyl, alkoxy or thioalkyl group having 3 to 40 C atoms or an alkenyl or alkynyl group having 2 to 40 C atoms, each of which may be substituted by one or more radicals R¹, where one or more non-adjacent CH₂ groups may be replaced by R¹C≡CR¹, C≡C, Si(R¹)₂, C═O, C═S, C═NR¹, P(═O)(R¹), SO, SO₂, NR¹, O, S or CONR¹ and where one or more H atoms may be replaced by D, F, Cl, Br, I, CN or NO₂, an aromatic or heteroaromatic ring system having 5 to 80, aromatic ring atoms, which may in each case be substituted by one or more radicals R¹, an aryloxy or heteroaryloxy group having 5 to 60 aromatic ring atoms, which may be substituted by one or more radicals R¹, or an aralkyl or heteroaralkyl group having 5 to 60 aromatic ring atoms, which may be substituted by one or more radicals R¹, where two or more adjacent substituents R may optionally form a monocyclic or polycyclic, aliphatic, aromatic or heteroaromatic ring system, which may be substituted by one or more radicals R¹;
R¹ is selected on each occurrence, identically or differently, from the group consisting of H, D, F, Cl, Br, I, CN, NO₂, N(Ar)₂, N(R²)₂, C(═O)Ar, C(═O)R², P(═O)(Ar)₂, a straight-chain alkyl, alkoxy or thioalkyl group having 1 to 40 C atoms or a branched or cyclic alkyl, alkoxy or thioalkyl group having 3 to 40 C atoms or an alkenyl or alkynyl group having 2 to 40 C atoms, each of which may be substituted by one or more radicals R², where one or more non-adjacent CH₂ groups may be replaced by R²C≡CR², C≡C, Si(R²)₂, C═O, C═S, C═NR², P(═O)(R²), SO, SO₂, NR², O, S or CONR² and where one or more H atoms may be replaced by D, F, Cl, Br, I, CN or NO₂, an aromatic or heteroaromatic ring system having 5 to 60 aromatic ring atoms, which may in each case be substituted by one or more radicals R², an aryloxy or heteroaryloxy group having 5 to 60 aromatic ring atoms, which may be substituted by one or more radicals R², or an aralkyl or heteroaralkyl group having 5 to 60 aromatic ring atoms, where two or more adjacent substituents R¹ may optionally form a monocyclic or polycyclic, aliphatic, aromatic or heteroaromatic ring system, which may be substituted by one or more radicals R²;
Ar is on each occurrence, identically or differently, an aromatic or heteroaromatic ring system having 5-30 aromatic ring atoms, which may be substituted by one or more non-aromatic radicals R²; two radicals Ar which are bonded to the same N atom or P atom here may also be bridged to one another by a single bond or a bridge selected from N(R²), C(R²)₂, O or S; and
R² is selected from the group consisting of H, D, F, CN, an aliphatic hydrocarbon radical having 1 to 20 C atoms, an aromatic or heteroaromatic ring system having 5 to 30 aromatic ring atoms, in which one or more H atoms may be replaced by D, F, Cl, Br, I or CN, where two or more adjacent substituents R² may form a mono- or polycyclic, aliphatic, aromatic or heteroaromatic ring system with one another.

39. A process for the production of the organic electroluminescent device according to claim 20, which comprises applying at least one layer by means of a sublimation process and/or in that at least one layer is applied by means of an OVPD (organic vapour phase deposition) process or with the aid of carrier-gas sublimation and/or in that at least one layer is applied from solution, by spin coating or by means of a printing process.
